(19) United States
(12) Patent Application Publication
(10) Pub. No.: US 2018/0023904 A1
(43) Pub. Date: Jan. 25, 2018

(54) GRAPHITE LAMINATES, PROCESSES FOR PRODUCING GRAPHITE LAMINATES, STRUCTURAL OBJECT FOR HEAT TRANSPORT, AND ROD-SHAPED HEAT-TRANSPORTING OBJECT

(71) Applicant: Kaneka Corporation, Osaka (JP)

(72) Inventors: Yusuke Kato, Osaka (JP); Makoto Kutsumizu, Osaka (JP); Yasushi Nishikawa, Osaka (JP); Keisuke Inaba, Osaka (JP); Michiyasu Sakagami, Osaka (JP)

(73) Assignee: Kaneka Corporation, Osaka (JP)

(21) Appl. No.: 15/536,381

(22) PCT Filed: Dec. 18, 2015
(86) PCT No.: PCT/JP2015/085524

§ 371 Date: Jun. 15, 2017

(30) Foreign Application Priority Data
Dec. 18, 2014 (JP) 2014-256603
Feb. 27, 2015 (JP) 2015-039109
Sep. 10, 2015 (JP) 2015-178821

(51) Int. Cl. F28F 21/02; B32B 9/04; H01L 23/367; C09K 5/14; C09J 7/00; B32B 7/12; C01B 32/20

(52) U.S. Cl. CPC F28F 21/02; B32B 7/12; B32B 9/04; C01B 32/20; C09K 5/14; C09J 7/00; H01L 23/3675; B32B 2309/105; B32B 2307/302; C01P 2006/32; C09J 2433/00; C09J 2467/00; C09J 2423/04; C09J 2479/08; C09J 2483/00; H05K 7/2039

(57) ABSTRACT

The present invention provides, with use of a particular material, (i) a graphite laminate that has high thermal conductivity and that is unlikely to contain a void, (ii) a graphite laminate that is good in thermal conductivity and peel strength, (iii) methods for producing such graphite laminates, (iv) heat transport structures including such graphite laminates, (v) a rod-shaped heat transporter whose operating temperature is not limited and which can be used stably, and (vi) an electronic device including a rod-shaped heat transporter.

### TECHNICAL FIELD

The present invention relates to a graphite laminate, a method for producing a graphite laminate, a heat transport structure, and a rod-shaped heat transporter.

### BACKGROUND ART

Recent years have seen a demand for a heat dissipating member for transferring heat generated by a heat source to a portion with a lower temperature efficiently for prevention of an increase in the temperature of an electronic device in order to solve the problem of heat generation by an electronic device. Examples of such a heat dissipating member in use include a graphite sheet (see, for example, Patent Literatures 1 to 3) and a heat pipe (see, for example, Patent Literatures 4 and 5).

Graphite sheets produced by a polymer burning method have an excellent heat dissipation property, and have thus been used as a heat dissipating component for (i) various electronic devices such as a computer or (ii) semiconductor devices and other heat generating components mounted in electric devices. A graphite sheet as a heat dissipating component is normally attached to, for example, the entire back surface of a liquid crystal display of a computer.

Recent semiconductor devices with higher performance have allowed a CPU to have a smaller size and a larger output, with the result of a semiconductor device generating a larger amount of heat locally. Although the use of a graphite sheet enables heat dissipation, it does not sufficiently transport heat from a heat generator to a lower temperature site. Electronic devices in which CPUs generate large amounts of heat such as a smart phone have been requiring a further measure against heat.

A large-sized electronic device such as a personal computer includes a heat pipe as a component for transporting heat generated by a CPU in a large amount. A heat pipe is structured to have a copper pipe and contain a liquid therein. This liquid draws heat from the electronic device as vaporization heat when the liquid is heated by a heated portion to vaporize, thereby cooling the electronic device. Gas resulting from the vaporization moves to a cooling section to liquefy. The resulting liquid then returns to the heated portion to cool the electronic device. A heat pipe, in other words, causes vaporization and liquefaction repeatedly to cool an electronic device efficiently. Efforts have been made for heat pipes as well for use in devices (such as a smart phone) that have a smaller size and a larger output. Such efforts include designing an improved cross-sectional shape and size for a pipe and preparing improved materials for a pipe and for an operating fluid.

Patent Literature 1 discloses a heat dissipating sheet prepared by disposing graphite films on top of each other with use of an adhesive into a graphite block and slicing the graphite block. The technique disclosed in Patent Literature 1 is intended to first dispose graphite films each having an orientation in the surface direction on top of each other into a graphite block and thinly slice the graphite block in the disposing direction to produce a flexible heat dissipating sheet having an orientation in the thickness direction. This differs from the present invention.

### CITATION LIST

### Patent Literature

[Patent Literature 1] Japanese Patent Application Publication, Tokukai, No. 2009-295921 (Publication Date: Dec. 17, 2009)
[Patent Literature 2] Japanese Patent Application Publication, Tokukaihei, No. 7-109171 (Publication Date: Apr. 25, 1995)
[Patent Literature 3] Japanese Patent Application Publication, Tokukai, No. 2008-305917 (Publication Date: Dec. 18, 2008)
[Patent Literature 4] PCT International Publication No. WO2012/147217 (Publication Date: Nov. 1, 2012)
[Patent Literature 5] PCT International Publication No. WO2014/077081 (Publication Date: May 22, 2014)

### SUMMARY OF INVENTION

### Technical Problem

A heat pipe, as described above, operates on the following principle: Heat is transported through a cycle in which an operating fluid absorbs heat at a high-temperature site to evaporate. Gas resulting from the vaporization passes through a hollow to move to a low-temperature site to agglutinate in liquid form, and returns to the high-temperature site.

As a result, there occurs a dryout; that is, in a case where a heat generating portion such as a CPU has a large output, and a heat pipe in contact with the heat generating portion has been heated, rapid evaporation causes the operating fluid to disappear, thus making it impossible to cool the electronic device. This means that a heat pipe may suddenly stop its operation once it is heated to a high temperature even temporarily. Heat pipes have thus been suffering from the following issues: A heat pipe cannot be used stably because its heat transport capability sharply decreases at a particular temperature. A heat pipe is also limited in terms of operating temperature.

This has led to a need to develop a new heat transporter that is made of a material different from that of heat pipes and that operates on a principle different from that of heat pipes in order to be capable of preventing a dryout.

The inventors of the present invention conducted diligent research to attain the above object and have discovered that one way of attaining the above object is to use a laminate of graphite sheets as a material for a heat pipe in preparing a heat transporter. Graphite sheets are advantageous in that they provide a heat dissipating member that is small, thin, and lightweight and that they are not easily influenced by gravity. It has thus been common technical knowledge to use a single graphite sheet as a heat dissipating member, but not a laminate of graphite sheets. Persons skilled in the art have not had a concept of using a laminate of graphite sheets as a heat transporter. Further, persons skilled in the art have not had a concept of shaping such a laminate as desired for use as a material for a heat transporter.

The inventors of the present invention, however, faced another issue when using a laminate of graphite sheets as a material for a heat transporter.

A simple laminate of graphite sheets and adhesive layers as a material for a heat transporter will, for instance, have a thermal conductivity that is significantly lower than an expected thermal conductivity, that is, a theoretical thermal conductivity, which equals (thermal conductivity of graphite sheets)×(total thickness of graphite sheets)/(thickness of laminate of graphite sheets and adhesive layers).

A graphite sheet, which is prepared from a polymeric film as a material, has low gas permeability. Thus, gas is present between a graphite sheet and an adhesive layer and forms a void. This void causes a heat transporter as a final product to have decreased strength and a poor thermal conductivity characteristic.

Gas can be present as above as a result of (i) gas remaining between a graphite sheet and an adhesive layer during a disposing step or (ii) gas being generated from adhesive layers. In a case where the adhesive layers are each made of a material having a glass transition point of not higher than 50° C. such as an acrylic adhesive and a rubber sheet, gas is likely to remain between a graphite sheet and an adhesive layer during a laminating step. In particular, a thinner adhesive layer has a poorer self-supporting property, requires greater difficulty in operation, and involves a higher risk of gas being present between a graphite sheet and an adhesive layer. Further, gas also results between a graphite sheet and an adhesive layer in a case where (i) gas has been generated from adhesive layers during the step of lamination of graphite sheets and adhesive layers or a case where (ii) heat generated by an electronic device including a laminate of graphite sheets and adhesive layers has caused gas to be generated from the adhesive layers. A graphite laminate containing gas is low in thermal conductivity and peel strength.

The present invention has been accomplished in view of the above issues involved in conventional techniques. A first aspect of the present invention has an object of affording (i) a rod-shaped heat transporter that has no limit on the operating temperature and that is stably usable and (ii) an electronic device including the rod-shaped heat transporter. A second aspect of the present invention has an object of affording (i) a graphite laminate that has high thermal conductivity and that is unlikely to contain a void, (ii) a method for producing the graphite laminate, and (iii) a heat transport structure including the graphite laminate. A third aspect of the present invention has an object of affording (i) a graphite laminate having high thermal conductivity and high peel strength and (ii) a method for producing the graphite laminate.

### Solution to Problem

The following (1) to (10) correspond to the above first aspect of the present invention:

(1) In order to attain the above object, a heat transporter of the present invention is a rod-shaped heat transporter having a thermal conductivity that satisfies Formula (1), the thermal conductivity being measured in a state where the rod-shaped heat transporter has a first end in contact with a high-temperature site and a second end in contact with a low-temperature site having a temperature kept at 20° C.,

λₐ/λ_{b}>0.7 Formula (1)

where λₐ represents a thermal conductivity for a case where the high-temperature site has a temperature of 100° C., and λ_{b} represents a thermal conductivity for a case where the high-temperature site has a temperature of 50° C.

(2) The rod-shaped heat transporter of the present invention may preferably include graphite.

(3) The rod-shaped heat transporter of the present invention may preferably have a layered structure.

(4) In order to attain the above object, a heat transporter of the present invention is a rod-shaped heat transporter including: graphite sheets in a number of not less than 3 and not more than 500; and adhesive layers, the graphite sheets and the adhesive layers being disposed alternately on top of each other.

(5) The rod-shaped heat transporter of the present invention may preferably be configured such that a ratio a/b is not less than 1/500, where a represents a short axis of a cross section of the rod-shaped heat transporter, and b represents a long axis of the cross section of the rod-shaped heat transporter.

(6) The rod-shaped heat transporter of the present invention may preferably have a length L of not less than 4 cm.

(7) The rod-shaped heat transporter of the present invention may preferably be configured such that in a case where (i) opposite ends of the rod-shaped heat transporter are held so that the rod-shaped heat transporter is horizontal with respect to ground and then (ii) one of the opposite ends is released, the released end has a center at a position that is not more than 10% of the length L vertically below a center that said one of the opposite ends had before being released.

(8) The rod-shaped heat transporter of the present invention may preferably be used as a heat pipe.

(9) In order to attain the above object, a rod-shaped heat transporter of the present invention is a rod-shaped heat transporter for use in an electronic device, the rod-shaped heat transporter including: a graphite component, the rod-shaped heat transporter having a first end connected to a heat generator and a second end connected to a low-temperature site having a temperature lower than a temperature of the heat generator, the rod-shaped heat transporter being used as a thermal highway.

(10) In order to attain the above object, an electronic device of the present invention is an electronic device, including: a heat generator; a low-temperature portion having a temperature lower than a temperature of the heat generator; and a thermal highway, the thermal highway including a rod-shaped heat transporter of the present invention.

The following (11) to (25) correspond to the above second aspect of the present invention:

(11) In order to attain the above object, a graphite laminate of the present invention is a graphite laminate including: graphite sheets; and adhesive layers, the graphite sheets and the adhesive layers being disposed alternately on top of each other, the adhesive layers each containing at least one of a thermoplastic resin and a thermosetting resin, the adhesive layers each having a water absorption rate of not more than 2% and a thickness of less than 15 μm, the graphite sheets being included in the graphite laminate in a number of not less than 3.

(12) In order to attain the above object, a graphite laminate of the present invention is a graphite laminate, including: graphite sheets; and adhesive layers, the graphite sheets and the adhesive layers being disposed alternately on top of each other, the adhesive layers each containing at least one of a thermoplastic resin and a thermosetting resin, the adhesive layers each having a thickness of less than 15 μm, the graphite sheets being included in the graphite laminate in a number of not less than 3, the graphite laminate having a water absorption rate of not more than 0.25%.

(13) The graphite laminate of the present invention may preferably be configured such that the thermoplastic resin and the thermosetting resin each have a glass transition point of not lower than 50° C.

(14) The graphite laminate of the present invention may preferably be configured such that the graphite sheets each have a thermal conductivity of not less than 1000 W/(m·K) in a surface direction.

(15) The graphite laminate of the present invention may preferably be configured such that the graphite laminate is bent so as to have at least one bent portion.

(16) In order to attain the above object, a graphite laminate of the present invention is a graphite laminate, including: graphite sheets; and adhesive layers, the graphite sheets and the adhesive layers each having a surface defined by an X axis and a Y axis, which is orthogonal to the X axis, the graphite sheets and the adhesive layers being disposed alternately on top of each other in a direction of a Z axis, which is perpendicular to the surface, in such a manner that the respective surfaces of the graphite sheets and the adhesive layers overlap with each other,

the graphite laminate being bent so as to have at least two bent portions,

each of the at least two bent portions being one of (a) to (c) below,

(a) a first bent portion, which is formed by bending the graphite laminate in a direction of the X axis or the Y axis,

(b) a second bent portion, which is formed by bending the graphite laminate in the direction of the Z axis, and

(c) a third bent portion, which is formed by bending the graphite laminate in a direction of the X axis or the Y axis and also in the direction of the Z axis.

(17) In order to attain the above object, a graphite laminate of the present invention is a graphite laminate, including: graphite sheets; and adhesive layers, the graphite sheets and the adhesive layers each having a surface defined by an X axis and a Y axis, which is orthogonal to the X axis, the graphite sheets and the adhesive layers being disposed alternately on top of each other in a direction of a Z axis, which is perpendicular to the surface, in such a manner that the respective surfaces of the graphite sheets and the adhesive layers overlap with each other,

the graphite laminate being bent so as to have at least one bent portion,

each of the at least one bent portion being (c) below, (c) a third bent portion, which is formed by bending the graphite laminate in a direction of the X axis or the Y axis and also in the direction of the Z axis.

(18) The graphite laminate of the present invention may preferably be configured such that in a case where (i) one end of the graphite laminate is fixed so that the graphite laminate is horizontal with respect to ground and then (ii) a load is imposed on a cross section of the graphite laminate which cross section is located 4 cm away from the fixed end, the load being 0.7 g per 1 mm² of the cross section, the cross section has a displacement of not more than 15 mm.

(19) In order to attain the above object, a heat transport structure of the present invention is a heat transport structure, including: a graphite laminate of the present invention; and a heat-generating element, the graphite laminate being connected with a high-temperature site, whose temperature is raised by heat generated by the heat-generating element, and with a low-temperature site, whose temperature is lower than the temperature of the high-temperature site.

(20) In order to attain the above object, a method of the present invention for producing a graphite laminate is a method for producing a graphite laminate including graphite sheets and adhesive layers, the graphite sheets and the adhesive layers being disposed alternately on top of each other, the method including the steps of: (a) disposing graphite sheets and adhesive layers alternately on top of each other so as to form a stack; and (b) either pressurizing or heating and pressurizing the stack to cause the graphite sheets and the adhesive layers to adhere to each other so as to form a graphite laminate.

(21) The method of the present invention may preferably be arranged such that the adhesive layers each contain at least one of a thermoplastic resin and a thermosetting resin and have a water absorption rate of not more than 2%.

(22) The method of the present invention may preferably be arranged such that the adhesive layers each have an adhesive force of not higher than 1 N/25 mm at 25° C.

(23) The method of the present invention may preferably be arranged such that the step (b) includes (b′) bending the graphite laminate so that the graphite laminate has at least one bent portion.

(24) The method of the present invention may preferably be arranged such that the step (a) includes disposing the graphite sheets and the adhesive layers, each of which has a surface defined by an X axis and a Y axis, which is orthogonal to the X axis, alternately on top of each other along a Z axis, which is perpendicular to the surface, in such a manner that the respective surfaces of the graphite sheets and the adhesive layers overlap with each other so as to form the stack, and

the step (b′) includes at least one of steps (d) to (h) below, each of which is a step of producing a graphite laminate having two or more bent portions,

(d) a first bent portion forming step, which is a step of cutting the stack, which has been heated and pressurized, in a direction of the Z axis so as to cut out a graphite laminate from the stack in such a manner that the graphite laminate has a first bent portion, which is bent in a direction of the X axis or the Y axis,

(e) a second bent portion forming step, which is a step of pressurizing the stack, which has been heated and pressurized, with use of a pressurizing jig with a bent shape in such a manner that the graphite laminate has a second bent portion, which is bent in the direction of the Z axis,

(f) a third bent portion forming step, which is a step of pressurizing the stack, which has been heated and pressurized, with use of a pressurizing jig with a bent shape in such a manner that the stack is bent in the direction of the Z axis and then cutting the stack in the direction of the Z axis so as to cut out a graphite laminate from the stack in such a manner that the graphite laminate has a second bent portion, which is bent in the direction of the Z axis,

(g) a fourth bent portion forming step, which is a step of cutting the stack, which has been heated and pressurized, in the direction of the Z axis so as to cut out from the stack a graphite laminate precursor that is bent in the direction of the X axis direction or the Y axis and then pressurizing the graphite laminate precursor with use of a pressurizing jig with a bent shape in such a manner that the graphite laminate has a third bent portion, which is bent in the direction of the X axis or the Y axis and also in the direction of the Z axis, and

(h) a fifth bent portion forming step, which is a step of pressurizing the stack, which has been heated and pressurized, with use of a pressurizing jig with a bent shape in such a manner that the stack is bent in the direction of the Z axis and cutting the stack in an oblique direction with respect to the direction of the Z axis so as to cut out a graphite laminate from the stack in such a manner that the graphite laminate has a third bent portion, which is bent in the direction of the X axis or the Y axis and also in the direction of the Z axis.

(25) The method of the present invention may preferably be arranged such that the step (a) includes disposing the graphite sheets and the adhesive layers, each of which has a surface defined by an X axis and a Y axis, which is orthogonal to the X axis, alternately on top of each other along a Z axis, which is perpendicular to the surface, in such a manner that the respective surfaces of the graphite sheets and the adhesive layers overlap with each other so as to form the stack, and

the step (b′) includes at least one of steps (g) and (h) below, each of which is a step of producing a graphite laminate having one or more bent portions,

(g) a fourth bent portion forming step, which is a step of cutting the stack, which has been heated and pressurized, in the direction of the Z axis so as to cut out from the stack a graphite laminate precursor that is bent in the direction of the X axis direction or the Y axis and then pressurizing the graphite laminate precursor with use of a pressurizing jig with a bent shape in such a manner that the graphite laminate has a third bent portion, which is bent in the direction of the X axis or the Y axis and also in the direction of the Z axis, and
(h) a fifth bent portion forming step, which is a step of pressurizing the stack, which has been heated and pressurized, with use of a pressurizing jig with a bent shape in such a manner that the stack is bent in the direction of the Z axis and cutting the stack in an oblique direction with respect to the direction of the Z axis so as to cut out a graphite laminate from the stack in such a manner that the graphite laminate has a third bent portion, which is bent in the direction of the X axis or the Y axis and also in the direction of the Z axis.

The following (26) to (31) correspond to the above third aspect of the present invention:

(26) In order to attain the above object, a graphite laminate of the present invention is a graphite laminate, including: graphite sheets; and adhesive layers, the graphite sheets and the adhesive layers being disposed alternately on top of each other, the adhesive layers each containing at least one of a thermoplastic resin and a thermosetting resin, the graphite sheets being included in the graphite laminate in a number of not less than 3, the graphite sheets and the adhesive layers being in close contact with each other at not less than 50% of an interface therebetween.

(27) In order to attain the above object, a method of the present invention for producing a graphite laminate is a method for producing a graphite laminate, the method including the steps of: (a) disposing an adhesive layer material, which is a material of adhesive layers, and graphite sheets alternately in a plurality of layers on top of each other so as to form a stack; and (b) heating the stack to thermally fuse the adhesive layer material to the graphite sheets so as to produce a graphite laminate in which the graphite sheets and the adhesive layers are arranged alternately, the adhesive layer material containing at least one of a thermoplastic resin and a thermosetting resin, in the step (b), a first pressurizing being performed in which the stack is pressurized at least by a time a temperature of the adhesive layer material reaches [(melting point of adhesive layer material)−20° C.], in the first pressurizing, the stack being pressurized in such a manner that the adhesive layer material does not thermally fuse to the graphite sheets, in the step (b), a second pressurizing being further performed in which the stack is pressurized at least after the temperature of the adhesive layer material reaches [(melting point of adhesive layer material)−20° C.], in the second pressurizing, the stack being pressurized in such a manner that the adhesive layer material does not thermally fuse to the graphite sheets.

(28) The method of the present invention may preferably be arranged such that in the second pressurizing, the stack is pressurized at a pressure higher than a pressure at which the stack is pressurized in the first pressurizing.

(29) The method of the present invention may preferably be arranged such that in the second pressurizing, the stack is pressurized at a pressure and temperature that are higher than a pressure and temperature at which the stack is pressurized in the first pressurizing.

(30) The method of the present invention may preferably be arranged such that the first pressurizing is started at a start of the step (b).

(31) In order to attain the above object, a method of the present invention for producing a graphite laminate is a method for producing a graphite laminate, the method including the steps of: (a) disposing an adhesive layer material, which is a material of adhesive layers, and graphite sheets alternately in a plurality of layers on top of each other so as to form a stack; and (b) heating the stack to thermally fuse the adhesive layer material to the graphite sheets so as to produce a graphite laminate in which the graphite sheets and the adhesive layers are arranged alternately, the adhesive layer material containing at least one of a thermoplastic resin and a thermosetting resin, in the step (a), a plurality of the stacks being disposed on top of each other.

### Advantageous Effects of Invention

A rod-shaped heat transporter of the present invention (specifically, the first aspect of the present invention) is advantageously usable at temperatures within a wide range.

The present invention (specifically, the second aspect of the present invention) advantageously provides a graphite laminate that has high thermal conductivity and that is unlikely to contain a void and a method for producing such a graphite laminate. The present invention (specifically, the first aspect of the present invention) advantageously makes it possible to dispose and cut layers in a desired manner during the production of a graphite laminate.

The present invention (specifically, the third aspect of the present invention) advantageously provides a graphite laminate that is good in thermal conductivity and peel strength and a method for producing such a graphite laminate.

### BRIEF DESCRIPTION OF DRAWINGS

FIG. 1 is a diagram illustrating a basic structure of a graphite laminate in accordance with an embodiment.

FIG. 2 is a diagram illustrating a graphite laminate having a bent portion in accordance with an embodiment.

FIG. 3 is a diagram illustrating a graphite laminate having a bent portion in accordance with an embodiment.

FIG. 4 is a diagram illustrating a graphite laminate having a bent portion in accordance with an embodiment.

FIG. 5 is a diagram illustrating a graphite laminate having a bent portion in accordance with an embodiment.

FIG. 6 is a diagram illustrating a method in accordance with an embodiment for producing a graphite laminate having a bent portion.

FIG. 7 is a diagram illustrating a method in accordance with an embodiment for producing a graphite laminate having a bent portion.

FIG. 8 is a diagram illustrating a method in accordance with an embodiment for producing a graphite laminate having a bent portion.

FIG. 9 is a diagram illustrating a bent portion having a non-adhering portion in accordance with an embodiment.

FIG. 10 is a diagram illustrating a bent portion having a non-adhering portion in accordance with an embodiment.

FIG. 11 is a diagram illustrating a heat transport structure in accordance with an embodiment.

FIG. 12 is a diagram illustrating a heat transport structure in accordance with an embodiment.

FIG. 13 is a diagram illustrating a heat transport structure in accordance with an embodiment.

FIG. 14 is a diagram illustrating how a graphite laminate is placed with respect to a high-temperature site in accordance with an embodiment.

FIG. 15 is a diagram illustrating how a graphite laminate is placed with respect to a high-temperature site in accordance with an embodiment.

FIG. 16 is a diagram illustrating a graphite laminate in accordance with an embodiment for a case where the graphite laminate is oriented so as to have a layered surface facing a high-temperature site.

FIG. 17 is a diagram that shows the dimensions of a graphite laminate in accordance with an embodiment.

FIG. 18 is a diagram that shows the dimensions of a graphite laminate in accordance with an embodiment.

FIG. 19 is a diagram illustrating a method in accordance with an embodiment for producing a graphite laminate having a bent portion.

FIG. 20 is a diagram illustrating a basic structure of a graphite laminate in accordance with an embodiment.

FIG. 21 is a diagram illustrating a method in accordance with an embodiment for producing a graphite laminate having a bent portion.

FIG. 22 is a diagram illustrating a device for measuring thermal conductivity.

FIG. 23 is a diagram illustrating a device for measuring thermal conductivity for the present invention.

FIG. 24 is a diagram illustrating a rod-shaped heat transporter of the present invention which rod-shaped heat transporter is placed on a smart phone as a thermal highway.

FIG. 25 is a graph that plots λₐ/λ_{b} of Examples and Comparative Examples for the present invention.

FIG. 26 is a diagram illustrating a method for measuring a deformation rate for the present invention.

FIG. 27 shows diagrams illustrating an example process of preparing a graphite composite film with use of a sticker.

(a) and (b) of FIG. 28 are each a side view of a device including a graphite laminate, the side view showing an example of how a graphite laminate having a bent portion is placed inside various devices.

(a) of FIG. 29 is a side view of a rod-shaped heat transporter, and (b) of FIG. 29 is a cross-sectional view of a rod-shaped heat transporter.

### DESCRIPTION OF EMBODIMENTS

The following description will discuss embodiments of the present invention. The present invention is, however, not limited to the embodiments below. The present invention is not limited to the description of the arrangements below, but may be altered variously by a skilled person within the scope of the claims. Any embodiment or Example based on a proper combination of technical means disclosed in different embodiments and Examples is also encompassed in the technical scope of the present invention. All academic and patent documents cited in the present specification are incorporated herein by reference. Further, any numerical range expressed as “A to B” in the present specification means “not less than A and not more than B” unless otherwise stated.

The above-described first aspect of the present invention is detailed in [Embodiment A] and <Example Set A> below. The above-described second aspect of the present invention is detailed in [Embodiment B] and <Example Set B> below. The above-described third aspect of the present invention is detailed in [Embodiment C] and <Example Set C> below. Further, [Embodiment D] below is covered in scope by all of the first aspect of the present invention, the second aspect of the present invention, and the third aspect of the present invention.

### Embodiment A

The present invention provides a rod-shaped heat transporter having a thermal conductivity that satisfies

Formula (1), the thermal conductivity being measured in a state where the rod-shaped heat transporter has a first end in contact with a high-temperature site and a second end in contact with a low-temperature site having a temperature kept at 20° C.,

λₐ/λ_{b}>0.7 Formula (1)

where λₐ represents a thermal conductivity for a case where the high-temperature site has a temperature of 100° C., and λ_{b} represents a thermal conductivity for a case where the high-temperature site has a temperature of 50° C.

Electronic devices that have a small size and a large output such as a smart phone and a tablet computer include CPUs that generate large amounts of heat. Such electronic devices include a heat pipe as a component for transferring the heat effectively to a site as far away as possible from the CPU. Heat pipes are capable of directly connecting a high-temperature site of an electronic device (namely, a heat generating portion such as a CPU or a portion near the heat generating portion) with a low-temperature site of the electronic device (that is, a site having a temperature lower than the high-temperature site) for heat transport. Heat pipes thus serve as a thermal highway built in an electronic device. The use of a heat pipe as a thermal highway, however, involves the following issue: In a case where a sharp increase in the amount of heat generated by a CPU has sharply increased the temperature of the electronic device, the operating fluid in the hollow portion of the heat pipe evaporates to disappear, making it impossible to cool the electronic device. This is called a dryout, and is unavoidable as long as a heat pipe is used for heat transport.

In view of that, the inventors of the present invention started to think that dryouts are avoidable by provision of a thermal highway that does not require an operating fluid and that operates on a different principle. Using as a thermal highway a rod-shaped material having no hollow portion or no operating fluid would make it possible to avoid dryouts. Such a rod-shaped material would need to be capable itself of heat transport. In view of that, the inventors of the present invention focused on a graphite material. The inventors shaped a graphite material into a rod, and used the rod-shaped graphite material as a thermal highway in replacement of a heat pipe to evaluate the heat transport capability, eventually discovering that such a rod-shaped graphite material is not only capable of preventing dryouts, but also excellent in heat transport capability.

Graphite materials are used as a negative electrode material for a lithium-ion battery or as a lubricant. Graphite materials are also used as a heat dissipating sheet for an electronic device. Graphite materials used as a heat dissipating sheet are thin, and are thus low in stiffness. The inventors of the present invention tried disposing a plurality of heat dissipating sheets, which are thin and flexible and each of which is used separately as a heat dissipating component, on top of each other (in a layered structure). The inventors then shaped the laminate into various rods with different shapes, hardnesses, and sizes that the inventors considered appropriate for use as a thermal highway, and evaluated the respective heat transport capabilities of the rods. The inventors of the present invention have, as a result, discovered that (i) the rods each exhibit a particularly excellent heat transport capability and also prevent dryouts and that (ii) using the rods as a thermal highway enables constant heat transport regardless of the temperature of the heat generating portion. This discovery has made it clear that graphite is suitably usable as a material for a thermal highway.

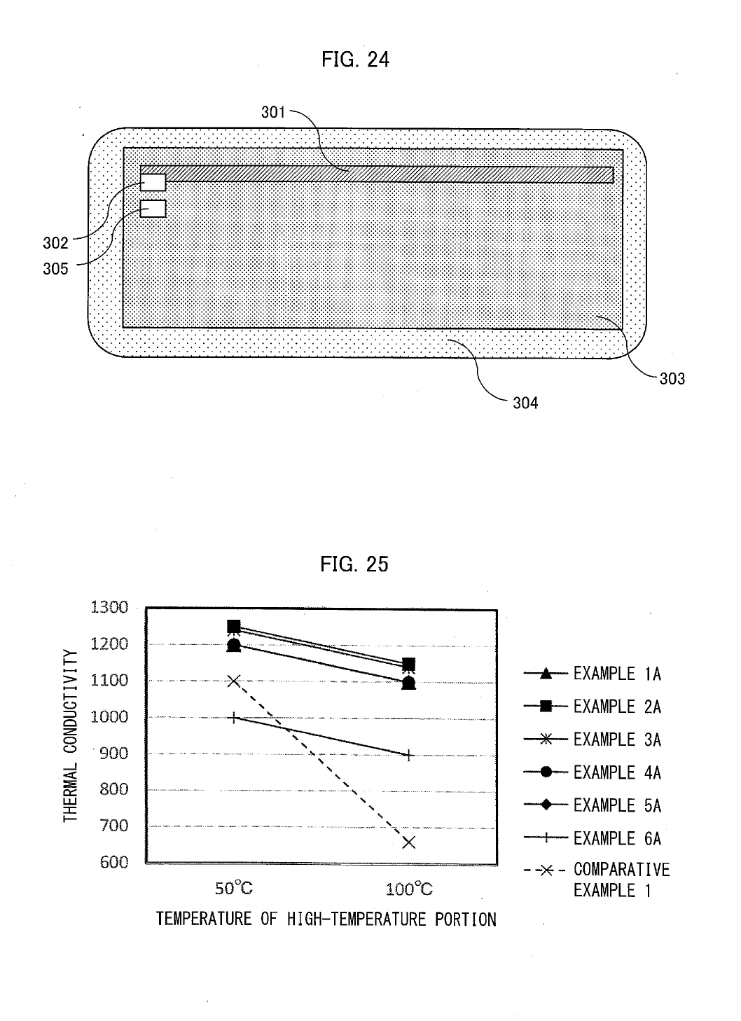

A heat transporter of the present invention is, as in the example illustrated in FIG. 24, usable as a thermal highway for an electronic device. The heat transporter of the present invention can, as described above, directly connect a high-temperature site such as a CPU with a low-temperature site for causing the heat to escape, thereby making it possible to transport heat efficiently. FIG. 24 is a diagram illustrating a casing 304 for a smart phone, a plate 303 inside the casing 304, and a rod-shaped heat transporter 301 of the present invention disposed on the plate 303 for use as a thermal highway. Using the rod-shaped heat transporter 301 as a thermal highway can advantageously prevent heat generated by a heat generating portion such as a first CPU 302 from being transmitted to a second CPU 305 having low heat resistance. Further, shaping the rod for a desired shape and size that allow heat to be transported from a heat generator directly to a low-temperature portion can advantageously prevent deterioration of other components of the electronic device such as a chip. A heat transporter of the present invention thus has a rod shape. The expression “rod shape” refers to the shape of a narrow bar that is long in one axis direction. The cross-sectional shape of such a bar is not limited to any particular one, and may be, for example, a rectangle, a circle, an ellipse, or a polygon.

To explain in greater detail that a heat transporter of the present invention has a rod shape that allows the heat transporter to be used as a thermal highway, the following description will discuss a preferable example of the size (that is, the ratio between the long axis and the short axis) of the cross section (that is, a cross section perpendicular to the long-axis direction of the rod) of the rod and a preferable length thereof.

(a) of FIG. 29 is a side view of a rod-shaped heat transporter 601. (b) of FIG. 29 is a cross-sectional view of the rod-shaped heat transporter 601 taken along the broken line in (a) of FIG. 29. As illustrated in (a) of FIG. 29, the rod-shaped heat transporter 601 has a length L in its long-axis direction. Further, as illustrated in (b) of FIG. 29, the rod-shaped heat transporter 601 has a cross section that has a short axis with a length a and a long axis with a length b.

In a case where the rod has a cross section with a short axis a and a long axis b, a/b is preferably not less than 1/500. a/b is more preferably not less than 1/200 because such a ratio (i) allows the difference in temperature to be small between any two positions over the cross section of the rod and (ii) increases the efficiency in heat transport. a/b is even more preferably not less than 1/100. In a case where the cross section has an area that varies in the longitudinal direction of the rod, a/b is calculated in a cross section having the largest difference between a and b. The rod has a length L of preferably not less than 4 cm. The length of the rod (which depends also on the size of a smart phone or tablet computer in which the heat transporter is to be included) is preferably large enough to directly connect a heat generating portion with a low-temperature portion that is sufficiently away from the heat generating portion in the electronic device in which the heat transporter is to be included. This is because it is preferable in terms of heat transport that heat is transported as far away as possible from the heat generating portion.

The ratio L/b between the long axis b and length L of the rod is preferably not less than 5 in a case where (i) heat is to be transported to a particular portion (for example, a graphite sheet, metal, or a heat sink in an electronic device [for example, a laptop personal computer]) or where (ii) the rod-shaped heat transporter is used in combination with, for example, a graphite sheet or a metal plate. L/b is more preferably not less than 10 because such a ratio makes it possible to reduce the region occupied by the heat pipe in the electronic device. L/b is even more preferably not less than 20. The upper limit of L/b is not limited to any particular value. However, in a case where heat is to be diffused across a surface for an escape to air or the like as in a smart phone or a tablet terminal, the upper limit is preferably not more than 100 (more specifically, 1 to 100), more preferably not more than 10 (more specifically 1 to 10), even more preferably not more than 5 (more specifically 1.2 to 5). The length of the long axis b is not limited to any particular value, but is preferably equal to or larger than the short sides of the heat source. This configuration allows heat to be transported from the heat source efficiently.

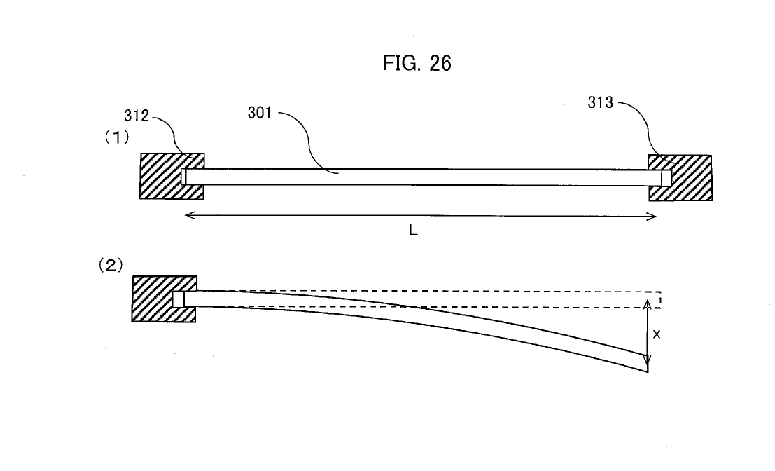

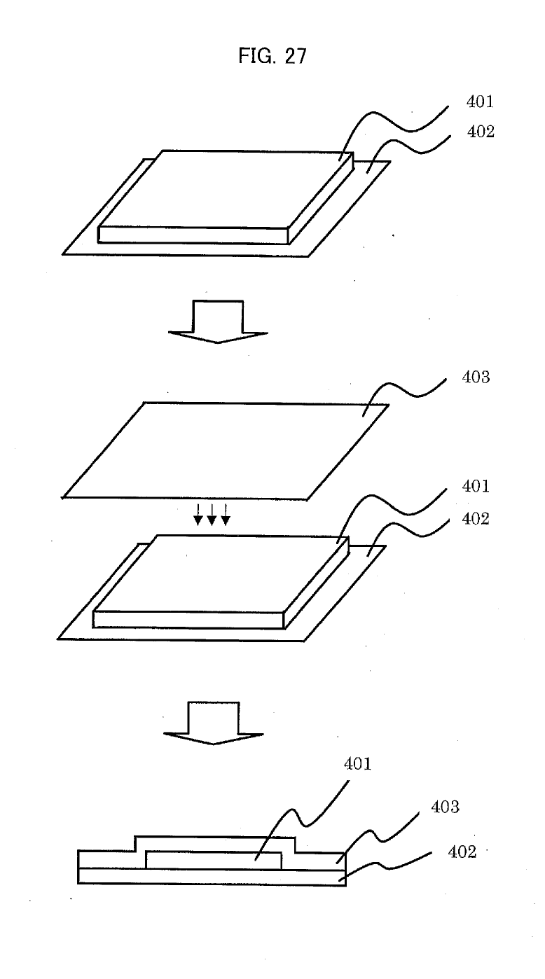

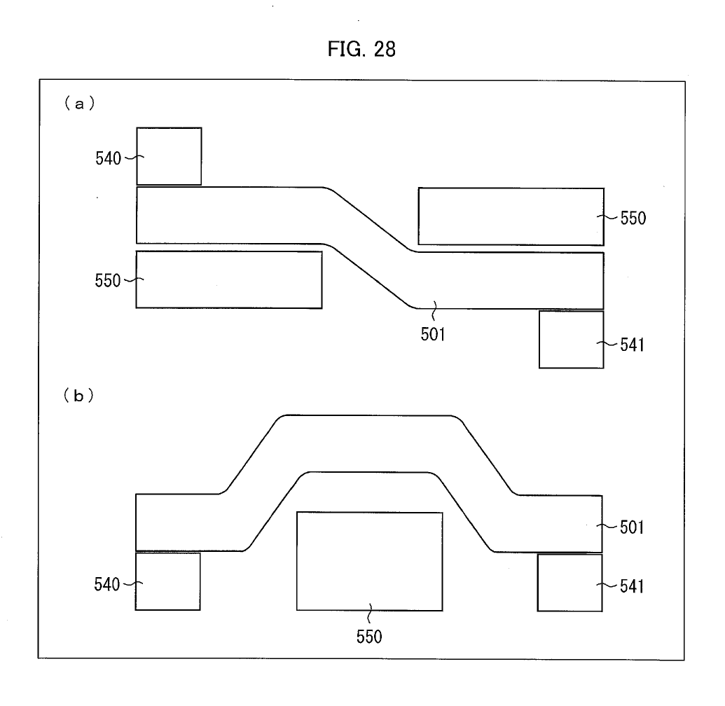

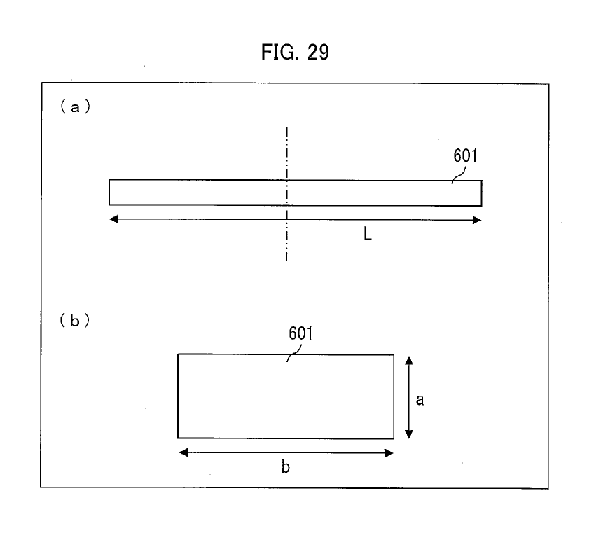

To specifically show that a heat transporter of the present invention is not in a sheet shape but in a rod shape, the heat transporter of the present invention can be expressed in terms of how unlikely it is to be deformed (deformation rate). The deformation rate is measured by the following method: As in (1) in FIG. 26, the opposite ends of a rod-shaped heat transporter 301 are held with use of a first clamp 312 and a second clamp 313, respectively, in such a manner that the rod-shaped heat transporter 301 is parallel to the ground (horizontal). Then, the second clamp 313 is removed as in (2) in FIG. 26. The deformation rate of the rod-shaped heat transporter 301 is defined as x/L, where x represents the vertical distance by which the center of the released end of the rod-shaped heat transporter 301 has been lowered as the result of the second clamp 313 stopping holding the corresponding end, and L represents the length of the rod-shaped heat transporter 301. A rod-shaped heat transporter of the present invention has a deformation rate of not more than 10%, indicating that the rod-shaped heat transporter is hard. The rod-shaped heat transporter of the present invention being in the form of a hard bar as described above is also preferable because such a configuration ensures the strength of the heat transporter itself.

A rod-shaped heat transporter invented by the inventors of the present invention, unlike conventional heat pipes, does not cause a dryout. This can be indicated with the thermal conductivity of the heat transporter. Specifically, a rod-shaped heat transporter of the present invention has a thermal conductivity measured in a state where the heat transporter has one end in contact with a high-temperature site and the other end in contact with a low-temperature site having a constant temperature of 20° C., the thermal conductivity satisfying the following Formula (1):

λₐ/λ_{b}>0.7 Formula (1)

In Formula (1), λₐ represents a thermal conductivity for a case where the high-temperature site has a temperature of 100° C., and λ_{b} represents a thermal conductivity for a case where the high-temperature site has a temperature of 50° C.

The thermal conductivity can be measured with use of a measurement device illustrated in FIG. 23. With reference to FIG. 23,

(1) Bring an end 328 of a rod-shaped heat transporter 301 into contact with running water 323 (low-temperature site) to keep the end 328 at 20° C.

(2) Attach a heater 322 (high-temperature site) to an end 327 of the rod-shaped heat transporter 301 (in other words, bring the end 327 into contact with the heater 322). Attach a thermocouple 325 to the portion of the rod-shaped heat transporter 301 at which portion the end 327 is in contact with the rod-shaped heat transporter 301. Attach a thermocouple 326 to the portion of the rod-shaped heat transporter 301 at which portion the running water 323 is in contact with the end 328. The temperature measured with use of the thermocouple 325 is the temperature T of the high-temperature site, whereas the temperature measured with use of the thermocouple 326 is the temperature (20° C.) of the low-temperature site.

(3) Cover the rod-shaped heat transporter 301 with a heat insulating material 324 except for the low-temperature site.

(4) Adjust the output Q of the heater 322 to keep the temperature of the high-temperature site constant.

After these operations, the thermal conductivity A can be calculated as follows:

Δ= [symbol] ×L/[S(T−20° C.)]

where S represents a cross section, and L represents the length in the axis direction.

The output Q of the heater 322 is determined for a case where the heater 322 has been adjusted so that the high-temperature site has a temperature of 100° C., and the output Q of the heater 322 is determined also for a case where the heater 322 has been adjusted so that the high-temperature site has a temperature of 50° C. Then, the thermal conductivity (λₐ) for the case where the high-temperature site has a temperature of 100° C. is determined, and the thermal conductivity (λ_{b}) for the case where the high-temperature site has a temperature of 50° C. is also determined. The thermal conductivity λₐ (that is, for the case where the high-temperature site has a temperature of 100° C.) is used for the following reason: For conventional heat pipes, in a case where the output of a heater has been adjusted so that a high-temperature site has a temperature of 100° C., the operating fluid is heated to a temperature close to the boiling point, and a dryout is likely to occur at the high-temperature site, with the result of a sharp decrease in the amount of heat transported. The thermal conductivity λ_{b} (that is, for the case where the high-temperature site has a temperature of 50° C.) is used for the following reason: For conventional heat pipes, in a case where the output of a heater has been adjusted so that a high-temperature site has a temperature of 50° C., no dryout occurs.

The ratio λₐ/λ_{b} of the thermal conductivities measured as above is more than 0.7. The heat transporter of the present invention causes no dryout. The heat transporter of the present invention is, in other words, capable of transporting heat constantly regardless of the heater output. However, λₐ/λ_{b} is preferably defined in view of a slight decrease in the heat transport capability caused by a factor other than a dryout. Specifically, λₐ/λ_{b} is preferably more than 0.8, more preferably more than 0.9. λₐ/λ_{b} is preferably more than 0.8 because such a ratio allows the heat transporter to be used to transport heat generated by a CPU that has a large output and that can have a high temperature.

A heat transporter of the present invention has λₐ of preferably not less than 320 W/mK, more preferably not less than 400 W/mK. The heat transporter has λ_{b} of preferably not less than 400 W/mK, more preferably not less than 500 W/mK.

A rod-shaped heat transporter that satisfies Formula (1) above can be produced by, for example, a method involving use of graphite (graphite component) as a material therefor. A graphite material can be shaped into a rod by, for example, a method of

(a) crushing graphite sheets, filling a mold with the crushed product, and then pressing the crushed product,

(b) forcing graphite sheets and (as necessary) adhesive layers into a box while bending the graphite sheets and the adhesive layers into a shape and then pressing the graphite sheets and the adhesive layers, or

(c) disposing graphite sheets and adhesive layers alternately on top of each other into a laminate, heating, pressurizing, and/or otherwise processing the laminate so that the graphite sheets and the adhesive layers adhere to each other, and cutting off a portion of the laminate into a rod.

The method is, however, not limited to these examples. Among the above examples, the method (c) is preferable because it makes it possible to freely design the size and shape of the rod and easily produce a rod-shaped heat transporter having an excellent thermal conductivity. The method (c) makes it possible to produce a rod-shaped heat transporter having a layered structure.

The following description will discuss in detail how a rod-shaped heat transporter is produced by the method (c). The graphite sheet for use in the method (c) is not limited to any particular kind, and can be, for example, a polymeric graphite sheet or a graphite sheet produced by expanding natural graphite as a raw material. A polymeric graphite sheet is preferable for the following reason: It has high strength and good thermal conduction property, and can thus provide a rod-shaped heat transporter having higher strength and higher heat transport capability.

The method for producing a graphite sheet for the present invention is not limited to any particular one. A first method for producing a graphite sheet for the present invention is a method of expanding natural graphite as a raw material. Specifically, the first method includes (i) immersing graphite powder in an acid (for example, sulfuric acid) to prepare a graphite intercalation compound, (ii) heat-treating and foaming the graphite intercalation compound to release a graphite layer, (iii) washing the graphite layer for removal of the acid to prepare a thin film formed of graphite powder, and (iv) shaping the thus-prepared thin film with use of pressure rolls to produce a graphite sheet.

A second method for producing a graphite sheet for the present invention is a method of heat-treating a polymeric film (for example, polyimide resin) to prepare a polymeric graphite sheet. Specifically, the second method includes (i) preheating a polymeric film as a starting material at a temperature of approximately 1000° C. under reduced pressure or in an atmosphere of an inert gas for carbonization to produce a carbonized film, and (ii) heat-treating the carbonized film at a temperature of not less than 2800° C. in an atmosphere of an inert gas for graphitization to produce a graphite sheet having a good graphite crystal structure and an excellent thermal conduction property.

A graphite sheet for the present invention has a thermal conductivity of preferably not less than 1000 W/(m·K), more preferably not less than 1100 W/(m·K), even more preferably not less than 1200 W/(m·K), even more preferably not less than 1300 W/(m·K), in the surface direction.

The use of a graphite sheet having a thermal conductivity of not less than 1000 W/(m·K) in the surface direction makes it possible to produce a rod-shaped heat transporter having a higher heat transport capability.

The adhesive layers can each be made of a thermosetting resin or a thermoplastic resin.

The thermosetting resin can be one of the examples listed under “(Kind of adhesive layer)” for Embodiment B.

The thermoplastic resin can be one of the examples listed under “(Kind of adhesive layer)” for Embodiment B.

The thermoplastic resin and the thermosetting resin each have a glass transition point of preferably not lower than 50° C., more preferably not lower than 60° C., even more preferably not lower than 70° C., even more preferably not lower than 80° C. A glass transition point of not lower than 50° C. makes it possible to more effectively prevent air from remaining in a graphite laminate to be produced. A material such as an acrylic adhesive and a rubber sheet which material has a glass transition point of not lower than 50° C. is preferable because such a material provides adhesive layers that are high in strength and that are unlikely to have property variations. Examples of a material having such a glass transition temperature include polyethylene terephthalate (PET), polystyrene (PS), and polycarbonate (PC). Graphite sheets and adhesive layers as described above are disposed alternately on top of each other into a laminate. This operation is carried out specifically by, for example, (i) a method of disposing graphite sheets and adhesive layers alternately on top of each other or (ii) a method of preparing graphite adhesive sheets each including a graphite sheet and an adhesive layer on at least one surface of the graphite sheet and disposing the graphite adhesive sheets on top of each other.

The method (ii) above includes first preparing graphite adhesive sheets. Graphite adhesive sheets can each be prepared by coating a graphite sheet with an adhesive resin or by laminating a graphite sheet with an adhesive film.

In a case where a method is used of applying an adhesive layer material (varnish) to a graphite sheet, the adhesive layer material (varnish) preferably has no tucking property after the application in order to prevent air from remaining in a graphite laminate to be produced. In a case where a method is used of disposing adhesive layers and graphite sheets alternately on top of each other, a low dielectric constant for the adhesive layers, which means that the adhesive layers are not easily electrically charged, allows the adhesive layers to be fixed to a conveyer stably with use of electrostatic force. The dielectric constant of the adhesive layers is not limited to any particular value, but is preferably 1.0 to 5.0, more preferably 2.0 to 4.0, even more preferably 2.5 to 3.6. A dielectric constant of 1.0 to 5.0 for the adhesive layers is preferable for the heat transporter as a thermal highway because such a dielectric constant causes the adhesive layers to repel each other as a result of static electricity and thus allows the adhesive layers to be released from each other.

Further, with a good electrical conduction property for the graphite sheets, in a case where the graphite sheets and the adhesive layers are in close contact with each other, static electricity of the adhesive layers escape to the graphite sheets, with the result that the graphite sheets and the adhesive layers are more slidable on each other and that the adhesive layers are less likely to be wrinkled. The electrical conductivity of a graphite sheet for the present invention is not limited to any particular value, but is preferably 1000 S/cm to 25000 S/cm, more preferably 2000 S/cm to 20000 S/cm, even more preferably 5000 S/cm to 18000 S/cm, even more preferably 10000 S/cm to 17000 S/cm. An electrical conductivity of 1000 S/cm to 25000 S/cm for the graphite sheets can ensure moderate adhesiveness and moderate slidability between the graphite sheets and the adhesive layers, and is suitable for disposing the adhesive layers (in particular, thin adhesive layers) and the graphite sheets on top of each other. The above electrical conductivity is thus preferable for the heat transporter as a thermal highway.

After lamination components are disposed on top of each other as described above, heating and pressurizing (in other words, compressing) the disposed components causes the graphite sheets and the adhesive layers to adhere to each other for formation of a graphite laminate. Specific examples of the heating and pressurizing include lamination and pressing. For the present invention, lamination components are suitably pressed for adhesion. Pressing allows a stack of many layers such as ten layers or more to adhere to each other in one operation. Further, pressurizing lamination components for several seconds or more while heating the lamination components can prevent air from remaining in the graphite laminate as a result of softening of the adhesive layers and the pressurizing, thereby making it possible to reduce the contact thermal resistance between the graphite sheets.

The temperature for the heating and the pressure for the pressurizing are not limited to any particular values, and can be selected as appropriate in correspondence with the material of the adhesive layers.

The rate of the compression for a laminate through heating and pressurizing is not limited to any particular value, but is preferably less than 1, more preferably not more than 0.97, even more preferably not more than 0.96, even more preferably not more than 0.95, even more preferably not more than 0.92, even more preferably not more than 0.90. In a case where the compression rate, that is, (thickness of graphite laminate)/(thickness of stack as raw material), is less than 1, it means that the adhesive layers are deformed while the graphite sheets and the adhesive layers are disposed on top of each other. In this case, the graphite sheets come into contact with each other more easily, making it possible to produce a graphite laminate having a thermal conductivity close to the theoretical thermal conductivity.

The number of graphite sheets (disposed layers) to be included in a graphite laminate is not less than 3 and not more than 500, preferably not less than 5 and not more than 400.

A graphite laminate in accordance with the present invention is distinct from the technique disclosed in Patent Literature 1, which is intended to dispose as many as 1000 or more graphite sheets on top of each other and slice the disposed lamination components in a longitudinal direction to produce sheet-shaped graphite again. The present invention includes temporarily producing the above-described laminate in order to produce a rod-shaped heat transporter having a shape, strength, and size that are necessary to transport heat in a desired in-plane direction. A graphite laminate in accordance with the present invention is thus distinct from the technique disclosed in Patent Literature 1, which is intended to achieve an orientation in an up-down direction. Further, a graphite laminate in accordance with the present invention, unlike the technique disclosed in Patent Literature 1 (with which the final product is a sheet), does not need an excessively large number of graphite sheets to be disposed on top of each other.

Next, a rod-shaped heat transporter is cut out from the laminate to have a desired shape and size that are suitable for use as a thermal highway. This method makes it possible to easily produce a rod having a bent portion described later. Specifically, the method includes punching out a rod with a bent portion from the laminate for the production. The cutting can be carried out with use of a cutter, a blade saw such as a peripheral cutting edge, a laser, a water jet, a wire saw, or the like.

Another method includes (i) heating and pressurizing lamination components to product a graphite laminate, (ii) placing the graphite laminate between a pair of pressurizing jigs (with a protruding member and a depressed member), (iii) pressurizing the graphite laminate with use of the pair of pressurizing jigs to prepare a graphite laminate having a bent portion, and (iv) cutting out a rod from the graphite laminate having a bent portion.

A rod-shaped heat transporter of the present invention may be so bent as to have at least one bent portion. A bent portion allows a heat transporter to be in the shape of a rod with which heat generated by a heat generator in an electronic device is transported directly and efficiently to a low-temperature portion (heat transport destination), thereby increasing the degree of freedom of designing a rod shape. This configuration is particularly effective in a case where a portion with a low temperature cannot necessarily be connected with a heat source in a straight line due to the specifications of the electronic device. The above configuration can, in other words, increase the degree of freedom of arranging a heat source and a lower temperature portion relative to each other.

As described above, the use of graphite as a material for a heat transporter advantageously allows the heat transporter to be freely designed in the shape of a rod suitable as a thermal highway.

The number of bent portions in a rod-shaped heat transporter is not limited to any particular value, and can be any desired number.

The angle formed by the bent portion is not limited to any particular value. The bent portion may have a radius of curvature of not less than 2 mm, not less than 5 mm, not less than 8 mm, not less than 10 mm, or not less than 20 mm. The maximum value of the radius of curvature is not limited to any particular value, and may be, for example, 100 mm, 90 mm, 80 mm, 70 mm, 60 mm, 50 mm, 40 mm, 30 mm, or 20 mm. The maximum value of the radius of curvature may, needless to say, be a value larger than 100 mm.

The rod-shaped heat transporter is preferably coated with a resin (for example, polyethylene terephthalate [PET], polyethylene [PE], or polyimide [PI]) or a metal (for example, copper, nickel, or gold). A graphite sheet is a layered compound. Thus, rubbing a graphite sheet is likely to cause graphite powder to fall. Since a graphite sheet has an electrical conduction property, graphite powder falling as above causes a short circuit in the electronic device.

Coating the rod-shaped heat transporter can prevent graphite powder from falling from a graphite sheet, thereby preventing a short circuit in the electric device. Further, coating the rod-shaped heat transporter increases its strength and can prevent delamination.

The rod-shaped heat transporter is coated preferably with a metal for a better thermal conduction property and increased strength. The method for coating the rod-shaped heat transporter with a metal is not limited to any particular one. Examples of the method include vapor deposition, sputtering, and plating. Among these examples, plating is preferable because it allows for formation of a metal layer having higher adhesiveness.

The rod-shaped heat transporter may be coated with a coating film having any thickness. The thickness is preferably not less than 0.5 μm and not more than 15 μm, more preferably not less than 1 μm and not more than 10 μm, even more preferably not less than 2 μm and not more than 7 μm. A coating film having a thickness of not less than 0.5 μm protects a rod-shaped heat transporter more effectively, allowing the rod-shaped heat transporter to be more resistant to, for example, a mechanical scratch and rub. A coating film having a thickness of not more than 15 μm allows the rod-shaped heat transporter to have a better thermal conduction property.

A heat transporter of the present invention can replace conventional heat pipes, and is usable as a thermal highway in an electronic device. The rod-shaped heat transporter is so placed as to have one end connected to a heat generator such as a CPU and the other end connected to a cooling portion. The term “heat generator” used to describe the present invention refers not only to a heat generating object itself such as a CPU, but also to a portion near the heat generating object, the portion being influenced by heat generated by the CPU. The term “low-temperature site” refers to a site having a temperature lower than the temperature of the high-temperature site described above. Heat is preferably transported to a portion as far away as possible from the heat generator. Stated differently, the low-temperature site is preferably positioned far away from the high-temperature site.

A heat transporter of the present invention is, as described above, suitably usable for transport of heat from one portion to another in the same plane.

A rod-shaped heat transporter of Embodiment A, which is capable of transporting heat in a fixed amount regardless of a change in the temperature of a heat generator, is advantageously capable of transporting heat highly stably and not limited in terms of what thermal environment the rod-shaped heat transporter is usable in. Further, the rod-shaped heat transporter, which is capable of transporting a large amount of heat, transmits most heat to a low-temperature site for a greater cooling effect. The rod-shaped heat transporter of Embodiment A is thus suitably usable as a heat transporter for use in, for example, a smart phone, a tablet computer, and a fanless laptop personal computer, in each of which smaller, higher performance CPUs generate large amounts of heat. The rod-shaped heat transporter of Embodiment A can replace conventional heat pipes. In such cases, the rod-shaped heat transporter not only has an excellent heat transport capability, but also prevents dryouts from occurring as a result of a change of a use condition.

### Embodiment B

[B-1. Graphite Laminate]

A graphite laminate of Embodiment B is a graphite laminate including graphite sheets and adhesive layers disposed alternately on top of each other (or a graphite laminate in which graphite sheets and adhesive layers are disposed alternately on top of each other). The adhesive layers may each contain at least one of a thermoplastic resin and a thermosetting resin. Further, the adhesive layers may each have a water absorption rate of not more than 2% and a thickness of less than 15 μm. The graphite sheets may be included in the graphite laminate in a number of not less than 3. The graphite laminate may further be produced by compression of a stack of the graphite sheets and the adhesive layers arranged alternately. The thickness of each adhesive layer refers to that of each adhesive layer as it is incorporated in a graphite laminate as a finished product, but not to that of each adhesive layer before it is incorporated in a graphite laminate as a finished product. The thickness of each adhesive layer as it is incorporated in a graphite laminate as a finished product is substantially equal to that of each adhesive layer before it is incorporated in a graphite laminate as a finished product.

A graphite laminate of Embodiment B is a graphite laminate including graphite sheets and adhesive layers disposed alternately on top of each other (or a graphite laminate in which graphite sheets and adhesive layers are disposed alternately on top of each other). The adhesive layers may each contain at least one of a thermoplastic resin and a thermosetting resin. The adhesive layers may each have a water absorption rate of not more than 2%. The graphite laminate may be produced by compression of a stack of the graphite sheets and the adhesive layers arranged alternately. The graphite sheets may be included in the graphite laminate in a number of not less than 3. The graphite laminate may be configured such that the adhesive layers each have a thickness of less than 15 μm.

A graphite laminate of Embodiment B is a graphite laminate including graphite sheets and adhesive layers disposed alternately on top of each other (or a graphite laminate in which graphite sheets and adhesive layers are disposed alternately on top of each other). The adhesive layers may each contain at least one of a thermoplastic resin and a thermosetting resin. Further, the adhesive layers may each have a thickness of less than 15 μm. The graphite sheets may be included in the graphite laminate in a number of not less than 3. The graphite laminate may have a water absorption rate of not more than 0.25% (preferably not more than 0.2%, more preferably not more than 0.1%).

The expression “produced by compression” as used herein indicates that the total thickness of the materials after the compression is smaller than the total thickness of the materials before the compression. Something “produced by compression” also encompasses in its scope a graphite sheet having a surface infiltrated with a component of an adhesive layer. Whether a graphite laminate has been “produced by compression” can be determined by, for example, (i) comparison between the thickness of the graphite laminate before the compression process and the thickness of the graphite laminate after the compression process or (ii) observation of the interface between layers in the graphite laminate under a scanning electron microscope (SEM). Specifically, the method (ii) includes, for example, observing the interface between a graphite sheet and an adhesive layer of a graphite laminate under a SEM and determining that the graphite laminate has been produced by compression if the interface is not in a straight line.

The graphite laminate of the present invention may be bent so as to have at least one bent portion. The graphite laminate of the present invention may, in other words, be prepared through bending of an unbent graphite laminate of the present invention so that the graphite laminate has a bent portion.

The following description will discuss a graphite laminate as well as graphite sheets and adhesive layers included in the graphite laminate.

[B-1-1. Graphite Laminate]

(Basic Structure of Graphite Laminate)

A graphite laminate includes graphite sheets and adhesive layers disposed alternately on top of each other. The graphite sheets and the adhesive layers may be separated by another component, and may not be separated by another component.

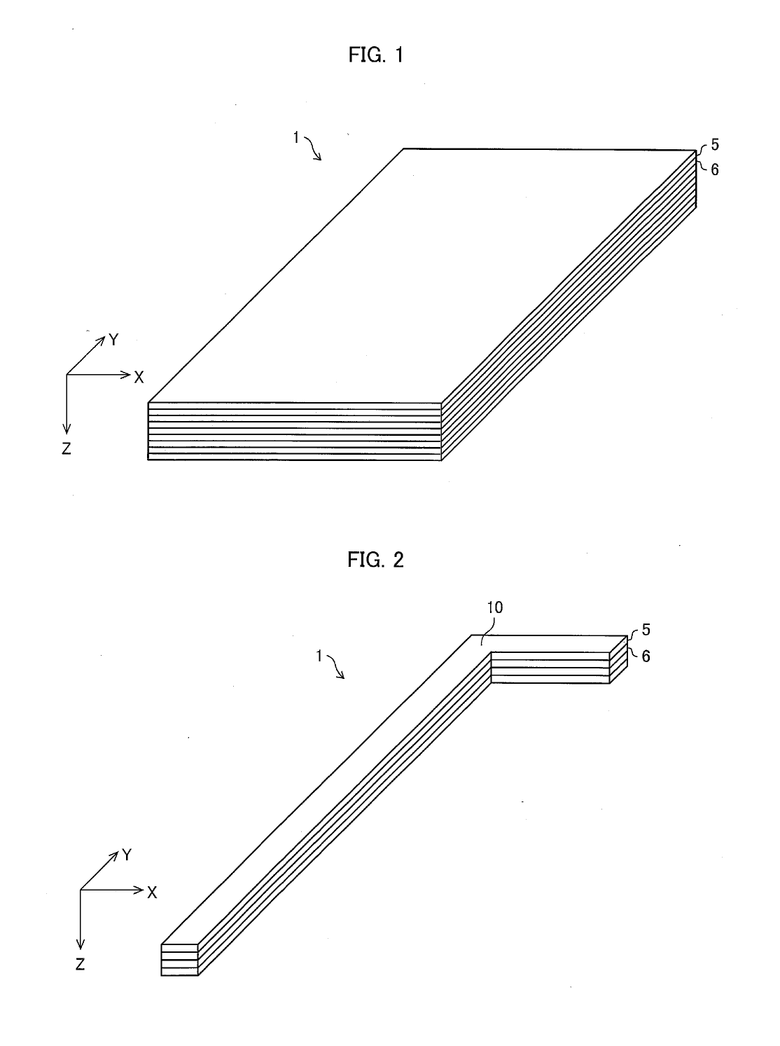

FIG. 1 is a diagram illustrating a basic structure of a graphite laminate. As illustrated in FIG. 1, a graphite laminate 1 includes graphite sheets 5 and adhesive layers 6 each having a surface defined by an X axis and a Y axis, which is orthogonal to the X axis. The surface is crossed at right angles by a Z axis. The graphite sheets 5 and the adhesive layers 6 are disposed alternately on top of each other along the Z axis in such a manner that the respective surfaces overlap with each other. The graphite laminate 1 is thus configured. As mentioned above, the X axis and the Y axis cross each other at an angle of 90°.

The expression “in such a manner that the respective surfaces overlap with each other” as used herein intends to mean a state where, as illustrated in FIG. 1, at least a portion of the surface of each graphite sheet 5 overlaps with at least a portion of the surface of each adjacent adhesive layer 6 when the laminate 1 is viewed in the Z-axis direction.

The respective surfaces of the graphite sheets 5 may have a shape identical to or different from the shape of the respective surfaces of the adhesive layers 6. The respective surfaces of the graphite sheets 5, however, preferably have a shape identical to the shape of the respective surfaces of the adhesive layers 6 for a desired effect to be produced more effectively.

The respective surfaces of the graphite sheets 5 and the respective surfaces of the adhesive layers 6 may each be in the shape of a square, for example. In this case, the surfaces may each have a side extending in the X-axis direction and another side extending in the Y-axis direction to cross the above side.

The respective surfaces of the graphite sheets 5 and the respective surfaces of the adhesive layers 6 may alternatively each be in the shape of a rectangle. In this case, the rectangles may each have short sides extending in the X-axis direction and long sides extending in the Y-axis direction.

The respective surfaces of the graphite sheets 5 and the respective surfaces of the adhesive layers 6 may alternatively each be in a shape other than a square or a rectangle. In this case, it is possible that the surfaces each have its largest dimension in the Y-axis direction and that the direction orthogonal to the Y axis is the X-axis direction.

The number of graphite sheets (disposed layers) to be included in a graphite laminate can be not less than 3, preferably not less than 5, more preferably not less than 10, even more preferably not less than 15, even more preferably not less than 20. The upper limit of the number of graphite sheets is not limited to any particular value, and may be not more than 1000, not more than 500, not more than 200, not more than 100, not more than 80, or not more than 50.

The number of graphite sheets (disposed layers) is preferably not less than 3 because such a number of graphite sheets allow for production of a graphite laminate having a high heat transport capability and an excellent mechanical strength.

The number of adhesive layers to be included in a graphite laminate is not limited to any particular value, and can be selected as appropriate in correspondence with the number of graphite sheets to be included. The graphite laminate may be configured as follows, for example: (i) Adjacent graphite sheets are separated by a single adhesive layer or even two or more adhesive layers. (ii) The graphite laminate includes a graphite sheet only at the uppermost surface, only at the lowermost surface, or at each of the uppermost surface and the lowermost surface. (iii) The graphite laminate includes an adhesive layer only at the uppermost surface, only at the lowermost surface, or at each of the uppermost surface and the lowermost surface. Expressions such as “graphite sheets and adhesive layers are disposed alternately on top of each other” as used herein intend to mean both (a) a case where adjacent graphite sheets are separated by a single adhesive layer and (b) a case where adjacent graphite sheets are separated by two or more adhesive layers. In other words, an adhesive layer for the present invention may include a plurality of adhesive layers.

(Thickness of Graphite Laminate)

The thickness of the graphite laminate (that is, its dimension along the Z axis in FIG. 1) is not limited to any particular value, but is preferably not less than 0.5 mm, more preferably not less than 0.6 mm, even more preferably not less than 0.7 mm, even more preferably not less than 0.8 mm. A thickness of not less than 0.5 mm for the graphite laminate allows the graphite laminate to transport a large amount of heat and to thus be used in an electronic device that generates a large amount of heat. The upper limit of the thickness of the graphite laminate is not limited to any particular value, and may be not more than 10 mm, not more than 7.5 mm, not more than 5 mm, not more than 2.5 mm, or not more than 1 mm in order to provide an electronic device having a reduced thickness.

It is further preferable that (i) the ratio Tg/Ta of the sum (Tg) of the respective thicknesses of the individual graphite sheets to the sum (Ta) of the respective thicknesses of the individual adhesive layers is not less than 4.1 and not more than 40 (more preferably, not less than 8.0 and not more than 40, not less than 4.1 and not more than 27, or not less than 8.0 and not more than 27) and that (ii) the thickness of the graphite laminate is not less than 0.5 mm. Although graphite sheets have a good thermal conduction property, they are thin with a thickness of approximately not more than 80 μm; An individual graphite sheet does not transport a large amount of heat. For transport of a large amount of heat, it is preferable that graphite sheets are disposed on top of each other for an improved heat transport capability. Graphite sheets can be effectively disposed on top of each other with an adhesive layer in-between because adhesive layers serve as a cushion against asperities on the respective surfaces of the graphite sheets and reduce the contact thermal resistance between the graphite sheets.

Tg/Ta is preferably not less than 4.1, more preferably not less than 8.0. A Tg/Ta value of not less than 4.1 ensures that the adhesive layers (which are lower in thermal conductivity than the graphite sheets) are included in the graphite laminate at a reduced proportion, thereby allowing the graphite laminate to have a good thermal conduction property.

Tg/Ta is preferably not more than 40, more preferably not more than 27. A Tg/Ta value of not more than 40 ensures that the adhesive layers serve as a cushion against asperities on the respective surfaces of the graphite sheets and reduce the contact thermal resistance between the graphite sheets, thereby allowing the graphite laminate to have a good thermal conduction property. Further, a Tg/Ta value of not more than 40 ensures a high adhesive force between the graphite sheets, thereby making it possible to produce a graphite laminate capable of withstanding processing such as cutting and bending.

Tg/Ta is preferably within a range of not less than 1 and not more than 50 in order to moderately disperse a cutting force among the adhesive layers to reduce thickness variations at cutting positions.

(Bent Portion)

The graphite laminate may be so bent as to have at least one bent portion (for example, one or more, or two or more bent portions). A graphite laminate of Embodiment B may, in other words, be prepared through bending of an unbent graphite laminate so that the graphite laminate has a bent portion. In electronic devices, heat generated by a heat source is transferred to a low-temperature portion for heat transport. However, a portion with a low temperature cannot necessarily be connected with a heat source in a straight line. In view of that, causing the graphite laminate to have a bent portion allows heat generated by a heat source to be easily transferred to a portion having a lower temperature, thereby allowing the graphite laminate to have a further improved heat transport capability. The above configuration can, in other words, increase the degree of freedom of arrangement of a heat source and a lower temperature portion relative to each other.

The number of bent portions in the graphite laminate is not limited to any particular value, and can be any desired number.

The bent portion preferably has no junction. A bent portion having no junction allows for efficient heat transfer, thereby allowing the graphite laminate to have an improved heat transport capability. The term “junction” as used herein refers to a portion that breaks the structural continuity of a single graphite sheet. While the structural continuity between adjacent graphite sheets can be broken by an intervening adhesive layer, this is not a “junction” for the sake of the present specification.

The specific shape of the bent portion is not limited to any particular one, and may be, for example, one of the following shapes (a) to (c):

(a) a first bent portion, which is formed by bending the graphite laminate in the X-axis direction or Y-axis direction.

(b) a second bent portion, which is formed by bending the graphite laminate in the Z-axis direction.

(c) a third bent portion, which is formed by bending the graphite laminate in the X-axis direction or Y-axis direction and also in the Z-axis direction.

More specifically, a graphite laminate of Embodiment B may be configured to have (i) two or more bent portions, each of which is a first bent portion, a second bent portion, or a third bent portion each defined above, or (ii) one or more bent portions, each of which is a third bent portion defined above. The graphite laminate of Embodiment B is, needless to say, not limited in configuration to (i) or (ii) above.

A first bent portion and a second bent portion are each formed by bending an unbent graphite laminate in a planar manner (in other words, two-dimensionally) at a desired angle, whereas a third bent portion is formed by bending an unbent graphite laminate spatially (in other words, three-dimensionally) at desired angles.

FIG. 2 illustrates an example graphite laminate having a first bent portion. The graphite laminate 1 illustrated in FIG. 2 has a bent portion 10 (first bent portion), at which the graphite laminate 1 is bent in the X-axis direction and/or Y-axis direction. The angle at which the graphite laminate 1 is bent is not limited to any value; The graphite laminate 1 can be bent at a desired angle.

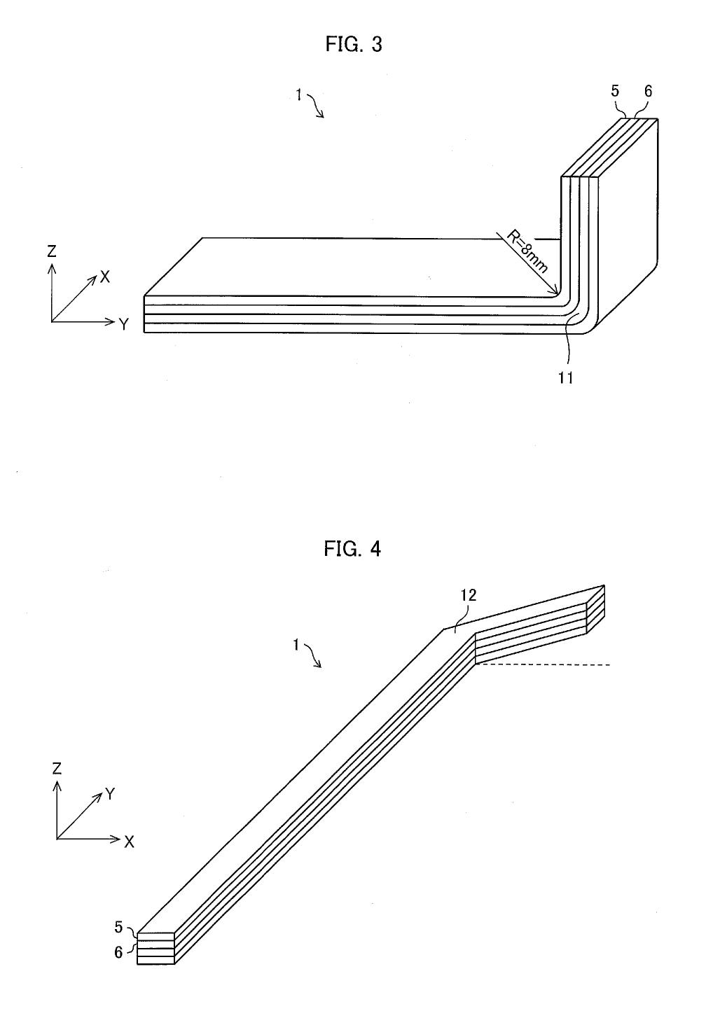

FIG. 3 illustrates an example graphite laminate having a second bent portion. The graphite laminate 1 illustrated in FIG. 3 has a bent portion 11 (second bent portion), at which the graphite laminate 1 is bent in the Z-axis direction. The angle at which the graphite laminate 1 is bent is not limited to any value; The graphite laminate 1 can be bent at a desired angle.

FIG. 4 illustrates an example graphite laminate having a third bent portion. The graphite laminate 1 illustrated in FIG. 4 has a bent portion 12 (third bent portion), at which the graphite laminate 1 is bent in the X-axis direction and/or Y-axis direction and also in the Z-axis direction. The angle at which the graphite laminate 1 is bent is not limited to any value; The graphite laminate 1 can be bent at a desired angle.

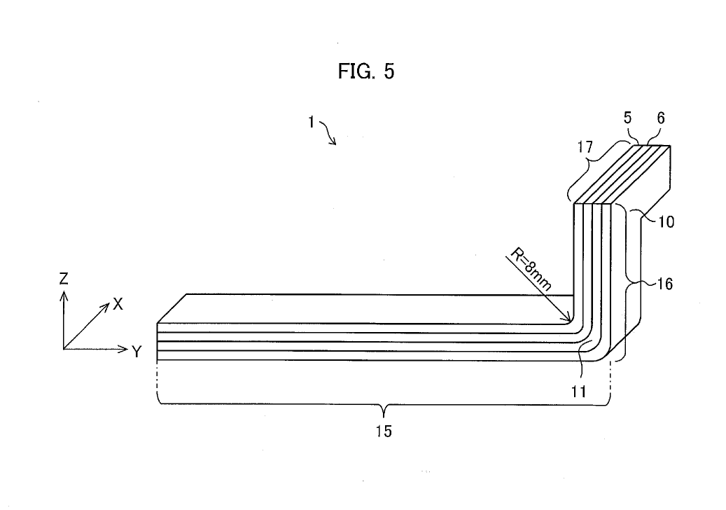

FIG. 5 illustrates an example graphite laminate having a plurality of bent portions. The graphite laminate 1 illustrated in FIG. 5 has a bent portion 11 (second bent portion), at which the graphite laminate 1 is bent in the Z-axis direction, and a bent portion 10 (first bent portion), at which the graphite laminate 1 is bent in the X-axis direction. More specifically, the graphite laminate illustrated in FIG. 5 has (i) a region 15, which extends in the Y-axis direction, (ii) a region 16, which extends in the Z-axis direction, and (iii) a region 17, which extends in the X-axis direction. The regions 15 and 16 share a boundary at a second bent portion, whereas the regions 16 and 17 share a boundary at a first bent portion. The angle at which the graphite laminate 1 is bent is not limited to any value; The graphite laminate 1 can be bent at a desired angle. FIG. 5 shows an X axis, a Y axis, and a Z axis that are defined on the basis of an unbent, planar graphite laminate. The X axis, the Y axis, and the Z axis that are defined before a graphite laminate is bent can be regarded as such even after the graphite laminate is bent. In other words, the direction in which graphite sheets are disposed may be regarded as corresponding to a Z axis. For instance, in the region 16, the axis indicated as “Y axis” in FIG. 5 corresponds to a Z axis (in which graphite sheets are disposed), whereas in the region 17, the axis indicated as “Y axis” in FIG. 5 corresponds to a Z axis (in which graphite sheets are disposed).

The present specification uses (i) the expression “bent in the X-axis direction” to indicate that an unbent, planar graphite laminate present in the X-Y plane is bent in the X-axis direction at a desired angle in the X-Y plane, (ii) the expression “bent in the Y-axis direction” to indicate that an unbent, planar graphite laminate present in the X-Y plane is bent in the Y-axis direction at a desired angle in the X-Y plane, (iii) the expression “bent in the Z-axis direction” to indicate that an unbent, planar graphite laminate present in the X-Y plane is bent in the Z-axis direction (which is orthogonal to the X-Y plane) at a desired angle, and (iv) the expression “bent in the X-axis direction or Y-axis direction and also in the Z-axis direction” to indicate that an unbent, planar graphite laminate present in the X-Y plane is bent in the X-axis direction or Y-axis direction at a desired angle in the X-Y plane and that the bent, planar graphite laminate present in the X-Y plane is bent in the Z-axis direction (which is orthogonal to the X-Y plane) at a desired angle.

The first bent portion, the second bent portion, and the third bent portion may each have a non-adhering portion, at which adjacent graphite sheets do not adhere to each other with use of an adhesive layer. A later description will deal with the non-adhering portion in detail.

The angle formed by the bent portion is not limited to any particular value. The bent portion may have a radius of curvature of not less than 2 mm, not less than 5 mm, not less than 8 mm, not less than 10 mm, or not less than 20 mm. The maximum value of the radius of curvature is not limited to any particular value, and may be, for example, 100 mm, 90 mm, 80 mm, 70 mm, 60 mm, 50 mm, 40 mm, 30 mm, or 20 mm. The maximum value of the radius of curvature may, needless to say, be a value larger than 100 mm.

(Coating for Graphite Laminate)

The graphite laminate is preferably coated with a resin (for example, polyethylene terephthalate [PET], polyethylene

[PE], or polyimide [PI]) or a metal (for example, copper, nickel, or gold). A graphite sheet is a layered compound. Thus, rubbing a graphite sheet is likely to cause graphite powder to fall. Since a graphite sheet has an electrical conduction property, graphite powder falling as above causes a short circuit in the electronic device.

Coating the graphite laminate can prevent graphite powder from falling from a graphite sheet, thereby preventing a short circuit in the electric device. Further, coating the graphite laminate increases its strength and can also prevent delamination.

The graphite laminate is coated preferably with a metal for a better thermal conduction property and increased strength. The method for coating the graphite laminate with a metal is not limited to any particular one. Examples of the method include vapor deposition, sputtering, and plating. Among these examples, plating is preferable because it allows for formation of a metal layer having higher adhesiveness.

The graphite laminate may be coated with a coating film having any thickness. The thickness is preferably not less than 0.5 μm and not more than 15 μm, more preferably not less than 1 μm and not more than 10 μm, even more preferably not less than 2 μm and not more than 7 μm. A coating film having a thickness of not less than 0.5 μm protects a graphite laminate more effectively, allowing the graphite laminate to be more resistant to, for example, a mechanical scratch and rub. A coating film having a thickness of not more than 15 μm allows the graphite laminate to have a better thermal conduction property.

(Water Absorption Rate of Graphite Laminate)

The graphite laminate may have any water absorption rate. The water absorption rate is preferably not more than 0.25%, more preferably not more than 0.20%, most preferably not more than 0.10%. A water absorption rate of not more than 0.25% for the graphite laminate allows for a smaller amount of gas (outgas) generated as a result of vaporization of water in the graphite laminate when the graphite laminate is being produced or when the graphite laminate is in use as a heat transport mechanism. The above arrangement thus prevents a void from being formed in the graphite laminate. The water absorption rate of a graphite laminate can be calculated in accordance with the following formula:

(Water absorption rate of graphite laminate)=(water absorption rate of adhesive layers)×(thickness of adhesive layers)/[(thickness of adhesive layers)+(thickness of graphite sheets)] (Formula)

(Hardness of Graphite Laminate)

In a case where (i) one end of the graphite laminate has been so fixed that the graphite laminate is horizontal with respect to the ground and (ii) a load has been imposed on that cross section of the graphite laminate which is located 4 cm away from the fixed end, the load being 0.7 g per 1 mm² of the cross section, the cross section is displaced by not more than 15 mm, preferably not more than 14 mm, more preferably not more than 13 mm, even more preferably not more than 12 mm, even more preferably not more than 11 mm, even more preferably not more than 10 mm, even more preferably not more than 9 mm, even more preferably not more than 8 mm, even more preferably not more than 7 mm, even more preferably not more than 6 mm, even more preferably not more than 5 mm, even more preferably not more than 4 mm, even more preferably not more than 3 mm, even more preferably not more than 2 mm, most preferably not more than 1 mm. The graphite laminate is preferably as hard as possible; in other words, the shape of the graphite laminate is changed preferably as little as possible, for better handleability of the graphite laminate.

[B-1-2. Graphite Sheet]

(Kind of Graphite Sheet)

The graphite sheet for the present invention is not limited to any particular kind, and can be, for example, a polymeric graphite sheet or a graphite sheet produced by expanding natural graphite as a raw material. A polymeric graphite sheet is preferable for the following reason: It has high strength and good thermal conduction property, and can thus help provide a graphite laminate having a higher strength and a higher heat transport capability.

(Method for Producing Graphite Sheet)

The method for producing a graphite sheet for the present invention is not limited to any particular one.

A first method for producing a graphite sheet for the present invention is a method of expanding natural graphite as a raw material. Specifically, the first method includes (i) immersing graphite powder in an acid (for example, sulfuric acid) to prepare a graphite intercalation compound, (ii) heat-treating and foaming the graphite intercalation compound to release a graphite layer, (iii) washing the graphite layer for removal of the acid to prepare a thin film formed of graphite powder, and (iv) shaping the thus-prepared thin film with use of pressure rolls to produce a graphite sheet.

A second method for producing a graphite sheet for the present invention is a method of heat-treating a polymeric film (for example, polyimide resin) to prepare a polymeric graphite sheet. Specifically, the second method includes (i) preheating a polymeric film as a starting material at a temperature of approximately 1000° C. under reduced pressure or in an atmosphere of an inert gas for carbonization to produce a carbonized film, and (ii) heat-treating the carbonized film at a temperature of not less than 2800° C. in an atmosphere of an inert gas for graphitization to produce a graphite sheet having a good graphite crystal structure and an excellent thermal conduction property.

(Thermal Conductivity of Graphite Sheet in Surface Direction)

A graphite sheet for the present invention has a thermal conductivity of preferably not less than 1000 W/(m·K), more preferably not less than 1100 W/(m·K), even more preferably not less than 1200 W/(m·K), even more preferably not less than 1300 W/(m·K), in the surface direction.

The use of a graphite sheet having a thermal conductivity of not less than 1000 W/(m·K) in the surface direction makes it possible to produce a graphite laminate having a higher heat transport capability. A graphite sheet having a thermal conductivity of not less than 1000 W/(m·K) in the surface direction will have a thermal conduction property that is three or more times greater than that of a metal material (for example, copper or aluminum). Thus, in a case where a graphite laminate includes graphite sheets in a number that allows the graphite laminate to have a heat transport capability equivalent to that of a heat transporter made of copper, aluminum, or the like, the graphite laminate has a significantly reduced weight, thereby contributing to a less heavy electronic device.

The method for calculating the thermal conductivity of a graphite sheet in the surface direction is described below in the Examples section, and is not described here.

(Thickness of Graphite Sheet)

The graphite sheet for the present invention may have any thickness. The thickness is, however, preferably not less than 10 μm and not more than 200 μm, more preferably not less than 12 μm and not more than 150 μm, even more preferably not less than 15 μm and not more than 100 μm, even more preferably not less than 20 μm and not more than 80 μm. A thickness of not less than 10 μm for the graphite sheet allows for a reduced number of graphite sheets to be included in the graphite laminate, and also allows for a reduced number of adhesive layers (which are low in thermal conductivity) to be included. A thickness of not more than 200 μm for the graphite sheet allows the graphite laminate to have a high thermal conductivity.

The method for calculating the thickness of a graphite sheet is described below in the Examples section, and is not described here.

(Electrical Conductivity of Graphite Sheet)

The graphite sheet for the present invention may have any electrical conductivity. The electrical conductivity is, however, preferably 1000 S/cm to 25000 S/cm, more preferably 2000 S/cm to 20000 S/cm, even more preferably 5000 S/cm to 18000 S/cm, even more preferably 10000 S/cm to 17000 S/cm. An electrical conductivity of 1000 S/cm to 25000 S/cm for the graphite sheet can ensure moderate adhesiveness and moderate slidability between graphite sheets and adhesive layers, and is preferably suitable for disposing adhesive layers (in particular, thin adhesive layers) and graphite sheets on top of each other.

The method for calculating the electrical conductivity of a graphite sheet is described below in the Examples section, and is not described here.

(Density of Graphite Sheet)

The graphite sheet for the present invention may have any density. The density is, however, preferably not less than 0.8 g/cm³, more preferably not less than 1.0 g/cm³, even more preferably not less than 1.5 g/cm³, even more preferably not less than 2.0 g/cm³, even more preferably not less than 2.5 g/cm³. A density of not less than 0.8 g/cm³ for the graphite sheet is preferable because a graphite sheet having such a density has an excellent self-supporting property.

The method for calculating the density of a graphite sheet is described below in the Examples section, and is not described here.

(Surface Roughness of Graphite Sheet)

The graphite sheet for the present invention may have any surface roughness. The surface roughness is, however, preferably not more than 5 μm, more preferably less than 2.0 μm, even more preferably not more than 1.5 μm, even more preferably less than 1.0 μm. A surface roughness of not more than 5 μm for the graphite sheet can ensure moderate adhesiveness and moderate slidability between graphite sheets and adhesive layers, and is preferably suitable for disposing adhesive layers (in particular, thin adhesive layers) and graphite sheets on top of each other.

The method for calculating the surface roughness of a graphite sheet is described below in the Examples section, and is not described here.

(Pores of Graphite Sheet)

In a case where (i) many graphite sheets are disposed on top of each other (for example, ten or more layers) or where (ii) graphite sheets each having a large area are disposed on top of each other (for example, graphite sheets each having the shape of a square with a side of not less than 100 mm), causing the graphite sheets to adhere to each other by heating and pressurizing may lead to expansion of gas slightly generated from adhesive layers or air remaining between layers in small amounts, with the possible result of a partial bulge. This is due to the great gas barrier property of graphite sheets.

In view of that, the graphite sheet for the present invention preferably has pores that allow gas to pass therethrough. The graphite sheet has pores on a surface thereof at a proportion of preferably not less than 0.5%, more preferably not less than 1%, of the surface area. The shape of the pores is not limited to any particular one, and can be a perfect circle, an ellipse, a triangle, a quadrangle, or the like as appropriate.

[B-1-3. Adhesive Layer]

(Kind of Adhesive Layer)

The adhesive layer for the present invention can be made of a thermosetting resin or a thermoplastic resin. The adhesive layer may be made of a material in the form of a film or varnish.

Examples of the thermosetting resin include polyurethane (PU), phenol resin, urea resin, melamine-based resin, guanamine resin, vinylester resin, unsaturated polyester, Oligoester acrylate, diallyl phthalate, DKF resin (kind of resorcinol-based resin), xylene resin, epoxy resin, furan resin, polyimide (PI)-based resin, polyetherimide (PEI) resin, polyamide imide (PAI) resin, and polyphenylene ether (PPE). Among these examples, epoxy resin, urethane resin, and polyphenylene ether (PPE) are preferable because they offer wide varieties of material options and have excellent adhesiveness with respect to a graphite sheet.

Examples of the thermoplastic resin include acryl, ionomer, isobutylene maleic anhydride copolymer, acrylonitrile-acryl-styrene copolymer (AAS), acrylonitrile-ethylene-styrene copolymer (AES), acrylonitrile-styrene copolymer (AS), acrylonitrile-butadiene-styrene copolymer (ABS), acrylonitrile-chlorinated polyethylene-styrene copolymer (ACS), methyl methacrylate-butadiene-styrene copolymer (MBS), ethylene-vinyl chloride copolymer, ethylene-vinyl acetate copolymer (EVA), ethylene-vinyl acetate copolymer (EVA)-based resin, ethylene vinyl alcohol copolymer (EVOH), polyvinyl acetate, chlorinated vinyl chloride, chlorinated polyethylene, chlorinated polypropylene, carboxy vinyl polymer, ketone resin, norbornene resin, vinyl propionate, polyethylene (PE), polypropylene (PP), polymethylpentene (TPX), polybutadiene, polystyrene (PS), styrene-maleic anhydride copolymer, methacryl, ethylene-methacrylic acid copolymer (EMAA), polymethylmethacrylate (PMMA), polyvinyl chloride (PVC), polyvinylidene chloride, polyvinyl alcohol (PVA), polyvinyl ether, polyvinyl butyral, polyvinyl formal, cellulose-based resin, nylon 6, nylon 6 copolymer, nylon 66, nylon 610, nylon 612, nylon 11, nylon 12, copolymer nylon, nylon MXD, nylon 46, methoxymethylated nylon, aramid, polyethylene terephthalate (PET), polybutylene terephthalate (PBT), polycarbonate (PC), polyacetal (POM), polyethylene oxide, polyphenylene ether (PPE), modified polyphenylene ether (PPE), polyether ether ketone (PEEK), polyether sulfone (PES), polysulfone (PSO), polyamine sulfone, polyphenylene sulfide (PPS), polyalylate (PAR), poly-para-vinyl phenol, poly-para-methylene styrene, polyallylamine, aromatic polyester, liquid crystal polymer, polytetrafluoroethylene (PTFE), tetrafluoroethylene-ethylene copolymer (ETFE), tetrafluoroethylene-hexafluoropropylene copolymer (FEP), tetrafluoroethylene-hexafluoro propylene-perfluoroalkyl vinyl ether copolymer (EPE), tetrafluoroethylene-perfluoroalkyl vinyl ether copolymer (PFA), polychlorotrifluoroethylene copolymer (PCTFE), ethylene-chlorotrifluoroethylene copolymer (ECTFE), polyvinylidene fluoride (PVDF)-based resin, polyvinyl fluoride (PVF), polyethylene naphthalate (PEN), and polyester resin.

The adhesive layer is preferably made of an aromatic material (for example, polyester adhesive and polyethylene terephthalate). With this arrangement, disposing graphite sheets and adhesive layers on top of each other allows the adhesive layers to be substantially parallel to the respective surfaces of the graphite sheets and prevents the graphite sheets from being easily disrupted, thereby making it possible to produce a graphite laminate having a thermal conductivity close to the theoretical value.

The thermoplastic resin and the thermosetting resin each have a glass transition point of preferably not lower than 50° C., more preferably not lower than 60° C., even more preferably not lower than 70° C., even more preferably not lower than 80° C. A glass transition point of not lower than 50° C. makes it possible to more effectively prevent air from remaining in a graphite laminate to be produced. A material such as an acrylic adhesive and a rubber sheet which material has a glass transition point of not lower than 50° C. is preferable because such a material provides adhesive layers that are high in strength and that are unlikely to have property variations. Examples of a material having such a glass transition temperature include polyethylene terephthalate (PET), polystyrene (PS), and polycarbonate (PC).

The method for calculating the glass transition point of an adhesive layer is described below in the Examples section, and is not described here.

The adhesive layer may have any elastic modulus. The elastic modulus is, however, preferably high (for example, an elastic modulus of not less than 100 MPa) to reduce thickness variations caused during a cutting operation.

(Thickness of Adhesive Layer)

The adhesive layer for the present invention may have a thickness of less than 15 μm. Specifically, the adhesive layer for the present invention has a thickness of preferably not less than 0.1 μm and less than 15 μm, more preferably not less than 1 μm and less than 15 μm. More specifically, the adhesive layer for the present invention has a thickness of preferably not less than 0.1 μm and less than 10 μm, more preferably not less than 1 μm and less than 10 μm, even more preferably not less than 1 μm and not more than 9 μm, even more preferably not less than 1 μm and not more than 7 μm. In a case where an adhesive layer has a thickness of less than 15 μm (more preferably less than 10 μm), the adhesive layer has a thermal conductivity much lower than that of a graphite sheet. Controlling the thickness of the adhesive layer to less than 15 μm (more preferably less than 10 μm) allows the adhesive layer to transmit heat efficiently without inhibiting heat transfer between graphite sheets. In a case where an adhesive layer has a thickness of not less than 1 μm, the adhesive layer is capable of serving as a cushion against asperities on graphite sheet surfaces to reduce the contact thermal resistance between the adhesive layer and a graphite sheet for efficient heat transmission. Further, an adhesive layer having a thickness of not less than 1 μm is capable of exhibiting good adhesiveness. Further, an adhesive layer having the above thickness allows a graphite laminate including the adhesive layer to have a thermal conductivity close to the theoretical value.

The method for calculating the thickness of an adhesive layer is described below in the Examples section, and is not described here.

(Water Absorption Rate of Adhesive Layer and Outgas)

The adhesive layer for the present invention may have a water absorption rate of not more than 2%. More specifically, the adhesive layer for the present invention has a water absorption rate of preferably not more than 1.5%, more preferably not more than 1.0%, even more preferably not more than 0.4%, even more preferably not more than 0.1%. A water absorption rate of not more than 2% for the adhesive layer allows for a smaller amount of gas (outgas) generated as a result of vaporization of water in the graphite laminate when the graphite laminate is being produced or when the graphite laminate is in use as a heat transport mechanism. The above arrangement thus prevents a void from being formed in the graphite laminate.

The method for calculating the water absorption rate of an adhesive layer is described below in the Examples section, and is not described here.

(Dielectric Constant of Adhesive Layer)

The adhesive layer for the present invention may have any dielectric constant. The dielectric constant is, however, preferably 1.0 to 5.0, more preferably 2.0 to 4.0, even more preferably 2.5 to 3.6. A dielectric constant of 1.0 to 5.0 for the adhesive layer is preferable because such a dielectric constant causes adhesive layers to repel each other as a result of static electricity and thus allows the adhesive layers to be released from each other.

The method for calculating the dielectric constant of an adhesive layer is described below in the Examples section, and is not described here.

(Adhesive Force of Adhesive Layer)

The adhesive layer preferably expresses adhesiveness on heating and is adhesive during an adhering step. The adhesive layer can thus be made of a material such as a tackifier, an adhesive, and a polymeric film. The adhesive layer has an adhesive force of preferably not more than 1 N/25 mm, more preferably not more than 0.5 N/25 mm, at 25° C. More specifically, the adhesive layer preferably has an adhesive force of not more than 1 N/25 mm or not more than 0.5 N/25 mm at 25° C. and expresses adhesiveness on heating.

Disposing many graphite sheets on top of each other involves a high risk of air remaining between layers and the graphite sheets being wrinkled. Adhesive layers having almost no adhesiveness at room temperature allow many graphite sheets to be placed on top of each other at the same time without being wrinkled. Melting such adhesive layers by heating and causing the resin to fill the asperities of graphite sheets by pressurizing makes it possible to prepare a graphite laminate with a reduced amount of air remaining between the layers.

The method for calculating the adhesive force of an adhesive layer is described below in the Examples section, and is not described here.

(Breaking Strength of Adhesive Layer)

The adhesive layer for the present invention may have any breaking strength. The breaking strength is, however, preferably 0.1 GPa to 10 GPa, more preferably 0.2 GPa to 5.0 GPa, even more preferably 0.2 GPa to 4.7 GPa, even more preferably 1.0 GPa to 4.7 GPa. The adhesive layer preferably has a breaking strength of not less than 0.1 GPa because such a breaking strength prevents the adhesive layer from being easily broken when the films are disposed on top of each other.

The method for calculating the breaking strength of an adhesive layer is described below in the Examples section, and is not described here.

[B-2. Method for Producing Graphite Laminate]

(Basic Arrangement of Method for Producing Graphite Laminate)

A graphite laminate having a large thickness (for example, not less than 0.5 mm) in the direction in which layers are disposed on top of each other is low in flexibility and difficult to bend after the production.

In view of that, an example method for producing a graphite laminate is a method for producing a graphite laminate having a bent portion formed in advance. In a case where a process of preparing a graphite laminate is a process of producing a graphite laminate having a bent portion formed in advance, such a graphite laminate can be connected with a lower temperature portion for an improved heat transport capability.

Another example method for producing a graphite laminate is a method of (i) preparing a graphite laminate having a non-adhering portion, at which adjacent graphite sheets do not adhere to each other with use of an adhesive layer, and (ii) bending the graphite laminate at the non-adhering portion. Adjacent graphite sheets not adhering to each other with use of an adhesive layer allow the graphite laminate to remain flexible.

The graphite laminate needs to be configured such that adjacent graphite sheets adhere to each other with use of an adhesive layer at portions at which the graphite laminate is connected with a high-temperature site (that is, a site of which the temperature is raised by heat generated by a heat source) and a low-temperature site (that is, a site of which the temperature is lower than the temperature of the high-temperature site). Thus, a non-adhering portion is preferably formed at a portion other than the opposite ends of the graphite laminate (for example, a portion other than the opposite lengthwise ends), at which opposite ends the graphite laminate is connected with the high-temperature site and the low-temperature site. A non-adhering layer allows a slight gap to be formed between adjacent graphite sheets, and in the gap, air convection occurs. The non-adhering portion thus serves as a heat sink, thereby improving the cooling capability of the graphite laminate. The connection portions refer to each portion of a graphite laminate at which portion the graphite laminate is in contact with the high-temperature site or the low-temperature site.

In view of the above, a method of Embodiment B for producing a graphite laminate is a method for producing a graphite laminate in which graphite sheets and adhesive layers are disposed alternately on top of each other, the method including the steps of: (a) disposing graphite sheets and adhesive layers alternately on top of each other so as to form a stack; and (b) heating and pressurizing the stack to cause the graphite sheets and the adhesive layers to adhere to each other so as to form a graphite laminate. The step (b) may include a bent portion forming step of producing a graphite laminate having at least one bent portion.

The following description will discuss the individual steps.

(Disposing Step)

A disposing step is a step of disposing graphite sheets and adhesive layers alternately on top of each other to form a stack.

More specifically, the disposing step is a step of disposing graphite sheets and adhesive layers, each of which has a surface defined by an X axis and a Y axis, which is orthogonal to the X axis, alternately on top of each other in the direction of a Z axis, which is perpendicular to the surface, in such a manner that the respective surfaces of the graphite sheets and the adhesive layers overlap with each other to form a stack.

Specific examples of a method used during the disposing step include (i) a method of disposing graphite sheets and polymeric films alternately on top of each other or (ii) a method of preparing graphite adhesive sheets each including a graphite sheet and an adhesive layer on at least one surface of the graphite sheet and disposing the graphite adhesive sheets on top of each other.

Examples of the method (i) above include a method of disposing graphite sheets and polymeric films alternately on top of each other one by one and a method of winding up a graphite sheet and a polymeric film together around a core to form a roll and then cutting and cleaving the roll to provide a laminate of graphite sheets and polymeric films.

The method (ii) above includes first preparing graphite adhesive sheets. Graphite adhesive sheets can each be prepared by coating a graphite sheet with varnish or by laminating a graphite sheet with an adhesive film. Examples of the method of disposing graphite sheets and polymeric films on top of each other include a method of cutting the graphite adhesive sheets into a plate shape and disposing the cut graphite adhesive sheets on top of each other and a method of winding up the prepared graphite adhesive sheets around a core to form a roll and cutting and cleaving the roll.

Examples of a method for preparing an adhesive layer include a method of applying varnish to a graphite sheet and a method of disposing adhesive layers each in the form of a film and graphite sheets alternately on top of each other. In a case where a method is used of applying varnish to a graphite sheet, the varnish preferably has no tucking property after the application in order to prevent air from remaining in a graphite laminate to be produced. In a case where a method is used of disposing adhesive layers each in the form of a film and graphite sheets alternately on top of each other, a low dielectric constant for the adhesive layers each in the form of a film, which means that the adhesive layers each in the form of a film are not easily electrically charged, allows the adhesive layers each in the form of a film to be fixed to a conveyer stably with use of electrostatic force. Further, with a good electrical conduction property for the graphite sheets, in a case where the graphite sheets and the adhesive layers each in the form of a film are in close contact with each other, static electricity of the adhesive layers escape to the graphite sheets, with the result that the graphite sheets and the adhesive layers each in the form of a film are more slidable on each other and that the adhesive layers are less likely to be wrinkled.

(Adhering Step)

An adhering step is a step of (i) pressurizing (in other words, compressing), preferably (ii) heating and pressurizing (in other words, compressing), the stack formed in the disposing step to cause the graphite sheets and the adhesive layers to adhere to each other to form a graphite laminate.

Specific examples of the adhering step include lamination and pressing. For the present invention, lamination components are suitably pressed for adhesion. Pressing allows a stack of many layers such as ten layers or more to adhere to each other in one operation. Further, pressurizing lamination components for several seconds or more while heating the lamination components can prevent air from remaining in the graphite laminate as a result of softening of the adhesive layers and the pressurizing, thereby making it possible to reduce the contact thermal resistance between the graphite sheets.

The temperature for the heating and the pressure for the pressurizing are not limited to any particular values, and can be selected as appropriate in correspondence with the material of the adhesive layers.

As mentioned above, the adhering step includes heating and pressurizing (in other word, compressing) a stack formed in the disposing step. During this step, the rate of the compression of a stack is not limited to any particular value, but is preferably less than 1, more preferably not more than 0.97, even more preferably not more than 0.96, even more preferably not more than 0.95, even more preferably not more than 0.92, even more preferably not more than 0.90. In a case where the compression rate, that is, (thickness of graphite laminate)/(thickness of stack as raw material), is less than 1, it means that the adhesive layers are deformed while the graphite sheets and the adhesive layers are disposed on top of each other. In this case, the graphite sheets come into contact with each other more easily, making it possible to produce a graphite laminate having a thermal conductivity close to the theoretical thermal conductivity.

(Bent Portion Forming Step)

A bent portion may be formed during the process of producing a graphite laminate by bending a precursor of the graphite laminate or after the production of a graphite laminate by bending the graphite laminate. For instance, a bent portion may be formed as follows: After graphite sheets and adhesive layers are disposed on top of each other, that stack is heated and pressurized. This pressure is used to bend a graphite laminate being produced (in other words, a precursor of a graphite laminate). Alternatively, a bent portion may be formed as follows: After graphite sheets and adhesive layers are disposed on top of each other, that stack is heated and pressurized to form a graphite laminate. The graphite laminate thus produced is further pressurized so as to be bent.

The bent portion forming step may include at least one of the bent portion forming steps (d) to (h) below, each of which is a step of producing a graphite laminate having at least one bent portion (for example, one or more, or two or more bent portions).

(d) a first bent portion forming step, which is a step of cutting the heated and pressurized stack in the Z-axis direction to cut out a graphite laminate from the stack in such a manner that the graphite laminate has a first bent portion, which is bent in the X-axis direction or Y-axis direction.

(e) a second bent portion forming step, which is a step of pressurizing the heated and pressurized stack with use of a pressurizing jig with a bent shape in such a manner that the graphite laminate has a second bent portion, which is bent in the Z-axis direction.

(f) a third bent portion forming step, which is a step of pressurizing the heated and pressurized stack with use of a pressurizing jig with a bent shape in such a manner that the stack is bent in the Z-axis direction and then cutting the stack in the Z-axis direction to cut out a graphite laminate from the stack in such a manner that the graphite laminate has a second bent portion, which is bent in the Z-axis direction.

(g) a fourth bent portion forming step, which is a step of cutting the heated and pressurized stack in the Z-axis direction to cut out from the stack a graphite laminate precursor that is bent in the X-axis direction or Y-axis direction and pressurizing the graphite laminate precursor with use of a pressurizing jig with a bent shape in such a manner that the graphite laminate has a third bent portion, which is bent in the X-axis direction or Y-axis direction and also in the Z-axis direction.

(h) a fifth bent portion forming step, which is a step of pressurizing the heated and pressurized stack with use of a pressurizing jig with a bent shape in such a manner that the stack is bent in the Z-axis direction and cutting the stack in an oblique direction with respect to the Z-axis direction to cut out a graphite laminate from the stack in such a manner that the graphite laminate has a third bent portion, which is bent in the X-axis direction or Y-axis direction and also in the Z-axis direction.

The bent portion forming step (e) above may more specifically be the following bent portion forming step (e′):

(e′) a sixth bent portion forming step, which is a step of pressurizing the heated and pressurized stack with use of a pressurizing jig that is bent at two positions (in other words, a pressurizing jig with a shape that is bent stepwise) in such a manner that a graphite laminate has two second bent portions, each of which is bent in the Z-axis direction (in other words, two second bent portions that are bent in respective opposite directions).

Carrying out the bent portion forming step (e) above allows a graphite laminate to have a shape that is bent stepwise (see, for example, (a) of FIG. 28). Such a graphite laminate is preferable because (i) it can be placed in close contact with something that is bent stepwise and (ii) it is capable of efficient heat transfer. A graphite laminate having a stepwise shape may have any step height. The step height is, however, preferably 0.05 mm to 5.0 mm, more preferably 0.10 mm to 3.0 mm, most preferably 0.20 mm to 1.0 mm.

More specifically, the bent portion forming step may include (i) at least one of the first bent portion forming step, the second bent portion forming step, the third bent portion forming step, the fourth bent portion forming step, and the fifth bent portion forming step for production of a graphite laminate having two or more bent portions or (ii) at least one of the fourth bent portion forming step and the fifth bent portion forming step for production of a graphite laminate having one or more bent portions. The present invention is, needless to say, not limited to (i) or (ii) above.

For a simple description, the bent portion forming step may include a cutting process and/or a pressurizing process.

The two processes (namely, a cutting process and a pressurizing process) during the bent portion forming step are not likely to cause force for detaching layers in the laminate from each other. The two processes above can thus prevent air from remaining in a graphite laminate. This in turn makes it possible to easily prepare a graphite laminate having a high thermal conductivity and containing no void.

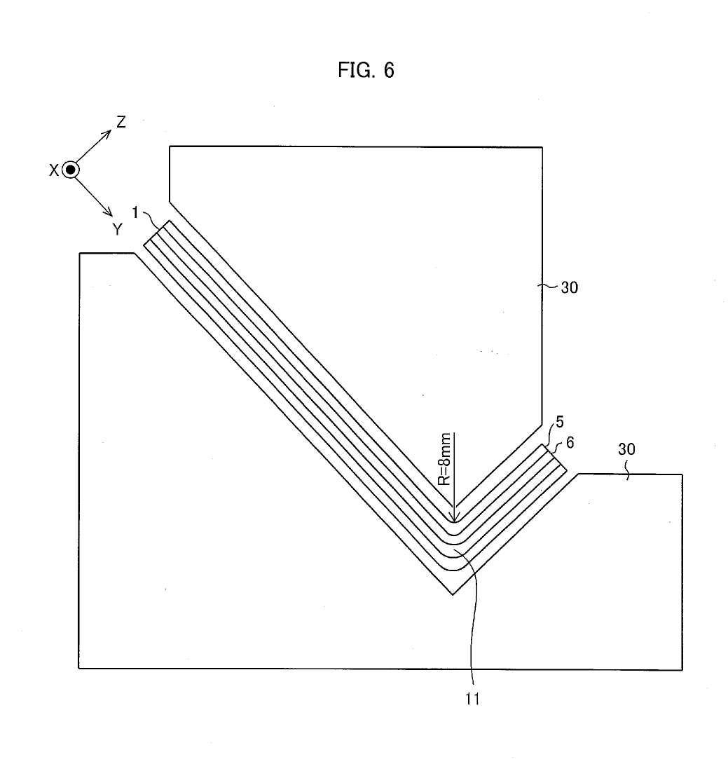

FIG. 6 illustrates an example pressurizing process. Pressurizing a graphite laminate with use of a pressurizing jig 30 including a pair of a protruding member and a depressed member as illustrated in FIG. 6 can prepare a graphite laminate 1 that is bent in the Z-axis direction so as to have a bent portion 11. Cutting out a graphite laminate with use of a cutter, a die, or the like unfortunately entails a material loss during the cutting operation. The above method can, on the other hand, prevent such a material loss.

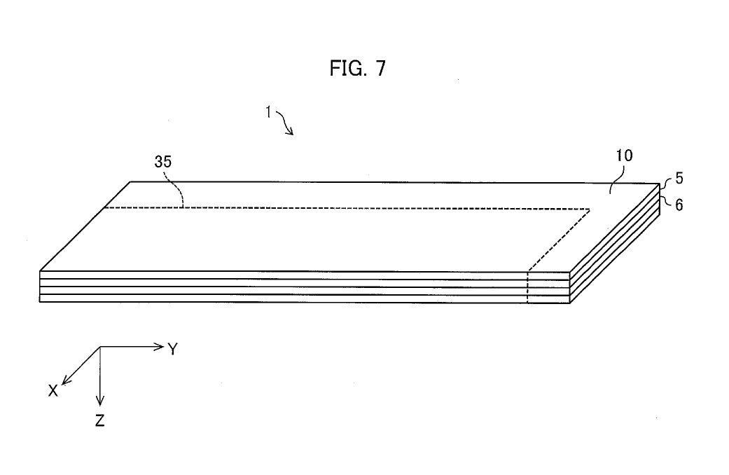

FIG. 7 illustrates an example cutting process. Cutting a graphite laminate in the Z-axis direction along the dotted line 35 as illustrated in FIG. 7 can prepare a graphite laminate 1 that is bent in the X-axis direction (or Y-axis direction) at a bent portion 10. The cutting process can be carried out with use of a cutter, a blade saw (such as a peripheral cutting edge), a laser, a water jet, a wire saw, or the like. The cutting process is, however, preferably carried out with use of a wire saw in order to prevent delamination of the graphite laminate, cut out a large number of graphite laminates at the same time, and improve the productivity. The cutting process allows a graphite laminate 1 to be bent at a sharp angle (for example, right angle).

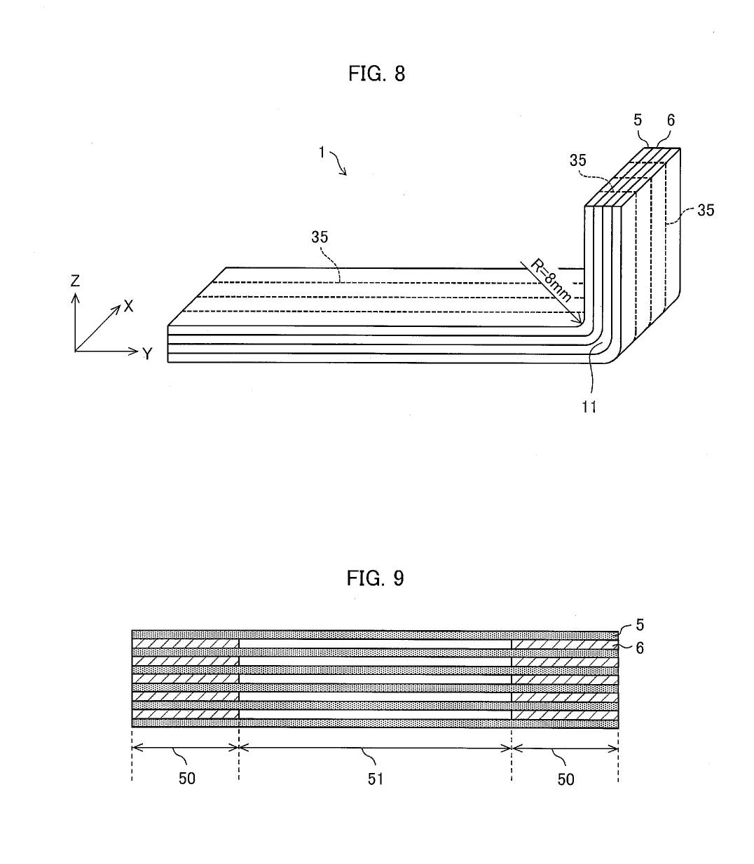

FIG. 8 illustrates an example involving a pressurizing process and a subsequent cutting process. In the example illustrated in FIG. 8, a graphite laminate is first pressurized with use of a pressurizing jig (not shown) including a pair of a protruding member and a depressed member for preparation of a graphite laminate that is bent in the Z-axis direction at a bent portion 11. The graphite laminate is then cut in the Z-axis direction along the dotted line 35 to provide a graphite laminate 1 that is bent in the Z-axis direction so as to have a bent portion 11. This method allows for production of a thin graphite laminate. Further, a graphite laminate produced by the method has an excellent heat transport capability. The pressurizing process may alternatively allow a graphite laminate to have a round bent portion (for example, with a radius of curvature of preferably not less than 8 mm).

FIG. 8 shows dotted lines 35 each in a straight line in the Y-axis direction. Cutting the graphite laminate along a dotted line 35 can prepare a graphite laminate that is bent in the Z-axis direction so as to have a second bent portion (corresponding to the third bent portion forming step).

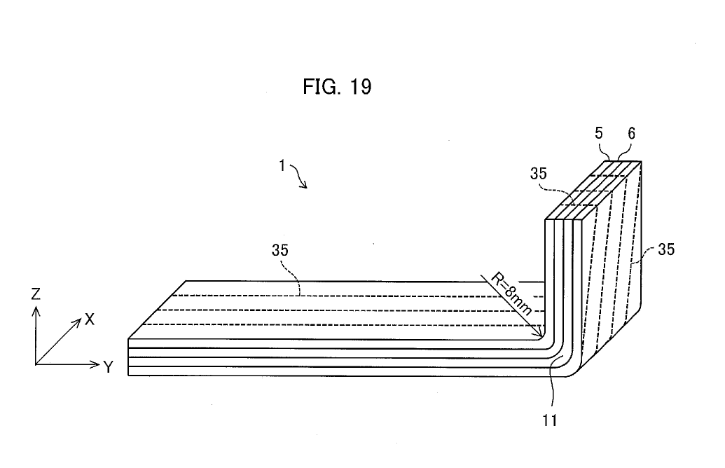

FIG. 19, in contrast, shows dotted lines 35 in a portion of a graphite laminate 1 at which portion the graphite laminate 1 is bent in the Z-axis direction, the dotted lines 35 extending obliquely with respect to the Z-axis direction. The Z-axis direction and the dotted lines 35 may form any angle. The angle can be selected as desired. Cutting the graphite laminate along a dotted line 35 can prepare a graphite laminate that is bent in the X-axis direction or Y-axis direction and also in the Z-axis direction so as to have a third bent portion (corresponding to the fifth bent portion forming step).

A person skilled in the art will easily understand the following from the present specification: Preparing a graphite laminate 1 that is bent in the X-axis direction (or Y-axis direction) at a bent portion 10 by the method illustrated in FIG. 7 and then bending the graphite laminate 1 at the bent portion 10 by the method illustrated in FIG. 6 can produce a graphite laminate 1 that is bent in the X-axis direction or Y-axis direction and also in the Z-axis direction so as to have a bent portion 12 as illustrated in FIG. 4.

The first bent portion, the second bent portion, and the third bent portion each described above may each have a non-adhering portion, at which adjacent graphite sheets do not adhere to each other with use of an adhesive layer. This arrangement makes it possible to easily bend a graphite laminate.

The following description will discuss two preferable examples of a method for forming a non-adhering portion. The present invention is, however, not limited by the description.

A first method includes (i) disposing graphite sheets and adhesive layers on top of each other in such a manner that the adhesive layers are absent at a portion intended to serve as a non-adhering portion (in other words, the adhesive layers are present at only a portion intended to serve as an adhering portion) and (ii) pressurizing the laminate over the entire surface thereof.

This method allows (i) a portion at which adhesive layers 6 are present to serve as an adhering portion 50 and (ii) a portion at which adhesive layers 6 are absent to serve as a non-adhering portion 51 (see FIG. 9). The first method thus makes it possible to easily produce a graphite laminate having a non-adhering portion 51.

A non-adhering portion 51, at which adhesive layers 6 are absent, allows a gap to be formed between adjacent graphite sheets 5, and in the gap, air convection occurs. The non-adhering portion 51 thus serves as a heat sink, thereby improving the cooling capability of the graphite laminate. Further, the absence of adhesive layers 6 at the non-adhering portion 51 allows the graphite laminate to be bent more flexibly to form a bent portion.

A second method includes (i) disposing graphite sheets and adhesive layers on top of each other in such a manner that the adhesive layers each cover the entire surface of each adjacent graphite sheet and then pressurizing a portion of the resulting stack (preferably heating and (ii) pressurizing a portion of the stack) to cause the graphite sheets to adhere to each other with use of a portion of the adhesive layers. Specifically, pressurizing, with use of a jig or the like, only a portion of the stack which portion is intended to serve as an adhering portion (preferably, pressurizing, with use of a jig or the like, only a portion of the stack which portion is intended to serve as an adhering portion while heating the portion) can produce a graphite laminate having an adhering portion and a non-adhering portion.

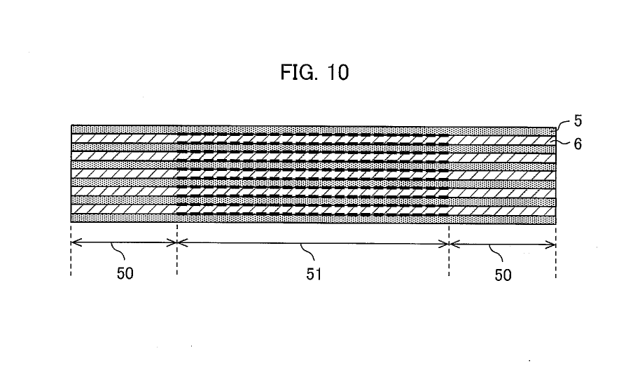

This method allows adhesive layers 6 to be present at a non-adhering portion 51 although not causing the graphite sheets 5 to adhere to each other (see FIG. 10). The second method allows a graphite laminate to have a bent portion with a higher strength. The second method also makes it possible to produce a graphite laminate that can withstand repeated bending. FIG. 10 shows dotted lines at the non-adhering portion 51 to indicate a portion at which the graphite sheets 5 and the adhesive layers 6 do not adhere to each other, in other words, at which the graphite sheets 5 do not adhere to each other.

[B-3. Heat Transport Structure]

(Basic Configuration of Heat Transport Structure)

The above-described graphite laminate of the present invention is usable mainly as a material for heat transport in an electronic device.

Specifically, a heat transport structure of Embodiment B is a heat transport structure, including: a graphite laminate of the present invention; and a heat-generating element, the graphite laminate being connected with a high-temperature site, whose temperature is raised by heat generated by the heat-generating element, and with a low-temperature site, whose temperature is lower than the temperature of the high-temperature site.

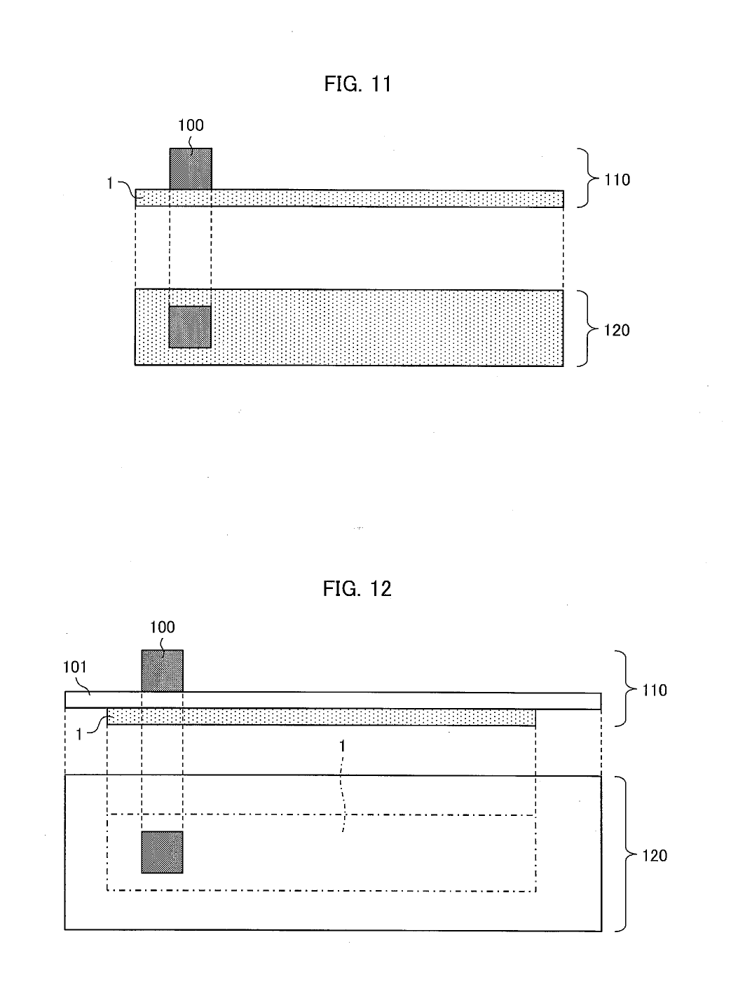

The expression “high-temperature site, which is a site whose temperature is raised by heat generated by a heat-generating element” as used herein refers to a site influenced by heat generated by a heat-generating element. For instance, as illustrated in FIG. 11, a heat-generating element 100 may be placed in contact with a graphite laminate 1. FIG. 11 shows a side view 110 and top view 120 of a composite of the heat-generating element 100 and graphite laminate 1. In FIG. 11, that surface of the heat-generating element 100 which is in contact with the graphite laminate 1 and a portion near the above surface are each an example of the “high-temperature site, which is a site whose temperature is raised by heat generated by a heat-generating element”. The heat-generating element 100 may be separated from the graphite laminate 100 by another member or a space. The term “portion near” may cover such another member and space.

A portion with which a heat-generating element is in contact and a portion near the above portion are each an example of the “high-temperature site, which is a site whose temperature is raised by heat generated by a heat-generating element” as long as such portions are influenced by heat generated by a heat-generating element. For instance, as illustrated in FIG. 12, a heat-generating element 100 may be placed in contact with a metal plate 101 placed on a graphite laminate 1. In a case where a metal plate 101 or the like is present between a graphite laminate 1 and a heat-generating element 100 as illustrated in FIG. 12, that surface of the metal plate 101 which is in contact with the heat-generating element 100 and a portion near the above surface are each an example of the “high-temperature site, which is a site whose temperature is raised by heat generated by a heat-generating element”. The metal plate 101 may be made of any metal. Examples of the metal include copper, aluminum, and nickel.

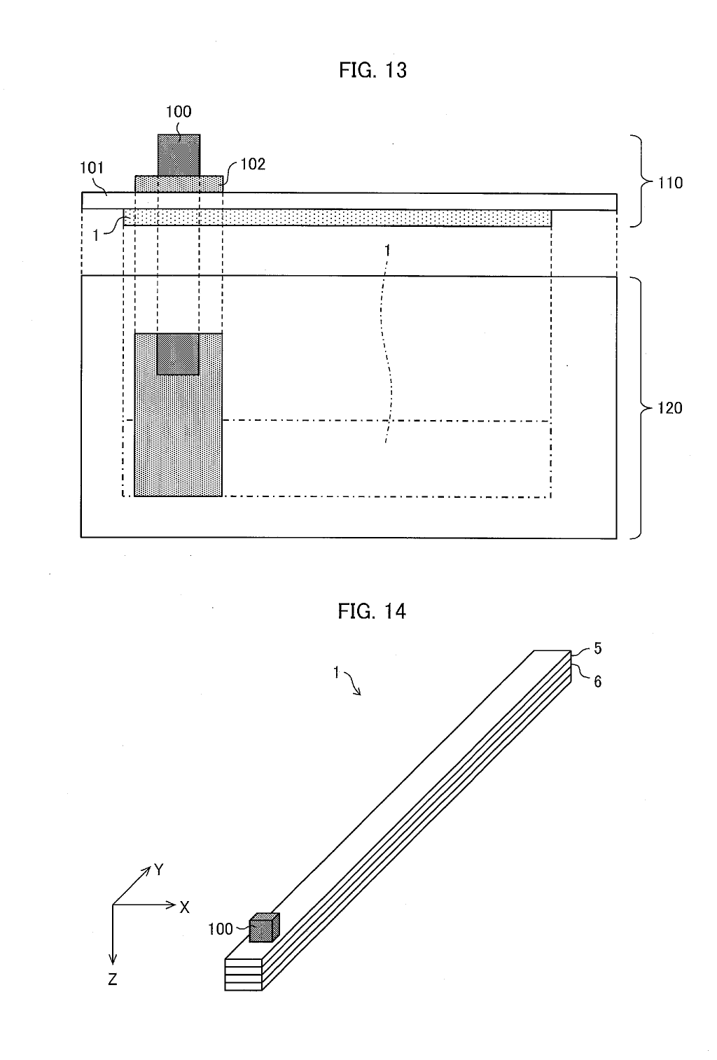

Portions other than a portion with which a heat-generating element is in contact or a portion near the above portion are also each an example of the “high-temperature site, which is a site whose temperature is raised by heat generated by a heat-generating element” as long as such other portions are influenced by heat generated by a heat-generating element. This means that the “high-temperature site, which is a site whose temperature is raised by heat generated by a heat-generating element” is neither limited to a portion with which a heat-generating element is in contact and a portion near the above portion nor limited to a portion itself at which heat generated by a heat-generating element is concentrated. As illustrated in FIG. 13, a heat-generating element 100 may be placed in contact with a heat-transferring material 102 (for example, a graphite sheet, a metal such as copper, or a heat pipe) on a metal plate 101 on a graphite laminate 1. In this case also, that surface of the metal plate 101 which is influenced by heat generated by the heat-generating element 100 and a portion near the above surface are each an example of the “high-temperature site, which is a site whose temperature is raised by heat generated by a heat-generating element”.

On the other hand, a portion with which a heat-generating element 100 is in contact and a portion near the above portion, the portions being uninfluenced by heat generated by the heat-generating element 100 as a result of thermal isolation or the like, are not examples of the “high-temperature site, which is a site whose temperature is raised by heat generated by a heat-generating element”.

The term “low-temperature site” refers to a site having a temperature lower than the temperature of the high-temperature site described above. The low-temperature site is not particularly limited in terms of detailed configuration, and may be any site having a temperature lower than the temperature of the high-temperature site.

A heat transport structure of the present embodiment can utilize the good thermal conduction property of the graphite laminate of the present invention to widely diffuse heat generated by a heat-generating element. A heat transport structure of the present embodiment, which includes a laminate (namely, the graphite laminate of the present invention), is capable of transporting a large amount of heat at the same time and transferring most heat to a low-temperature site for an improved cooling effect.

(Placement of Graphite Laminate with Respect to High-Temperature Site)

The following description will discuss how a graphite laminate is placed with respect to a high-temperature site.

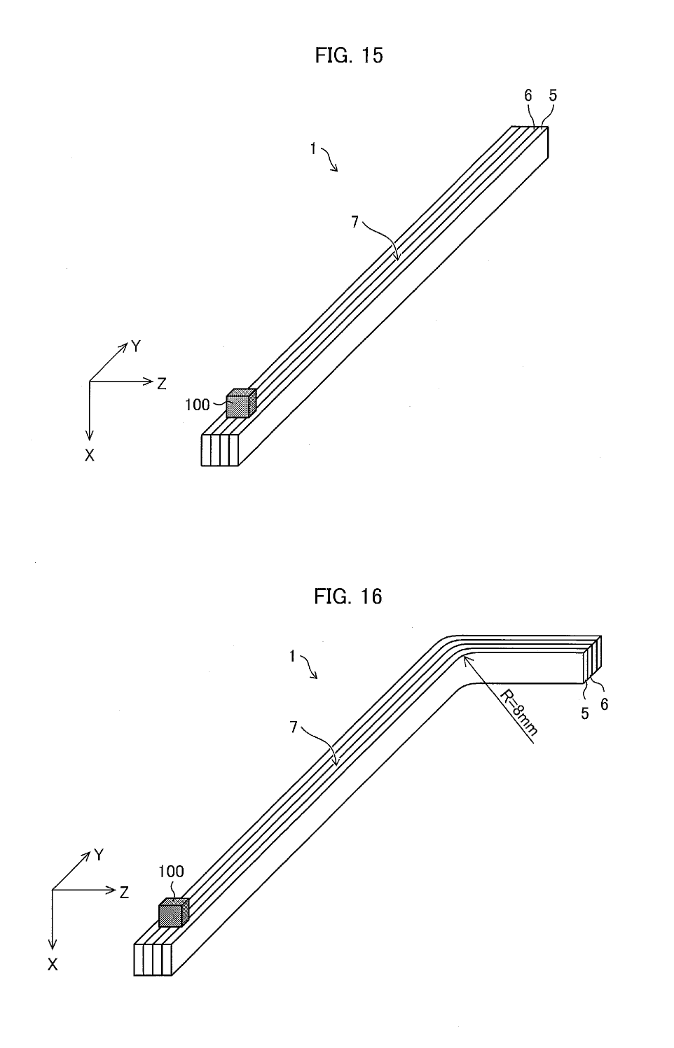

A graphite laminate may be placed with respect to a high-temperature site in such a manner that (i) as illustrated in FIG. 14, the graphite laminate 1 has a front surface facing a high-temperature site or (ii) as illustrated in FIG. 15 or 16, the graphite laminate 1 has a layered surface facing a high-temperature site. A graphite laminate is, however, preferably placed in such a manner that the graphite laminate 1 has a layered surface facing a high-temperature site.

FIGS. 15 and 16 each illustrate a layered surface 7. The term “layered surface” as used herein refers to that surface of a graphite laminate 1 which shows a pattern of stripes of graphite sheets 5 and adhesive layers 6 arranged each other. FIGS. 15 and 16 each illustrate a surface in the Y-Z plane as a layered surface. However, a surface in the X-Z plane may also be considered as a layered surface.

A graphite sheet has a thermal conductivity of 5 W/(m·K) in the thickness direction, which is lower than its thermal conductivity in the surface direction. In particular, a graphite laminate, which includes graphite sheets disposed on top of each other with adhesive layers having a lower thermal conductivity (specifically, 1 W/(m·K)) in-between, has a thermal conductivity of not more than 5 W/(m·K) in the direction in which the graphite sheets and the adhesive layers are disposed on top of each other. Further, a graphite laminate includes a large number of graphite sheets disposed on top of each other and thus has a large thickness in the disposing direction. It is thus important that a graphite laminate should (i) sufficiently transmit heat generated by a heat-generating element to a surface of the graphite laminate which surface is opposite from a heat receiving surface and (ii) transfer heat to a low-temperature site with efficient use of its entirety.

A graphite sheet has a high thermal conductivity of 1500 W/(m·K) in the surface direction. Orienting a graphite laminate so that a layered surface thereof faces a high-temperature site is preferable because such an arrangement (i) allows heat to be sufficiently transmitted also to a surface of the graphite laminate which surface is opposite from the heat receiving surface and also (ii) allows heat to be transferred to a low-temperature site with efficient use of the entire graphite laminate.

(Shape of Graphite Laminate for Case where Layered Surface Faces High-Temperature Site)

In a case where a graphite laminate is so oriented as to have a layered surface facing a high-temperature site, the graphite laminate preferably has, in the direction in which layers are disposed on top of each other, a length that is larger than the short side of a surface of the graphite laminate which surface (having the shape of, for example, a rectangle) is perpendicular to the disposing direction. More specifically, in FIGS. 15 and 16, the graphite laminate 1 preferably has a length in the Z-axis direction which length is larger than the X-axis length of the graphite laminate 1. A graphite laminate having a length in the disposing direction which length is larger than the short side of a surface of the graphite laminate which surface is perpendicular to the disposing direction allows heat to be moved efficiently from a heat receiving surface of the graphite laminate to a surface of the graphite laminate which surface is opposite to the heat receiving surface. This in turn makes it possible to transport heat to a low-temperature site more effectively.

In a case where a graphite laminate is so oriented as to have a layered surface facing a high-temperature site, the graphite laminate has a length of preferably not less than 2 mm, more preferably not less than 2.5 mm, in the disposing direction. A length of not less than 2 mm in the disposing direction allows the graphite laminate to have a large heat receiving surface for a heat-generating element, thereby allowing the graphite laminate to receive heat more efficiently.

In a case where a graphite laminate is so oriented as to have a layered surface facing a high-temperature site, the graphite laminate 1 preferably has a bent portion as illustrated in FIG. 16 similarly to the case where a graphite laminate is so oriented as to have a front surface facing a high-temperature site. Causing the layered surface to face a high-temperature site as above allows the graphite laminate to receive heat more efficiently, while forming a bent portion allows the graphite laminate 1 to be connected with a low-temperature site having a lower temperature. This in turn makes it possible to produce a heat transport structure having a high heat transport capability.

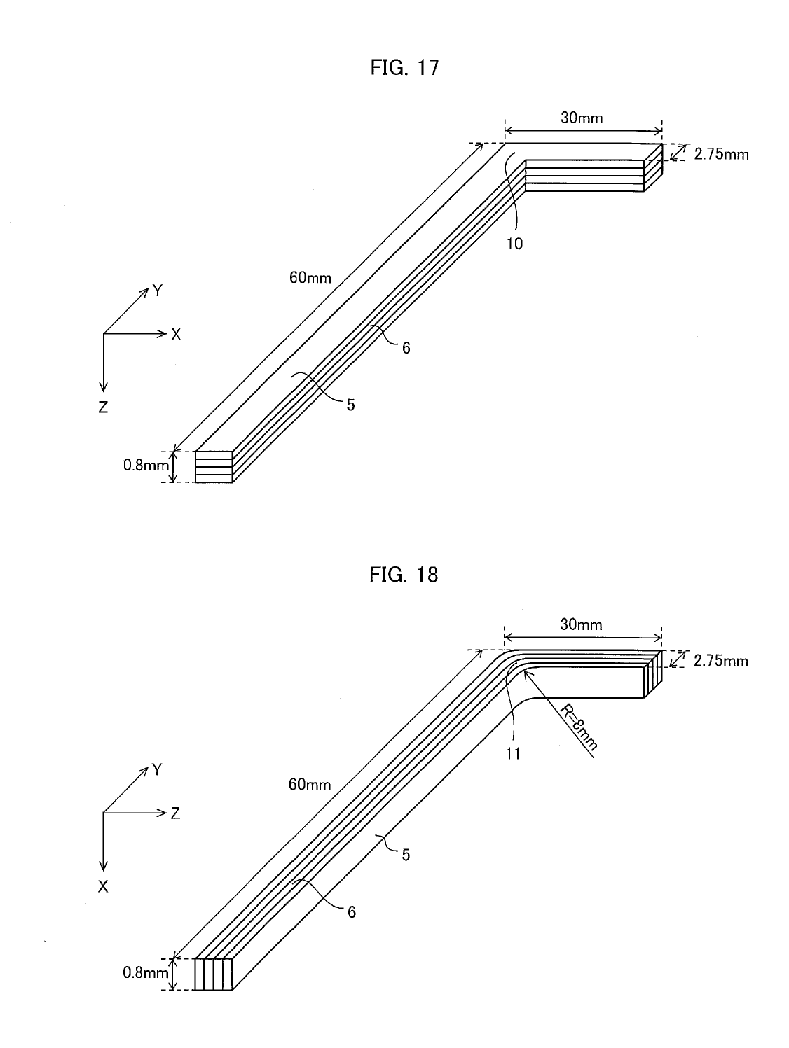

FIGS. 17 and 18 each show an example of the dimensions of a graphite laminate. The present invention is, however, not limited by the examples.

The present invention may alternatively be configured as follows:

<1> A graphite laminate in which graphite sheets and adhesive layers are disposed alternately on top of each other,

the adhesive layers each containing a thermoplastic resin and/or a thermosetting resin,

the adhesive layers each having a water absorption rate of not more than 2% and a thickness of less than 10 μm,

the graphite sheets being included in a number of not less than 5.

<2> A graphite laminate in which graphite sheets and adhesive layers are disposed alternately on top of each other,

the adhesive layers each containing a thermoplastic resin and/or a thermosetting resin,

the adhesive layers each having a water absorption rate of not more than 2%,

the graphite laminate having a thickness smaller than a sum of (i) respective thicknesses of raw material sheets for the graphite sheets and (ii) respective thicknesses of the adhesive layers,

the graphite sheets being included in a number of not less than 5.

<3> The graphite laminate according to <2> or <3>, wherein the thermoplastic resin and/or the thermosetting resin has a glass transition point of not lower than 50° C.

<4> The graphite laminate according to any one of <1> to <3>, wherein the graphite sheets each have a thermal conductivity of not less than 1000 W/(m·K) in a surface direction.

<5> The graphite laminate according to any one of <1> to <4>, wherein Tg/Ta is not less than 4.1 and not more than 40, where Tg represents a sum of respective thicknesses of the graphite sheets, and Ta represents a sum of the respective thicknesses of the adhesive layers, and the graphite laminate has a length of not less than 0.5 mm in a direction in which the graphite sheets and the adhesive layers are disposed alternatively on top of each other (specifically, a direction of a Z axis).

<6> The graphite laminate according to any one of <1> to <5>, wherein the graphite laminate has a surface perpendicular to the direction in which the graphite sheets and the adhesive layers are disposed alternatively on top of each other (specifically, the direction of the Z axis) which surface (defined by an X axis and a Y axis, which crosses the X axis) has a long side that is not less than 5 times longer than a short side thereof.

<7> The graphite laminate according to any one of <1> to <6>, wherein the graphite laminate has at least one bent portion.

<8> The graphite laminate according to <7>, wherein the bent portion has no junction.

<9> The graphite laminate according to <7> or <8>, wherein at least one of the at least one bent portion is bent in a direction (specifically, a direction of the X axis or the Y axis) perpendicular to the direction in which the graphite sheets and the adhesive layers are disposed alternatively on top of each other (specifically, the direction of the Z axis).

<10> The graphite laminate according to <7> or <8>, wherein at least one of the at least one bent portion is bent in the direction in which the graphite sheets and the adhesive layers are disposed alternatively on top of each other (specifically, the direction of the Z axis).

<11> The graphite laminate according to <7> or <8>, wherein at least one of the at least one bent portion is bent in (i) the direction (specifically, the direction of the X axis or the Y axis) perpendicular to the direction in which the graphite sheets and the adhesive layers are disposed alternatively on top of each other (specifically, the direction of the Z axis) and also in (ii) the direction in which the graphite sheets and the adhesive layers are disposed alternatively on top of each other (specifically, the direction of the Z axis).

<12> The graphite laminate according to any one of <7> to <11>, wherein the graphite laminate has a non-adhering portion, at which the graphite sheets do not adhere to each other with use of the adhesive layers, and the non-adhering portion is present at a position other than opposite lengthwise ends of the graphite laminate.

<13> The graphite laminate according to <12>, wherein the non-adhering portion is present at the at least one bent portion.

<14> The graphite laminate according to any one of <1> to <13>, wherein the graphite laminate is coated with resin or metal.

<15> The graphite laminate according to any one of <1> and <14>, wherein the graphite laminate has, in the direction in which the graphite sheets and the adhesive layers are disposed alternatively on top of each other (specifically, the direction of the Z axis), a length larger than a length of a short side of a surface of the graphite laminate which surface (defined by the X axis and the Y axis, which crosses the X axis) is perpendicular to the direction in which the graphite sheets and the adhesive layers are disposed alternatively on top of each other.

<16> The graphite laminate according to <15>, wherein the graphite laminate has a length of not less than 2 mm in the direction in which the graphite sheets and the adhesive layers are disposed alternatively on top of each other (specifically, the direction of the Z axis).

<17> A heat dissipation structure, including: a graphite laminate according to any one of <1> to <16>; and a heat-generating element,

the graphite laminate having a first end placed at a high-temperature site, which is a site whose temperature is raised by heat generated by the heat-generating element,

the graphite laminate having a second end placed at a low-temperature site, which is a site whose temperature is lower than the temperature of the high-temperature site.

<18> The heat dissipation structure according to <17>, wherein the graphite laminate is so oriented as to have a layered surface (specifically, a surface parallel to the direction of the Z axis) facing the high-temperature site.

<19> A method for producing a graphite laminate, the method including the steps of:

(a) disposing graphite sheets and adhesive layers alternately on top of each other; and

(b) causing the graphite sheets and the adhesive layers to adhere to each other by heating and pressurizing.

<20> The method according to <19>, wherein

the adhesive layers become adhesive on heating, and

in the step (b), all of the graphite sheets and the adhesive layers are caused to adhere to each other by heating and pressurizing in a single operation.

<21> The method according to <19> or <20>, wherein the adhesive layers each have an adhesive force of not higher than 1 N/25 mm at 25° C.

<22> The method according to any one of <19> to <21>, wherein in the step (b), the graphite laminate is so pressurized with use of a pressurizing jig with a bent shape as to be bent in a direction in which the graphite sheets and the adhesive layers are disposed alternatively on top of each other (specifically, a direction of a Z axis).

<23> The method according to any one of <19> to <21>, wherein in the step (b), a graphite laminate precursor is cut in a direction in which the graphite sheets and the adhesive layers are disposed alternatively on top of each other (specifically, a direction of a Z axis) so that the graphite laminate is cut out.

<24> The method according to any one of <19> to <21>, wherein in the step (b), the graphite laminate is so pressurized with use of a pressurizing jig with a bent shape as to be bent in a direction in which the graphite sheets and the adhesive layers are disposed alternatively on top of each other (specifically, a direction of a Z axis) and is then cut in the direction in which the graphite sheets and the adhesive layers are disposed alternatively on top of each other (specifically, the direction of the Z axis).

Further, the present invention may alternatively be configured as follows:

<25> A graphite laminate of the present invention includes: graphite sheets; and adhesive layers, the graphite sheets and the adhesive layers being disposed alternately on top of each other, the adhesive layers each containing at least one of a thermoplastic resin and a thermosetting resin, the adhesive layers each having a water absorption rate of not more than 2%, the graphite laminate being produced by compressing a stack of the graphite sheets and the adhesive layers disposed alternately on top of each other, the graphite sheets being included in the graphite laminate in a number of not less than 3 (or not less than 5).

### Embodiment C

[C-1. Graphite Laminate]

A graphite laminate of Embodiment C is a graphite laminate including graphite sheets and adhesive layers disposed alternately on top of each other (or a graphite laminate in which graphite sheets and adhesive layers are disposed alternately on top of each other), an adhesive layer material (which is a material of the adhesive layers) or the adhesive layers containing at least one of a thermoplastic resin and a thermosetting resin.

The graphite sheets are included in the graphite laminate in a number of not less than 3. The graphite laminate is produced, as described later, by heating and pressurizing a stack of the graphite sheets and the adhesive layer material arranged alternately.

The graphite laminate of the present invention may be configured to be bent so as to have at least one bent portion.

Such a graphite laminate may be formed by bending a stack. Such a graphite laminate may also be formed by bending a graphite laminate.

The following description will discuss a graphite laminate as well as graphite sheets and adhesive layers included in the graphite laminate.

[C-1-1. Graphite Laminate]

(Basic Structure of Graphite Laminate)

A graphite laminate includes graphite sheets and adhesive layers disposed alternately on top of each other. The graphite sheets and the adhesive layers may be separated by another component, and may not be separated by another component.

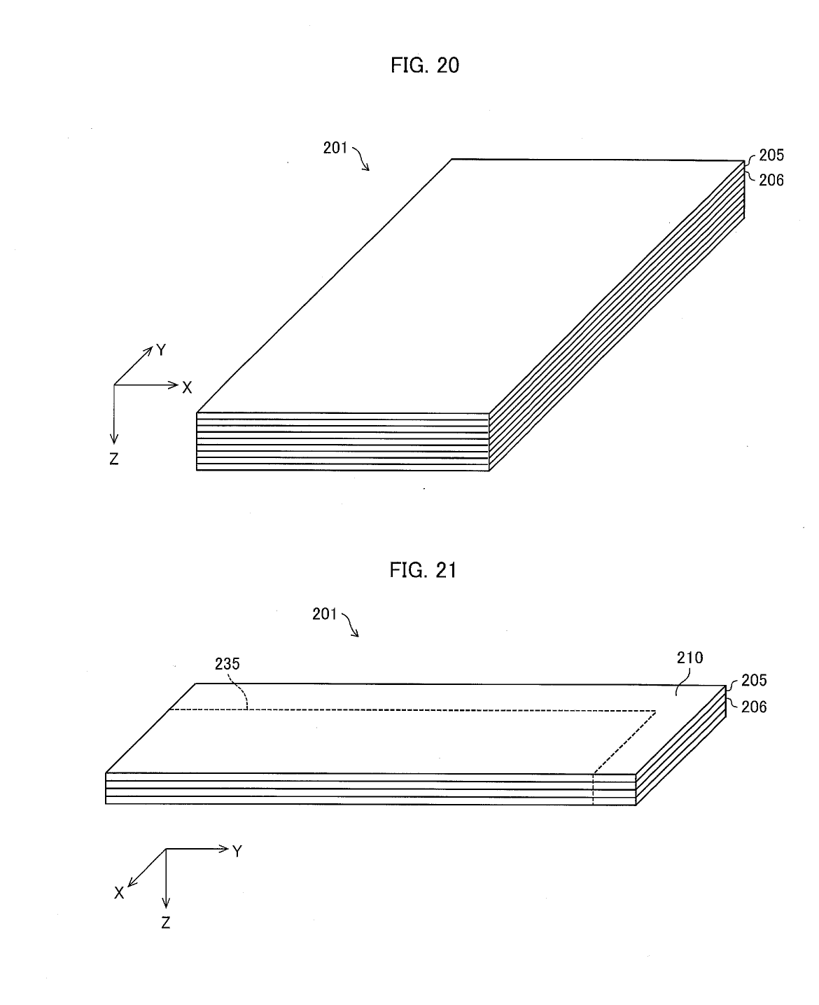

FIG. 20 is a diagram illustrating a basic structure of a graphite laminate. As illustrated in FIG. 20, a graphite laminate 201 includes graphite sheets 205 and adhesive layers 206 each having a surface defined by an X axis and a Y axis, which is orthogonal to the X axis. The surface is crossed at right angles by a Z axis. The graphite sheets 205 and the adhesive layers 206 are disposed alternately on top of each other along the Z axis in such a manner that the respective surfaces overlap with each other. The graphite laminate 201 is thus configured. As mentioned above, the X axis and the Y axis cross each other at an angle of 90°.

The graphite sheets and the adhesive layers are in close contact with each other (for example, thermally fused) at not less than 50% of an interface therebetween. In terms of thermal contact resistance (thermal conductivity), the graphite sheets and the adhesive layers are preferably in close contact with each other at not less than 70% of an interface therebetween, more preferably at not less than 80% of an interface therebetween, and further preferably at not less than 95% of an interface therebetween. The thermal conductivity is described below in the Examples section, and is not described here.

The expression “in such a manner that the respective surfaces overlap with each other” as used herein indicates a state where, in FIG. 20, at least a portion of each graphite sheet 205 overlaps with at least a portion of each adjacent adhesive layer 206 when the laminate 201 is viewed from the Z-axis direction.

Each of the graphite sheets 205 may have a shape and size identical to or different from the shape and size of each of the adhesive layers 206. Each of the graphite sheets 205 preferably has a size and shape identical to the size and shape of the each of the adhesive layers 206 for a desired effect to be produced more effectively.

The graphite sheets 205 and the adhesive layers 206 may each be in the shape of a square, for example. In this case, the squares may each have a side extending in the X-axis direction and another side extending in the Y-axis direction to cross the above side.

Alternatively, the graphite sheets 205 and the adhesive layers 206 may each be in the shape of a rectangle. In this case, the rectangles may each have short sides extending in the X-axis direction and long sides extending in the Y-axis direction.

The graphite sheets 205 and the adhesive layers 206 may alternatively each be in a shape other than a square or a rectangle. In this case, it is possible that the graphite sheets 205 and the adhesive layers 206 each have its largest dimension in the Y-axis direction and that the direction orthogonal to the Y axis is the X-axis direction.

The number of graphite sheets (disposed layers) to be included in a graphite laminate can be not less than 3. In terms of thermal capacity, the number of graphite sheets is preferably not less than 5, more preferably not less than 10, even more preferably not less than 15, even more preferably not less than 20. The upper limit of the number of graphite sheets is not limited to any particular value, and may be not more than 1000, not more than 500, not more than 200, not more than 100, not more than 80, or not more than 50.

The number of graphite sheets (disposed layers) is preferably not less than 3 because such a number of graphite sheets allow for production of a graphite laminate having a high heat transport capability and an excellent mechanical strength.

The number of adhesive layers to be included in a graphite laminate is not limited to any particular value, and can be selected as appropriate in correspondence with the number of graphite sheets to be included. The graphite laminate may be configured as follows, for example: (i) Adjacent graphite sheets are separated by a single adhesive layer or even two or more adhesive layers. (ii) The graphite laminate includes a graphite sheet only at the uppermost surface, only at the lowermost surface, or at each of the uppermost surface and the lowermost surface. (iii) The graphite laminate includes an adhesive layer only at the uppermost surface, only at the lowermost surface, or at each of the uppermost surface and the lowermost surface. Expressions such as “graphite sheets and adhesive layers are disposed alternately on top of each other” as used herein intend to mean both (a) a case where adjacent graphite sheets are separated by a single adhesive layer and (b) a case where adjacent graphite sheets are separated by two or more adhesive layers. In other words, an adhesive layer for the present invention may include a plurality of adhesive layers.

(Thickness of Graphite Laminate)

The thickness of the graphite laminate (that is, its dimension along the Z axis in FIG. 20) is not limited to any particular value, but is preferably not less than 0.1 mm, more preferably not less than 0.4 mm, even more preferably not less than 0.6 mm, and even more preferably not less than 0.8 mm. A thickness of not less than 0.1 mm for the graphite laminate allows the graphite laminate to transport a large amount of heat and to thus be used in an electronic device that generates a large amount of heat. The upper limit of the thickness of the graphite laminate is not limited to any particular value, and may be not more than 10 mm, not more than 7.5 mm, not more than 5 mm, not more than 2.5 mm, or not more than 1 mm in order to provide an electronic device having a reduced thickness.

Graphite sheets can be effectively disposed on top of each other with an adhesive layer in-between because adhesive layers serve as a cushion against asperities on the respective surfaces of the graphite sheets and reduce the contact thermal resistance between the graphite sheets.

(Bent Portion)

The graphite laminate may be so bent as to have at least one bent portion (for example, one or more, or two or more bent portions). The graphite laminate may, in other words, be prepared through bending of an unbent graphite laminate so that the graphite laminate has a bent portion. In electronic devices, an increase in temperature can be prevented by transferring heat generated by a heat source to a low-temperature portion. However, a low-temperature portion cannot necessarily be connected with a heat source in a straight line. In view of that, causing the graphite laminate to have a bent portion allows heat generated by a heat source to be transferred to a portion having a lower temperature, thereby allowing the graphite laminate to have a further improved heat transport capability. The above configuration can, in other words, increase the degree of freedom of arrangement of a heat source and a lower temperature portion relative to each other. The configuration of the bent portion as described in Embodiment B can be employed as the specific configuration of the bent portion of Embodiment C.

The angle formed by the bent portion is not limited to any particular value. The bent portion may have a radius of curvature of not less than 2 mm, not less than 5 mm, not less than 8 mm, not less than 10 mm, or not less than 20 mm. The maximum value of the radius of curvature is not limited to any particular value, and may be, for example, 100 mm, 90 mm, 80 mm, 70 mm, 60 mm, 50 mm, 40 mm, 30 mm, or 20 mm. The maximum value of the radius of curvature may, needless to say, be a value larger than 100 mm.

(Coating for Graphite Laminate)

With regards to a coating for the graphite laminate of Embodiment C, a configuration identical to that described under “(Coating for graphite laminate)” for Embodiment B can be employed.

(Graphite composite product)

A graphite composite product is a product in which a sheet including at least an adhesive or a binding material has been bonded to at least one side of the graphite laminate. The sheet including the adhesive or binding material makes it possible to attach the graphite laminate to, for example, a semiconductor device or other heat generating component mounted in any of various electronic or electric devices, such as a computer, for the purpose of heat transport.

A configuration of a sheet including an adhesive is not particularly limited. Examples of such include (i) a sheet made from an adhesive, (ii) a sheet including a two-layered structure constituted by an adhesive and a base, and (iii) a sheet including a three-layered structure constituted by an adhesive, a base, and an adhesive. The adhesive is not particularly limited. Examples of the adhesive include a silicone-based adhesive, an acrylic adhesive, and a synthetic-rubber-based adhesive. The base is not particularly limited. Examples of materials that can be used for the base include polyimide-based resin, polyethylene terephthalate (PET)-based resin, polyphenylene sulfide (PPS)-based resin, polyethylene naphthalate (PEN)-based resin, polyester resin, and a metal sheet (such as aluminum foil or copper foil).

A configuration of a sheet including a binding material is not particularly limited. Examples of such include (i) a film made from a binding material, (ii) a sheet including a two-layered structure constituted by a binding material and a base, and (iii) a sheet including a three-layered structure constituted by an adhesive layer, a base, and an adhesive layer. The binding material is not particularly limited. Examples of the binding material include a thermosetting-type resin binding material such as (i) a polyimide-based resin or (ii) an epoxy-based resin. Other examples of the binding material include a thermoplastic resin, with which binding is performed while the thermoplastic resin is in a melted state. The base is not particularly limited. Examples of materials that can be used for the base include polyimide-based resin, polyethylene terephthalate (PET)-based resin, polyphenylene sulfide (PPS)-based resin, polyethylene naphthalate (PEN)-based resin, polyester resin, a metal sheet (such as aluminum foil or copper foil), carbon fiber reinforced plastic (CFRP), carbon fiber felt, and other carbon materials.

(Heat Transport Structure)

The above-described graphite laminate and graphite composite product of the present invention can each be used in a heat transport structure, mainly as a heat transport material of an electronic device. A heat transport structure includes a graphite laminate or graphite composite product; and a heat-generating element, the graphite laminate or graphite composite product being connected with a high-temperature site, whose temperature is raised by heat generated by the heat-generating element, and with a low-temperature site, whose temperature is lower than the temperature of the high-temperature site.

[C-1-2. Graphite Sheet]

(Kind of Graphite Sheet)

With regards to the kind of graphite sheet for Embodiment C, a configuration identical to that described under “(Kind of graphite sheet)” for Embodiment B can be employed.

(Method for Producing Graphite Sheet)

With regards to a method for producing the graphite sheet of Embodiment C, a method similar to that described under “(Method for producing graphite sheet)” for Embodiment B can be employed.

(Thermal Conductivity of Graphite Sheet in Surface Direction)

With regards to a thermal conductivity of the graphite sheet in the surface direction for Embodiment C, a configuration similar to that described under “(Thermal conductivity of graphite sheet in surface direction)” for Embodiment B can be employed.

(Thermal Conductivity of Graphite Sheet)

The following Formula (1) was used to calculate the thermal conductivity of a graphite sheet in the surface direction.

A=a×d×Cp (1)

(Where A represents thermal conductivity of a graphite sheet, a represents thermal diffusivity of the graphite sheet, d represents density of the graphite sheet, and Cp represents specific thermal capacity of the graphite sheet.) Note that the thermal diffusivity, density, and specific thermal capacity of the graphite sheet were determined by use of methods described later.

The thermal diffusivity of the graphite sheet was measured in the following manner. A sample having a size of 4 mm×40 mm was cut out from the graphite sheet, and the thermal diffusivity of the sample was measured using a thermal diffusivity measurement device which employs the light alternating-current method (for example, “LaserPit” manufactured by ULVAC-RIKO, Inc.), in an atmosphere whose temperature was 20° C., and at a 10 Hz alternating current.

(Thickness of Graphite Sheet)

With regards to the thickness of the graphite sheet for Embodiment C, a configuration similar to that described under “(Thickness of graphite sheet)” for Embodiment B can be employed.

[C-1-3. Adhesive Layer]

(Kind of Adhesive Layer Material)

An adhesive layer material, which is a material of the adhesive layer for the present invention, is preferably a material which exhibits adhesiveness upon heating thereof. A thermosetting resin or a thermoplastic resin can be used as the adhesive layer material.

The thermosetting resin can be one of the examples listed under “(Kind of adhesive layer)” for Embodiment B.

The thermoplastic resin can be one of the examples listed under “(Kind of adhesive layer)” for Embodiment B.

The adhesive layer material is preferably an aromatic material (for example, polyester adhesive and polyethylene terephthalate). With this arrangement, disposing graphite sheets and adhesive layers on top of each other allows the adhesive layers to be substantially parallel to the graphite sheets and prevents a layered structure of the graphite sheets from being easily disrupted, thereby making it possible to produce a graphite laminate having a thermal conductivity close to the theoretical value.

The thermoplastic resin and the thermosetting resin each have a melting point of preferably not lower than 50° C., more preferably not lower than 60° C., even more preferably not lower than 70° C., even more preferably not lower than 80° C. A melting point of not lower than 50° C. makes it possible to more effectively prevent air from remaining in a graphite laminate to be produced. A material such as an acrylic adhesive and a rubber sheet which material has a melting point of not lower than 50° C. is preferable because such a material provides adhesive layers that are high in strength and that are unlikely to have property variations. Examples of a material having such a melting point include polyethylene terephthalate (PET), polystyrene (PS), and polycarbonate (PC).

The melting point of the adhesive layer material can be measured in conformance with JIS K 7121, and by using a differential scanning calorimeter (DSC-50, manufactured by Shimadzu Corporation).

The adhesive layer material may have any elastic modulus. The elastic modulus is, however, preferably high (for example, an elastic modulus of not less than 100 MPa) to reduce thickness variations in an adhesive layer caused during cutting of the graphite laminate.

(Thickness of Adhesive Layer Material)

The adhesive layer material for the present invention may have any thickness. The thickness is, however, preferably less than 10 μm. More specifically, the adhesive layer material has a thickness of preferably not less than 0.1 μm and less than 10 μm, more preferably not less than 1 μm and less than 10 μm, even more preferably not less than 1 μm and not more than 9 μm, even more preferably not less than 1 μm and not more than 7 μm. In a case where an adhesive layer material has a thickness of less than 10 μm, the adhesive layer has a thermal conductivity much lower than that of a graphite sheet. Controlling the thickness of the adhesive layer material to less than 10 μm allows the adhesive layer material to transmit heat efficiently without an adhesive layer inhibiting heat transfer between graphite sheets. In a case where an adhesive layer material has a thickness of not less than 0.1 μm (and preferably not less than 1 μm), an adhesive layer is more easily capable of serving as a cushion against asperities on graphite sheet surfaces to reduce the contact thermal resistance between the adhesive layer and a graphite sheet for efficient heat transmission. Further, an adhesive layer material having a thickness of not less than 0.1 μm (and preferably not less than 1 μm) allows an adhesive layer to exhibit good adhesiveness. Further, an adhesive layer material having the above thickness allows a graphite laminate including the adhesive layer material to have a thermal conductivity close to the theoretical value. The method for calculating the thickness of an adhesive layer material is described below in the Examples section, and is not described here.

(Thickness of Adhesive Layer)

The adhesive layer for the present invention has a thickness which is identical to or thinner than the thickness of the adhesive layer material. In a case where the adhesive layer is thinner than the adhesive layer material, the adhesive layer material has presumably infiltrated a surface of a graphite sheet (that is, the adhesive layer is presumably serving as a cushion against asperities on the surface of the graphite sheet). The adhesive layer may have any specific thickness. The thickness is, however, preferably less than 10 μm. More specifically, the adhesive layer has a thickness of preferably not less than 0.1 μm and less than 10 μm, more preferably not less than 1 μm and less than 10 μm, even more preferably not less than 1 μm and not more than 9 μm, even more preferably not less than 1 μm and not more than 7 μm. In a case where an adhesive layer has a thickness of less than 10 μm, the adhesive layer has a thermal conductivity much lower than that of a graphite sheet. Controlling the thickness of the adhesive layer to less than 10 μm allows the adhesive layer to transmit heat efficiently without inhibiting heat transfer between graphite sheets. In a case where an adhesive layer has a thickness of not less than 0.1 μm (and preferably not less than 1 μm), the adhesive layer is more easily capable of serving as a cushion against asperities on graphite sheet surfaces to reduce the contact thermal resistance between the adhesive layer and a graphite sheet for efficient heat transmission. Further, an adhesive layer having a thickness of not less than 0.1 μm (and more preferably not less than 1 μm) is capable of exhibiting good adhesiveness. Further, an adhesive layer having the above thickness allows a graphite laminate including the adhesive layer to have a thermal conductivity close to the theoretical value.

Examples of a method of calculating the thickness of the adhesive layer include the method described later. Specifically, a method can be employed in which (i) an SEM imaging is used to observe a cross section of a given adhesive layer, (ii) the thickness of the adhesive layer is measured at 9 given points, and (iii) an average value of the measurements is considered to be the thickness of the adhesive layer.

[C-2. Method for Producing Graphite Laminate]

(Basic Arrangement of Method for Producing Graphite Laminate)

A method of the present invention for producing a graphite laminate includes the steps of: disposing graphite sheets and an adhesive layer material alternately on top of each other so as to form a stack; and heating the stack to thermally fuse the graphite sheets and adhesive layers to each other so as to produce a graphite laminate. The method may further include a step of cutting the graphite laminate via a cutting process. The phrase “thermally fuse” as used herein intends to refer to a state in which a resin or wax is softened by heating and then adhered to another material.

The following description will discuss the individual steps.

(Disposing Step)

A disposing step is a step of disposing (i) the adhesive layer material, which is the material of the adhesive layers, and (ii) graphite sheets alternately in a plurality of layers on top of each other to form a stack.

More specifically, the disposing step is a step of disposing graphite sheets and adhesive layer material, each of which has a surface defined by an X axis and a Y axis, which is orthogonal to the X axis, alternately on top of each other in the direction of a Z axis, which is perpendicular to the surface, in such a manner that the respective surfaces of the graphite sheets and the adhesive layer material overlap with each other to form a stack.

This disposing step is carried out specifically by, for example, (i) a method of disposing graphite sheets and the adhesive layer material alternately on top of each other or (ii) a method of preparing graphite adhesive sheets each including a graphite sheet and the adhesive layer material on at least one surface of the graphite sheet and disposing the graphite adhesive sheets on top of each other.

Examples of the method (i) above include a method of disposing graphite sheets and the adhesive layer material alternately one by one on top of each other and a method of winding up a graphite sheet and the adhesive layer material together around a core to form a roll and then cutting and cleaving the roll to provide a laminate of graphite sheets and the adhesive layer material.

The method (ii) above includes first preparing graphite adhesive sheets. Graphite adhesive sheets can each be prepared by coating a graphite sheet with the adhesive layer material (in the form of an adhesive resin sheet, for example) or by laminating a graphite sheet with the adhesive layer material (in the form of an adhesive film, for example). Examples of the method of disposing graphite sheets and the adhesive layer material on top of each other include a method of cutting the graphite adhesive sheets into a plate shape and disposing the cut graphite adhesive sheets on top of each other and a method of winding up the prepared graphite adhesive sheets around a core to form a roll and cutting and cleaving the roll.

In a case where the adhesive layer material is applied to a graphite sheet, the adhesive layer material preferably has no tucking property after the application in order to prevent air from remaining in a graphite laminate to be produced.

In a case where the adhesive layer material and graphite sheets are disposed alternately on top of each other, or in a case where the adhesive layer material is laminated onto a graphite sheet, a low dielectric constant for the adhesive layer material, which means that the adhesive layer material is not easily electrically charged, allows the adhesive layer material to be fixed to a conveyer stably with use of electrostatic force. Further, with a good electrical conduction property for the graphite sheets, in a case where the graphite sheets and the adhesive layer material are in close contact with each other, static electricity of the adhesive layer material escape to the graphite sheets, with the result that the graphite sheets and the adhesive layer material are more slidable on each other and that the adhesive layer material is less likely to be wrinkled.

In the disposing step, it is preferable to dispose a plurality of stacks on each other. This is because doing so makes it possible to simultaneously produce a plurality of graphite laminates which can be separated from each other after thermal fusion. From the standpoint of facilitating mass production, the number of stacks disposed on each other is preferably not less than 100, and more preferably not less than 200. The upper limit of the number of stacks disposed on each other is not limited to any particular value, and may be, for example, 1,000, 900, 800, 700, 600, 500, 400, or 300. With the method of production of the present invention, in a case where an adhering step is carried out for large number of stacks disposed on each other, an adhesion ratio will be favorable in any of the graphite laminates produced, whether the graphite laminate was positioned in an upper, middle, or lower region of its respective batch.

(Adhering Step)

An adhering step is a step of heating the stack(s) formed in the disposing step to thermally fuse the adhesive layer material to graphite sheets so as to obtain a graphite laminate in which the graphite sheets and adhesive layers are arranged alternately. The temperature for the heating is not limited to any particular value, and can be selected as appropriate in correspondence with the adhesive layer material. A first and second pressurizing are carried out during the adhering step. Two-stage pressurizing involving a first and second pressurizing effectively removes gas in a stack, thereby making it possible to produce a graphite laminate which is highly smooth and has a high peel strength. The temperature for the heating and the pressures for the first and second pressurizing are not limited to any particular values, and can be selected as appropriate in correspondence with the adhesive layer material. The adhering step may include one or more further pressurizings, such as a third and fourth pressurizing, to be carried out after the second pressurizing. The adhering step may include one or more further pressurizings, such as a third and fourth pressurizing, to be carried out between the first and second pressurizing. The adhering step may include one or more preliminary pressurizings to be carried out before the first pressurizing. A pressure applied to a stack during such a preliminary pressurizing is preferably lower than (i) the pressure applied to the stack during the first pressurizing and (ii) the pressure applied to the stack during the second pressurizing. This configuration removes gas in a stack even more effectively. The third, fourth, and preliminary pressurizings may each be carried out in a step other than the adhering step.

The first pressurizing refers to pressurizing of a stack at least by the time the temperature of the adhesive layer material being heated reaches [(melting point of adhesive layer material)−20° C.]. Here, “[(melting point of adhesive layer material)−20° C.]” refers to a point where the temperature of the adhesive layer material, as measured using a thermocouple in contact with a stack, has reached a temperature 20° C. lower than the melting point of the adhesive layer material. In other words, in Embodiment C, the first pressurizing can be carried out by the time the temperature of the adhesive layer material, as measured using a thermocouple in contact with the stack, reaches a temperature 20° C. lower than the melting point of the adhesive layer material. The pressure used in the first pressurizing is not particularly limited, provided that it is a pressure at which the adhesive layer material does not thermally fuse to a graphite sheet. The pressure can be selected as appropriate in correspondence with the adhesive layer material. The length of time of the first pressurizing is not particularly limited. The first pressurizing is preferably carried out starting from the commencement of the adhering step, since doing so makes it possible to produce a graphite laminate which is highly smooth and has a high peel strength.

The second pressurizing refers to pressurizing of a stack at least after the temperature of the adhesive layer material being heated reaches [(melting point of adhesive layer material)−20° C.]. Here, “after the temperature of adhesive layer material being heated reaches [(melting point of adhesive layer material)−20° C.]” refers to a time after the temperature of the adhesive layer material, as measured using a thermocouple in contact with the stack, has reached [(melting point of adhesive layer material)−20° C.]. In other words, in Embodiment C, the second pressurizing can be carried out after the temperature of the adhesive layer material, as measured using a thermocouple in contact with the stack, reaches [(melting point of adhesive layer material)−20° C.]. The pressure used in the second pressurizing is not limited, provided that it is a pressure at which the adhesive layer material thermally fuses to a graphite sheet. The pressure can be selected as appropriate in correspondence with the adhesive layer material. The length of time of the second pressurizing is not particularly limited. The length of time is preferably in a range from 1 minute to 10 minutes, more preferably in a range from 3 minutes to 8 minute, and particularly preferably in a range from 4 minutes to 6 minutes. This is because a length of time in such ranges improves the adhesiveness between graphite sheets and adhesive layers.

The second pressurizing is preferably carried out immediately after the first pressurizing. In such a case, (i) the second pressurizing may involve pressurizing a stack at a pressure higher than that of the first pressurizing, (ii) the second pressurizing may involve pressurizing a stack at a pressure and temperature which are both higher than those of the first pressurizing, (iii) the pressure applied to a stack during the first pressurizing may be gradually increased, (iv) the pressure applied to the stack during the second pressurizing may be gradually increased, and (v) the pressure applied to the stack during the second pressurizing may be gradually increased after the pressure applied to the stack during the first pressurizing has been gradually increased. Graphite sheets have surficial asperities and are easily deformed. As such, successively increasing the pressure applied to a stack makes it possible to adjust the timing of deformation of (i) the adhesive layers and (ii) the graphite sheets such that the adhesive layers conform to the shape of the surficial asperities of the graphite sheets. This makes possible to improve the strength of adhesion between the graphite sheets and the adhesive layers.

Specific examples of the adhering step include lamination and pressing. For the present invention, lamination components are suitably pressed for adhesion. Pressing allows layers in a stack to adhere to each other in one operation, even in the case of stack of many layers such as ten layers or more. Further, pressurizing a stack for several seconds or more while heating the stack can prevent the adhesive layers from softening and air from remaining in the graphite laminate as a result of the pressurizing, thereby making it possible to reduce the contact thermal resistance between the graphite sheets.

As mentioned above, the adhering step includes heating and pressurizing (in other word, compressing) a stack formed in the disposing step. During this step, the rate of the compression of a stack is not limited to any particular value, but is preferably less than 1, more preferably not more than 0.97, even more preferably not more than 0.96, even more preferably not more than 0.95, even more preferably not more than 0.92, even more preferably not more than 0.90. In a case where the compression rate, that is, (thickness of graphite laminate)/(thickness of stack as raw material), is less than 1, it means that the adhesive layers disposed in the stack are deformed. In this case, the graphite sheets come into contact with each other more easily, making it possible to produce a graphite laminate having a thermal conductivity close to the theoretical thermal conductivity.

FIG. 21 illustrates an example cutting process. As illustrated in FIG. 21, cutting a graphite laminate in the Z-axis direction along cutting positions 235 (indicated by a dotted line) can prepare a graphite laminate 201 that is bent in the X-axis direction (or Y-axis direction) at a bent portion 210. The cutting process can be carried out with use of a cutter, a blade saw such as a peripheral cutting edge, a laser, a water jet, a wire saw, or the like. The cutting process is, however, preferably carried out with use of a wire saw in order to prevent delamination of the graphite laminate, cut a large number of graphite laminates at the same time, and improve the productivity. The cutting process allows a graphite laminate 201 to be bent at a sharp angle (for example, right angle).

### Embodiment D

The respective graphite laminates described in Embodiments A through C can each be configured to be a graphite composite film which includes the graphite laminate, a protective layer, and an adhesion layer.

In this case, the graphite composite film includes a graphite laminate, a protective layer, and an adhesion layer, and it is preferable that at least a portion of an end of the graphite laminate be coated with the protective layer and the adhesion layer.

The graphite composite film can be configured in accordance with Japanese Patent Application Publication, Tokukai, No. 2008-80672 (Publication Date: Apr. 10, 2008). Note that Japanese Patent Application Publication, Tokukai, No. 2008-80672 is incorporated herein by reference. The following description will discuss, in detail, the graphite composite film.

The graphite composite film is preferably configured such that at least a portion of an end of the graphite laminate is coated by the protective layer and the adhesion layer. More specifically, the graphite composite film can be (i) structured such that an end of the graphite laminate is entirely coated by the protective layer and the adhesion layer, (ii) structured such that a portion of the end of the graphite laminate is coated by the protective layer and the adhesion layer, or (iii) structured so that the graphite laminate is entirely coated by the protective layer and the adhesion layer.

With a graphite composite film in which at least a portion of an end of the graphite laminate is coated by the protective layer and the adhesion layer, it is possible to prevent a cohesive failure between graphite layers when, for example, the graphite composite film is separated from a release liner or during reworking. Furthermore, in small-sized electronic devices such as mobile phones, laptop PCs, handheld video cameras, and automotive headlights, a reduction in the size of the space inside the device has resulted in reduction in the size of heat dissipating space as well. As such, there has been a rapid increase in cases where, for example, a heat transport film is affixed to a movable part, such as a hinge part or flexible substrate, or a heat transport film is bent inside a device. Even if the graphite composite film of the present invention is used in such a bent state or a state where is caused to bend repeatedly, the graphite composite film prevents delamination occurring from an end thereof and prevents interface detachment at (i) an interface between the protective layer and the graphite laminate and (ii) an interface between the adhesion layer and a graphite film. The graphite composite film of the present invention therefore serves as a heat transport film which can withstand being in a bent state and being caused to bend repeatedly.

<Width of Protruding Portion of Protective Layer>

The protective layer and the adhesion layer which coat a perimetric end of the graphite laminate are structured to protrude past the graphite laminate. A portion of the protective layer protruding thusly has a width of not more than 2 mm, and preferably not more than 1 mm. Setting the width of the protruding portion to be not more than 2 mm makes it possible to decrease the amount of the protruding portion which does not contribute to thermal diffusion at the perimeter of the graphite laminate. This makes it possible to design the graphite laminate to have a larger area in an electronic device with little space and thus makes it possible to realize an electronic device having an excellent heat dissipation property.

<Ratio of Protruding Portion Area>

A “ratio of the area of the protruding portion” is defined here as (area of protective layer−area of graphite laminate)/(area of graphite laminate). This ratio is not more than 50%, preferably not more than 30%, and more preferably not more than 10%. Setting the ratio of the area of the protruding portion to be not more than 50% makes it possible to decrease the amount of protruding portion which does not contribute to thermal diffusion at the perimeter of the graphite laminate. This makes it possible to design the graphite laminate to have a larger area in an electronic device with little space and thus makes it possible to realize an electronic device having an excellent heat dissipation property.

<Coating Ratio>

A “coating ratio” is defined here as (length of coated portion of end of graphite laminate)/(length of end of graphite laminate). This ratio is not less than 10%, preferably not less than 20%, and more preferably not less than 30%. With a graphite composite film in which at least a portion of an end of the graphite laminate is coated by the protective layer and the adhesion layer at a coating ratio of not less than 10%, it is possible to prevent a cohesive failure between graphite layers when, for example, the graphite composite film is separated from a release liner or during reworking. Furthermore, even if such a graphite composite film is used in a bent state or a state where is caused to bend repeatedly, the graphite composite film prevents delamination occurring from an end thereof and prevents interface detachment at an interface between (i) the protective layer or the adhesion layer and (ii) the graphite laminate. The graphite composite film of the present invention therefore serves as a heat transport film which can withstand being in a bent state and being caused to bend repeatedly.

<Thickness of Graphite Composite Film>

The graphite composite film has a thickness which is not more than 100 μm, is preferably 90 μm, and is more preferably not more than 80 μm. Setting the thickness of the graphite composite film to be not more than 100 μm prevents an excessive force from acting on graphite layers even in a case where a bending force with an abrupt curvature is applied to the graphite composite film due to, for example, pulling the graphite composite film from an object it is attached to, reworking the graphite composite film, or using the graphite composite film in a state where it is bent or caused to bend repeatedly. This prevents the graphite layers from easily separating from each other.

<Thermal Conductivity of Graphite Composite Film>

The graphite composite film has a thermal conductivity that is not less than 400 W/m·K, preferably not less than 500 W/m·K, and more preferably not less than 600 W/m·K. Setting the thermal conductivity to be not less than 400 W/m·K affords a high thermal conduction property and therefore allows heat to easily escape from a heat generating device. This makes it possible to prevent a rise in the temperature of the heat generating device. Here, “thermal conductivity” refers to a value calculated from the product of thermal diffusivity, thermal capacity, and density.

<MIT (R 1 mm) of Graphite Composite Film>

The graphite composite film has an MIT (R 1 mm) which is not less than 100,000 times, preferably not less than 200,000 times, and more preferably not less than 300,000 times. Setting the MIT (R 1 mm) to be not less than 100,000 times makes it possible to suitably use the graphite composite film in, for example, a hinge of a mobile phone and bent part of a small-sized electronic device.

In measuring MIT, an angle of bending can be selected, and R can be selected to be, for example, 5 mm, 2 mm, or 1 mm. A smaller R corresponds to a more acute angle of bending and a more stringent test. In particular, in electronic devices with little space, such as mobile phones, gaming devices, liquid crystal televisions, and plasma display panels (PDPs), having excellent bendability at R 1 mm is exceedingly important, as it allows for space saving design of the device. Note that MIT (R 1 mm) can be measured via a method in accordance with the method disclosed in Japanese Patent Application Publication, Tokukai, No. 2008-80672 (Publication Date: Apr. 10, 2008).

<Protective Layer and Adhesion Layer>

The protective layer serves to protect a surface of the graphite laminate from being damaged or wrinkled when, for example, the graphite laminate is being handled or mounted to an electronic device. Graphite powder can come off a surface of the graphite. The protective layer is formed also in order to prevent such powder from coming off. The adhesion layer can be used to cause the graphite laminate to be in close contact with a heat generating component, a heat dissipating component, a housing, or the like.

<Thickness of Protective Layer and Adhesion Layer>

The protective layer and the adhesion layer each have a thickness that is not more than 40 μm, preferably not more than 30 μm, and more preferably not more than 20 μm. Setting the respective thicknesses of the protective layer and the adhesion layer each to be not more than 40 μm prevents an excessive force from acting on graphite layers even in a case where a bending force with an abrupt curvature is applied to the graphite composite film due to, for example, pulling the graphite composite film from an object it is attached to, reworking the graphite composite film, or using the graphite composite film in a state where it is bent or caused to bend repeatedly. This prevents film layers from easily separating from each other.

<Protective Layer>

Specific examples of the protective layer include an insulating layer and a conductive layer. Examples of a material of the insulating layer include polyimide, polyethylene terephthalate, and epoxy. Such materials have excellent heat resistance and allow the insulating layer to achieve sufficient long-term reliability even in a case where the graphite composite film is combined with a heat generating component or a heat dissipating component.

The insulating layer has a thickness that is not more than 40 μm, preferably not more than 30 μm, and more preferably not more than 20 μm. Setting the insulating layer to have thickness of not more than 40 μm allows the graphite laminate combined therewith to sufficiently exhibit its excellent thermal conduction property. The thickness of the insulating layer is preferably not less than 10 μm. Setting the insulating layer to have a thickness of not less than 10 μm allows the graphite composite film to maintain adequate adhesiveness even in a case where the graphite composite film is combined with a heat generating component or a heat dissipating component. Such a thickness also enables excellent long-term reliability of the adhesiveness.

Such an insulating layer may be formed directly on the graphite laminate by means of application, printing, immersion, vapor deposition or the like. An adhesive or a binding material may be provided between insulating layer and the graphite laminate.

<Conductive Layer>

Examples of a material of the conductive layer include copper and aluminum. Such materials have excellent heat resistance and allow the conductive layer to achieve sufficient long-term reliability even in a case where the graphite composite film is combined with a heat generating component or a heat dissipating component.

The conductive layer has a thickness that is not more than 40 μm, preferably not more than 30 μm, and more preferably not more than 20 μm. Setting the conductive layer to have thickness of not more than 40 μm allows the graphite laminate combined therewith to sufficiently exhibit its excellent thermal conduction property. The thickness of the conductive layer is preferably not less than 10 μm. Setting the conductive layer to have a thickness of not less than 10 μm allows the graphite composite film to maintain adequate adhesiveness even in a case where the graphite composite film is combined with a heat generating component or a heat dissipating component. Such a thickness also enables excellent long-term reliability of the adhesiveness.

Such a conductive layer may be formed directly on the graphite laminate by means of application, plating, sputtering, vapor deposition, or the like. An adhesive or a binding material may be provided between the conductive layer and the graphite laminate.

<Adhesion Layer>

Examples of a material of the adhesion layer include an acrylic adhesive and a silicone-based adhesive. Such materials have excellent heat resistance and allow the adhesion layer to achieve sufficient long-term reliability even in a case where the graphite composite film is combined with a heat generating component or a heat dissipating component. There are cases in which the graphite composite film needs to be removed after having been mounted, such as a case where there is an error in the mounting position, or during repairs after the graphite composite film has been used. An acrylic adhesive and a silicone-based adhesive excel in terms of repeated use and long-term reliability and therefore also exhibit excellent reusability and removability in cases such as the above.

The adhesion layer has a thickness that is not more than 40 μm, preferably not more than 30 μm, and more preferably not more than 20 μm. Setting the adhesion layer to have thickness of not more than 40 μm allows the graphite laminate combined therewith to sufficiently exhibit its excellent thermal conduction property. The thickness of the adhesion layer is preferably not less than 10 μm. Setting the adhesion layer to have a thickness of not less than 10 μm allows the graphite composite film to maintain adequate adhesiveness even in a case where the graphite composite film is combined with a heat generating component or a heat dissipating component. Such a thickness also enables excellent long-term reliability of the adhesiveness.

The adhesion layer is preferably made from a material including a base. The inclusion of a base increases the resilience of the graphite composite film, thereby preventing delamination of the graphite laminate when removing a release liner or when removing the graphite composite film after it has been mounted to an object. In particular, in a graphite laminate which is markedly excellent in both crystallinity and thermal diffusivity, the constituent films thereof can, in some cases, be easily detached in the form of a film. The inclusion of a base, however, ameliorates this detachability. The inclusion of a base also increases the strength of the graphite composite film and makes it possible to prevent the graphite laminate from being damaged during mounting, fixing via mechanical swaging, or reworking.

The base of the adhesion layer preferably contains polyimide or polyethylene terephthalate. Polyimide and polyethylene terephthalate each have excellent heat resistance, strength, and dimensional stability. When combined with a graphite laminate, these materials make it possible to realize a graphite composite film which excels in terms of detachability and damage resistance, without impairing the thermal conduction property of the graphite laminate.

The base has a thickness which is preferably not more than 6 μm. Setting the base to be thin makes it possible to combine the base with a graphite composite without causing deterioration in the excellent thermal diffusivity of the graphite laminate. If the base is thick, force is more likely to be applied to the base of the adhesion layer in when removing a release liner or when using the graphite composite film in a bent state. A base is generally resistant to damage from stretching and can thus conform to a curve. The graphite laminate, however, is easily damaged by bending and is likely to be wrinkled if bent to the same degree as the base. As such, it is preferable to prevent wrinkling of the graphite laminate when removing a release liner or when using the graphite composite film in a bent state by causing more force to be applied to the graphite laminate that to the base of the adhesion layer (in other words, by setting the base of the adhesion layer to be thin).

The insulating layer may be formed directly on a graphite film by means of application, printing, immersion, vapor deposition or the like. The insulating layer may be formed via transfer printing by using lamination.

### Usage Examples of the Present Invention

As described above, the graphite laminate, heat transport structure, and rod-shaped heat transporter of the present invention can each have a bent shape. When mounting the graphite laminate, heat transport structure, or rod-shaped heat transporter of the present invention to any of a variety of devices (for example, electronic or electric devices), such a shape is advantageous in terms of achieving both (i) a reduction in size of the device and (ii) efficient heat dissipation in the device. The following will discuss this point with reference to FIG. 28.

(a) and (b) of FIG. 28 are each a side view of a device including a graphite laminate. (a) and (b) of FIG. 28 each illustrate an example arrangement of the graphite laminate, having a bent portion, inside any of a variety of devices.

For example, in (a) of FIG. 28, two electronic components 550 are provided in a device, and a high-temperature site 540 is provided above one of the electronic components 550, while a low-temperature site 541 is provided below another one of the electronic components 550. With such an arrangement, since a graphite laminate 501 has a stepped shape, it is possible to provide the graphite laminate 501, the high-temperature site 540, the low-temperature site 541, and the electronic components 550 within a small space while also reliably connecting the high-temperature site 540 to the low-temperature site 541 via the graphite laminate 501.

The graphite laminate 501 and the high-temperature site 540 are preferably provided so as to be in close contact with each other. Furthermore, the graphite laminate 501 and the low-temperature site 541 are preferably provided so as to be in close contact with each other. This configuration allows heat to be transported efficiently from the high-temperature site 540 to the low-temperature site 541.

The graphite laminate 501 may be provided so as to be in close contact with the electronic components 550. The graphite laminate 501 may alternatively be provided so as to be separated from the electronic components 550 by a desired distance. The graphite laminate 501 is preferably provided so as to be separated from the electronic components 550 by a desired distance in order to prevent heat from being transferred from the graphite laminate 501 to the electronic components 550.

In (b) of FIG. 28, one electronic component 550 is provided in a device, and a high-temperature site 540 is provided laterally to one side of the electronic component 550, while a low-temperature site 541 is provided laterally to another side of the electronic component 550. With such an arrangement, since a graphite laminate 501 has a concave shape, it is possible to provide the graphite laminate 501, the high-temperature site 540, the low-temperature site 541, and the electronic component 550 within a small space while also reliably connecting the high-temperature site 540 to the low-temperature site 541 via the graphite laminate 501.

The graphite laminate 501 and the high-temperature site 540 are preferably provided so as to be in close contact with each other. Furthermore, the graphite laminate 501 and the low-temperature site 541 are preferably provided so as to be in close contact with each other. This configuration allows heat to be transported efficiently from the high-temperature site 540 to the low-temperature site 541.

The graphite laminate 501 may be provided so as to be in close contact with the electronic components 550. The graphite laminate 501 may alternatively be provided so as to be separated from the electronic components 550 by a desired distance. The graphite laminate 501 is preferably provided so as to be separated from the electronic components 550 by a desired distance in order to prevent heat from being transferred from the graphite laminate 501 to the electronic components 550.

### EXAMPLES

### Example Set A

<Measurement of Thermal Conductivity>

A measurement device as illustrated in FIG. 23 was used to make a measurement as described below, and the thermal conductivity was then calculated.

(1) An end 328 of a rod-shaped heat transporter 301 was brought into contact with running water 323 (low-temperature site) and kept at 20° C.

(2) A heater 322 (high-temperature site) was attached to an end 327 of the rod-shaped heat transporter 301. A thermocouple 325 was attached to the portion of the rod-shaped heat transporter 301 at which portion the end 327 was in contact with the rod-shaped heat transporter 301. A thermocouple 326 was attached to the portion of the rod-shaped heat transporter 301 at which portion the running water 323 was in contact with the end 328. The temperature measured with use of the thermocouple 325 is the temperature T of the high-temperature site, whereas the temperature measured with use of the thermocouple 326 is the temperature (20° C.) of the low-temperature site.

(3) The rod-shaped heat transporter 301 was covered with a heat insulating material 324 except for the low-temperature site.

(4) The output Q of the heater 322 was adjusted to keep the temperature of the high-temperature site constant. After these operations, the thermal conductivity A was calculated via the following formula:

λ= [symbol] ×L/S(T−20° C.)

(Where S represents a cross section of the rod-shaped heat transporter 301, and L represents the length in the axis direction of the rod-shaped heat transporter 301.) The output Q of the heater 322 was determined for a case where the heater 322 has been adjusted so that the high-temperature site has a temperature of 100° C., and the output

Q of the heater 322 was determined also for a case where the heater 322 has been adjusted so that the high-temperature site has a temperature of 50° C. Then, the thermal conductivity (λₐ) for the case where the high-temperature site has a temperature of 100° C. was determined, and the thermal conductivity (λ_{b}) for the case where the high-temperature site has a temperature of 50° C. was also determined.

<Deformation Rate>

Deformation rate was calculated as follows. As in (1) in FIG. 26, the opposite ends of a rod-shaped heat transporter 301 were held with use of a first clamp 312 and a second clamp 313, respectively, in such a manner that the rod-shaped heat transporter 301 was parallel to the ground. Then, the second clamp 313 was removed as in (2) in FIG. 26. A vertical distance x was measured as the distance between (i) a position of a center of an end of the rod-shaped heat transporter prior to the removal of the second clamp 313 and (ii) a position of the center of the end of the rod-shaped heat transporter having been lowered subsequent to the removal of the second clamp 313. The length L of the rod-shaped heat transporter was also measured. The deformation rate of the rod-shaped heat transporter was calculated as x/L.

As in (1) in FIG. 26, the length L of the rod-shaped transporter was determined as the length of a portion of the rod-shaped heat transporter which portion is held by neither the first clamp 312 nor the second clamp 313. In other words, the length L of the rod-shaped transporter was determined as a length obtained by subtracting (i) portions of the rod-shaped heat transporter which portions are held by the first clamp 312 or the second clamp 313 from (ii) the entire length of the rod-shaped heat transporter.

<Graphite Sheet>

Utilized in the Examples of Example Set A was a graphite sheet which is obtained by heat treating a polymeric film (polyimide film) and has a thickness of 40 μm, a surface direction thermal conductivity of 1,450 W/mK, a density of 2.1 g/cm³, and an electrical conductivity of 14,000 S/cm. This type of graphite sheet is called “GS1” herein.

### Example 1A

GS1 graphite sheets and PET films (thickness: 5 μm; dielectric constant: 3.2; melting point: 260° C.) each measuring 200 mm×200 mm were disposed alternately on top of each other to form a laminate having 20 layers. A pressing machine heated to 250° C. was used to pressurize the laminate for 1 minute at a pressure of 0.5 MPa. This produced a laminate (thickness: 0.8 mm). The laminate thus produced was cut into a rod-shaped heat transporter measuring 2.7 mm×0.8 mm×90 mm.

The thermal conductivity of the rod-shaped heat transporter thus produced was λₐ=1,100 W/m·K and λ_{b}=1,200 W/m·K. The ratio of the former to the latter was λₐ/λ_{b}=0.92. The deformation rate of the rod-shaped heat transporter was not more than 1%.

### Example 2A

GS1 graphite sheets and PET films (thickness: 5 μm; dielectric constant: 3.2; melting point: 260° C.) each measuring 200 mm×200 mm were disposed alternately on top of each other to form a laminate having 68 layers. A pressing machine heated to 250° C. was used to pressurize the laminate for 1 minute at a pressure of 0.5 MPa. This produced a laminate (thickness: 2.7 mm). The laminate thus produced was cut into a rod-shaped heat transporter measuring 2.7 mm×0.8 mm×90 mm.

The thermal conductivity of the rod-shaped heat transporter thus produced was λₐ=1,150 W/m·K and λ_{b}=1,250 W/m·K. The ratio of the former to the latter was λₐ/λ_{b}=0.92. The deformation rate of the rod-shaped heat transporter was not more than 1%.

### Example 3A

GS1 graphite sheets and PET films (thickness: 5 μm; dielectric constant: 3.2; melting point: 260° C.) each measuring 200 mm×200 mm were disposed alternately on top of each other to form a laminate having 68 layers. A pressing machine heated to 250° C. was used to pressurize the laminate for 1 minute at a pressure of 0.5 MPa. This produced a laminate (thickness: 2.7 mm). The laminate thus produced was cut into a rod-shaped heat transporter measuring 2.7 mm×2.7 mm×90 mm.

The thermal conductivity of the rod-shaped heat transporter thus produced was λₐ=1,140 W/m·K and λ_{b}=1,240 W/m·K. The ratio of the former to the latter was λₐ/λ_{b}=0.92. The deformation rate of the rod-shaped heat transporter was not more than 1%.

### Example 4A

The rod-shaped heat transporter obtained in Example 3 was processed by grinding it into a rod-shaped heat transporter having a circular cross section whose diameter was 2 mm (2 mm along both short and long axes of the cross section).

The thermal conductivity of the rod-shaped heat transporter thus produced was λₐ=1,100 W/m·K and λ_{b}=1,200 W/m·K. The ratio of the former to the latter was λₐ/λ_{b}=0.92. The deformation rate of the rod-shaped heat transporter was not more than 1%.

### Example 5A

GS1 graphite sheets and PET films (thickness: 5 μm; dielectric constant: 3.2; melting point: 260° C.) each measuring 200 mm×200 mm were disposed alternately on top of each other to form a laminate having 20 layers. A pressing machine heated to 250° C. was used to pressurize the laminate for 1 minute at a pressure of 0.5 MPa. This produced a laminate (thickness: 0.8 mm). The laminate thus produced was cut into a rod-shaped heat transporter measuring 2.7 mm×0.8 mm×180 mm.

The thermal conductivity of the rod-shaped heat transporter thus produced was λₐ=1,100 W/m·K and λ_{b}=1,200 W/m·K. The ratio of the former to the latter was λₐ/λ_{b}=0.92. The deformation rate of the rod-shaped heat transporter was not more than 1%.

### Example 6A

A laminator was used to bond an acrylic double-sided tape 1 (Teraoka Seisakusho Co., Ltd. 707: acrylic 13 μm/PET 4 μm/acrylic 13 μm) to one side of a GS1 graphite sheet. This produced a graphite film having an adhesive. A plurality of these graphite films were disposed on top of each other by pushing each graphite film into a box mold, while bending each graphite film in the same direction into a given shape, so as to cause each graphite film to bond to another one of the graphite films. A pressing machine was then used to apply a pressure of 0.5 MPa to the resulting stack for 1 minute. This produced a graphite rectangular parallelepiped block measuring 300 mm×100 mm×100 mm. The laminate thus produced was cut into a rod-shaped heat transporter measuring 2.7 mm×2.7 mm×90 mm.

The thermal conductivity of the rod-shaped heat transporter thus produced was λₐ=900 W/m·K and λ_{b}=1,000 W/m·K. The ratio of the former to the latter was λₐ/λ_{b}=0.90. The deformation rate of the rod-shaped heat transporter was not more than 1%.

### Comparative Example 1A

A heat pipe (2.7 mm×0.8 mm×9.0 mm) used in a smartphone (MEDIAS X N-06E) manufactured by NEC was removed from the smartphone, and the thermal conductivity of the heat pipe was measured.

The thermal conductivity of the heat pipe was λₐ=660 W/m·K and λ_{b}=1,100 W/m·K. The ratio of the former to the latter was λₐ/λ_{b}=0.6. The deformation rate of the heat pipe was not more than 1%.

From the above, it is clear that (i) the rod-shaped heat transporter of the present invention has a thermal conductivity which remains substantially constant even when the temperature of the rod-shaped heat transporter rises and (ii) the range of temperatures at which the rod-shaped heat transporter of the present invention can be used is greater than that of a heat pipe.

### Example Set B

<B-1. Graphite Sheet>

(Basic Configuration of Graphite Sheet)

The respective configurations of graphite sheets used in Example Set B are indicated in Table 1 and in the description below.

One type of graphite sheet used is obtained by heat treating a polymeric film (polyimide film) and has a thickness of 40 μm, a surface direction thermal conductivity of 1,300 W/mK, a density of 2.0 g/cm³, a surface roughness Ra of 1.5 μm, and an electrical conductivity of 12,000 S/cm. This type of graphite sheet is called “GS1” herein.

Another type of graphite sheet used is obtained by heat treating a polymeric film (polyimide film) and has a thickness of 40 μm, a surface direction thermal conductivity of 1,450 W/mK, a density of 2.1 g/cm³, a surface roughness Ra of 1.5 μm, and an electrical conductivity of 14,000 S/cm. This type of graphite sheet is called “G52” herein.

Another type of graphite sheet used is obtained by heat treating a polymeric film (polyimide film) and has a thickness of 40 μm, a surface direction thermal conductivity of 1,300 W/mK, a density of 2.0 g/cm³, a surface roughness Ra of 0.7 μm, and an electrical conductivity of 12,000 S/cm. This type of graphite sheet is called “G53” herein.

Another type of graphite sheet used is obtained by heat treating a polymeric film (polyimide film) and has a thickness of 40 μm, a surface direction thermal conductivity of 800 W/mK, a density of 1.25 g/cm³, a surface roughness Ra of 1.5 μm, and an electrical conductivity of 7,500 S/cm. This type of graphite sheet is called “G54” herein.

Another type of graphite sheet used is obtained by heat treating a polymeric film (polyimide film) and has a thickness of 100 μm, a surface direction thermal conductivity of 600 W/mK, a density of 1.0 g/cm³, a surface roughness Ra of 1.5 μm, and an electrical conductivity of 5,000 S/cm. This type of graphite sheet is called “GS5” herein.

Another type of natural graphite sheet used has a thickness of 240 μm, a surface direction thermal conductivity of 200 W/mK, a density of 1.0 g/cm³, a surface roughness Ra of 3 μm, and an electrical conductivity of 1,500 S/cm. This type of graphite sheet is called “G56” herein.

(Thickness of Graphite Sheet)

The thickness of a graphite sheet was measured using a thickness gauge (“Heidenhain-CERTO,” manufactured by Heidenhain Corporation). A 50 mm×50 mm sample was cut from the graphite sheet, and the sample was measured at 10 given points in a temperature controlled room at 25° C. The thickness of the graphite sheet was then calculated as the average value of these measurements.

(Density of Graphite Sheet)

The density of a graphite sheet was calculated as follows. First, a 100 mm×100 mm sample was cut from the graphite sheet, and the weight and thickness thereof were measured. Density was then calculated by dividing the value of the measured weight by the value of a calculated volume (100 mm×100 mm×thickness).

(Electrical Conductivity of Graphite Sheet)

The electrical conductivity of a graphite sheet was measured by applying a constant current in a four-point probe method (for example, by using the Loresta-GP, manufactured by Mitsubishi Chemical Analytech Co., Ltd.).

(Thermal Conductivity of Graphite Sheet)

The following Formula (1) was used to calculate the thermal conductivity of a graphite sheet in the surface direction.

A=a×d×Cp (1)

(Where A represents thermal conductivity of a graphite sheet, a represents thermal diffusivity of the graphite sheet, d represents density of the graphite sheet, and Cp represents specific thermal capacity of the graphite sheet.)

Note that the thermal diffusivity, density, and specific thermal capacity of the graphite sheet were determined by use of methods described later.

The thermal diffusivity of the graphite sheet was measured in the following manner. A sample having a size of 4 mm×40 mm was cut out from the graphite sheet, and the thermal diffusivity of the sample was measured using a thermal diffusivity measurement device which employs the light alternating-current method (for example, “LaserPit” manufactured by ULVAC-RIKO, Inc.), in an atmosphere whose temperature was 20° C., and at a 10 Hz alternating current.

The density of a graphite sheet was calculated as follows. First, a 100 mm×100 mm sample was cut from the graphite sheet, and the weight and thickness thereof were measured. Density was then calculated by dividing the value of the measured weight by the value of a calculated volume (100 mm×100 mm×thickness).

The specific thermal capacity of a graphite sheet was measured using the differential scanning calorimeter DSC220CU, which is a thermal analysis system manufactured by SII NanoTechnology Inc. Measurements were carried out as temperature was increased at a rate of 10° C. per minute, from 20° C. to 260° C.

(Surface Roughness of Graphite Sheet)

Surface roughness of a graphite sheet was measured using the “Portable Surface Roughness Tester SJ-210” manufactured by Mitutoyo Corp.

In Table 1, a surface roughness Ra measurement of 1.0 μm or greater is indicated as “B”, whereas a surface roughness Ra measurement of less than 1.0 μm is indicated as “A.”

<B-2. Adhesive Layer>

(Basic Configuration of Adhesive Layer)

The respective configurations of adhesive layers used in Example Set B are indicated in Table 2 and in the description below.

The adhesive layers were made from polyester-based adhesive, PET (polyethylene terephthalate, melting point: 260° C.), polyethylene (PE), acrylic double-sided tape, a polyimide precursor, or a silicone rubber sheet. Table 2 indicates details regarding the physical properties of each adhesive layer. The following description discusses methods by which the various physical properties were measured.

(Glass Transition Point of Adhesive Layer)

The glass transition point of an adhesive layer was measured via differential scanning calorimetry (using the “DSC-50,” manufactured by Shimadzu Corporation, at a temperature increase rate of 1° C./min).

(Thickness of Adhesive Layer)

The thickness of an adhesive layer was measured using a thickness gauge (“Heidenhain-CERTO,” manufactured by Heidenhain Corporation). A 50 mm×50 mm sample was cut from the adhesive layer, and the sample was measured at 10 given points in a temperature controlled room at 25° C. The thickness of the adhesive layer was then calculated as the average value of these measurements.

(Dielectric Constant of Adhesive Layer)

The dielectric constant of an adhesive layer was measured using the “AS-4245” manufactured by Ando Electric Co., Ltd. Measurements were carried out at a frequency of 1 kHz, after first leaving the adhesive layer for 24 hours in an environment having a temperature of 20° C. and a humidity of 60%.

(Water Absorption Rate of Adhesive Layer)

The water absorption rate of an adhesive layer was measured in conformance with JIS K 7209. The measurement involved comparing (i) the mass of the adhesive layer in a dry state to (ii) the mass of the adhesive layer after being immersed in water for 24 hours.

(Outgassing)

The occurrence or absence of outgassing from an adhesive layer was checked by heating a sample of the adhesive layer to 150° C. and then checking for gas via gas chromatography.

(Breaking Strength of Adhesive Layer)

The tension testing machine “TENSILON UTM-2” (manufactured by A&D Company, Limited.) was used to measure the breaking strength of an adhesive layer. Specifically, an adhesive layer was cut so as to measure 3 mm×35 mm and was fixed to a jig. The jig was set in the tension testing machine such that the center of the film coincided with the center of the testing machine. Chuck interval was set to 20 mm. A tension test was then carried out at a crosshead speed of 8 mm/min, and the breaking strength was measured.

(Adhesive Force of Adhesive Layer)

The adhesive force of an adhesive layer was determined in conformance with JIS-Z0237, method 1 (“Method for testing adhesion in 180° peeling from test plate”). A stainless steel plate (width: 50 mm; length: 125 mm; thickness: 1.1 mm; surface roughness Ra: 50 nm) as described in JIS-Z0237 was cleaned with methanol. A 2 kg roller was used to apply a protective layer measuring 20 mm×300 mm to the stainless steel plate thus cleaned. Specifically, the roller was rolled back and forth over the protective layer twice so as to prevent air from remaining between the protective layer and the stainless steel plate. This application was performed in an environment having a temperature of 23° C. and a humidity of 50%. The protective layer was then left for 1 hour. Thereafter, a testing machine (“Autograph”; model number: AG-10 TB) and a 50 N load cell (model number: SBL-50N), each manufactured by SIMAZU were used to pull the protective layer, under the same temperature and humidity conditions as above, at a rate of 300 mm/min, and the 180° peeling adhesion was measured. The values of three such measurements were averaged, using a unit of N/25 mm. Each average value was rounded to the nearest thousandth.

<3. Graphite Laminate>

(Method for Producing Graphite Laminates of Comparative Examples 1B, 3B, 5B and 7B and Reference Examples 1B and 2B)

A laminator was used to bond each adhesive layer indicated in Table 2 to one side of a respective one of the graphite sheets indicated in Table 1. Each of the graphite sheets measured 200 mm×300 mm (and had a thickness as indicated in Table 1).

Each resulting graphite sheet having an adhesive layer was then stacked in a number of layers as indicated in Table 3 to produce a laminate. A pressing machine was then used to pressurize each laminate for 1 minute at a pressure of 0.5 MPa. This produced respective graphite blocks each having biaxially oriented graphite crystals.

Each graphite block thus produced was cut with a carbide-tipped saw angled at 90° with respect to a crystal plane of the graphite. This produced the respective graphite laminates indicated in Table 3. Note that in the present Examples, a crystal plane as observed using an x-ray diffraction instrument (manufactured by Rigaku Corporation) was considered to be the crystal plane of the graphite.

(Method for Producing Graphite Laminates of Example 4B, Comparative Examples 2B, 4B, and 6B, and Reference Example 3B)

Each graphite sheet indicated in Table 1 (each measuring 200 mm×300 mm; thickness being as indicated in Table 1) was stacked alternately with a corresponding adhesive layer indicated in Table 2 in a number of layers as indicated in Table 3 to produce a laminate. A pressing machine heated to 180° C. was then used to pressurize each laminate for 1 minute at a pressure of 0.5 MPa. This produced respective graphite blocks each having biaxially oriented graphite crystals.

Each graphite block thus produced was cut with a carbide-tipped saw angled at 90° with respect to a crystal plane of the graphite. This produced the respective graphite laminates indicated in Table 3.

(Method for Producing Graphite Laminates of Examples 1B, 5B, 7B, 9B, 11B and 13B)

A polyester-based adhesive (manufactured by Jujo Chemical Co., Ltd.) was applied to one side of each of the graphite sheets indicated in Table 1, such that the polyester-based adhesive would have a thickness of 3 μm after drying. This produced respective graphite sheets each having an adhesive layer.

Each resulting graphite sheet having an adhesive layer was then stacked in a number of layers as indicated in Table 3 to produce a laminate. A hot pressing machine heated to 100° C. was then used to pressurize each laminate for 10 minutes at a pressure of 0.5 MPa. This produced respective graphite blocks each having biaxially oriented graphite crystals.

Each graphite block thus produced was cut at an angle of 90° with respect to a crystal plane of the graphite. This produced the respective graphite laminates indicated in

Table 3.

(Method for Producing Graphite Laminates of Examples 2B, 3B, 6B, 8B, 10B, 12B, and 14B Through 17B)

Each graphite sheet indicated in Table 1 was stacked alternately with a corresponding adhesive layer indicated in Table 2 in a number of layers as indicated in Table 3 to produce a laminate. A pressing machine heated to 250° C. was then used to pressurize each laminate for 1 minute at a pressure of 0.5 MPa. This produced respective graphite blocks each having biaxially oriented graphite crystals.

Each graphite block thus produced was cut at an angle of 90° with respect to a crystal plane of the graphite. This produced the respective graphite laminates indicated in Table 3.

(Method for Producing Graphite Laminate of Reference Example 4B)

To a graphite film, a polyimide precursor (“TORAYNEECE,” manufactured by Toray Industries, Inc.) was applied in the form of a solution so as to have a thickness of 10 μm. Then, after drying under reduced pressure, the graphite film was stacked in 20 layers while imidization had not yet completely progressed. These layers were then pressure-bonded under heat to produce a graphite laminate. The pressure bonding under heat was performed at a temperature of 300° C. and a pressure of 10 Kg/cm².

(Method for Producing Graphite Laminate of Reference Example 5B)

A graphite laminate was produced using (i) a graphite sheet measuring approximately 50 mm both lengthwise and widthwise, the graphite sheet having a thickness of approximately 0.1 mm and an in-plane direction thermal conductivity of 600 W/mK and (ii) a rubber sheet (made from EPDM; modulus of elasticity: 1.7 MPa) measuring approximately 50 mm both lengthwise and widthwise, the rubber sheet having a thickness of approximately 0.4 mm.

Specifically, silicone-based adhesive was applied to both sides of the graphite sheet so as to have a thickness of approximately 0.5 mm on both sides. Thereafter, 17 layers of the graphite sheet and 18 layers of the rubber sheet were disposed alternately on top of each other. A resulting stack was then pressurized from a vertical direction (a direction substantially orthogonal to a sheet surface of the graphite sheets) so as to cause the sheets to adhere to each other. This produced a laminate having a thickness of approximately 10 mm (in the graphite sheets of the laminate produced, the a-b plane of graphite crystals and the sheet surface of the graphite sheets were substantially parallel). This laminate was cut to produce a graphite laminate having a thickness of 1 mm.

(Method for Producing Graphite Laminate of Example 18B)

In Example 2, after heated pressing of the laminate, an NC cutter was used to cut the laminate into the shape illustrated in FIG. 17 so as to obtain a graphite laminate having a bent portion. The graphite laminate measured 90 mm (along a long side direction of a surface perpendicular to the direction in which layers are disposed on top of each other)×2.75 mm (along a short side direction of the surface perpendicular to the direction in which layers are disposed on top of each other)×0.8 mm (along the direction in which layers are disposed on top of each other).

(Method for Producing Graphite Laminate of Example 19B)

In Example 2, a mold having a bent portion, as illustrated in FIG. 6, was used during heated pressing of the laminate. Thereafter, a single-wire saw was used to cut the laminate, perpendicularly to the direction in which layers are disposed on top of each other, so as to obtain a graphite laminate having a bent portion as illustrated in FIG. 18. The graphite laminate measured 90 mm (along a long side direction of a surface perpendicular to the direction in which layers are disposed on top of each other)×0.8 mm (along a short side direction of the surface perpendicular to the direction in which layers are disposed on top of each other)×2.75 mm (along the direction in which layers are disposed on top of each other).

(Thickness of Graphite Laminate)

The thickness of a graphite sheet was measured using a thickness gauge (“Heidenhain-CERTO,” manufactured by Heidenhain Corporation). A 50 mm×50 mm sample was cut from the graphite sheet, and the sample was measured at 10 given points in a temperature controlled room at 25° C. The thickness of a graphite laminate was then calculated by using an average value of these measurements.

(Compression Rate of Graphite Laminate)

In the following formula for calculating the compression rate of a graphite laminate, the thickness of each graphite sheet included as a material of the graphite laminate is represented as A1 (μm), and the number of graphite sheet layers is represented as B1 (number of layers). The thickness of each adhesive layer included as a material of the graphite laminate is represented as A2 (μm), and the number of adhesive layers is represented as B2 (number of layers).

The measured value of thickness of the graphite laminate is represented as X (μm), and the compression rate of the graphite laminate is represented as Y. Y was calculated in accordance with the following formula:

Y=X÷(A1×B1+A2×B2)

(Thermal Conductivity [Measured Value] of Graphite Laminate)

The thermal conductivity of a graphite laminate in the surface direction can be calculated in accordance with Formula (2) as follows:

A₁=a₁×d₁×Cp₁ (2)

(Where A₁ represents thermal conductivity of a graphite laminate, a₁ represents thermal diffusivity of the graphite laminate, d₁ represents density of the graphite laminate, and Cp₁ represents specific thermal capacity of the graphite laminate.) Note that the thermal diffusivity, density, and specific thermal capacity of the graphite laminate can be determined by use of methods described later.

The thermal diffusivity of a graphite laminate can be measured by (i) cutting out a graphite sheet sample having a size of 4 mm×40 mm, and (ii) measuring the thermal diffusivity of the sample using a thermal diffusivity measurement device which employs the light alternating-current method (for example, “LaserPit” manufactured by ULVAC-RIKO, Inc.), in an atmosphere whose temperature is 20° C., and at a 10 Hz alternating current.

The density of a graphite laminate can be calculated by (i) cutting a 100 mm×100 mm sample from the graphite laminate, (ii) measuring the weight and thickness thereof, and (iii) calculating the density by dividing the value of the measured weight by the value of a calculated volume (100 mm×100 mm×thickness).

The specific thermal capacity of a graphite laminate can be measured using the differential scanning calorimeter DSC220CU, which is a thermal analysis system manufactured by SII NanoTechnology Inc. Measurements can be carried out as temperature is increased at a rate of 10° C. per minute, from 20° C. to 260° C.

(Thermal Conductivity [Theoretical Value] of Graphite Laminate)

The thermal conductivity (theoretical value) of a graphite laminate was calculated as follows: (thermal conductivity of graphite sheet)×(total thickness of graphite sheets)÷(thickness of laminate).

(Thermal Conductivity [Closeness to Theoretical Value] of Graphite Laminate)

The thermal conductivity (closeness to theoretical value) of a graphite laminate was calculated as follows: (measured value of thermal conductivity)+(theoretical value of thermal conductivity).

(Layer Disposal Workability of Graphite Laminate)

The layer disposal workability of a graphite laminate was evaluated visually.

A case where wrinkling occurred in the entirety of an adhesive layer when disposed onto a graphite sheet was evaluated as “D.” A case where wrinkling occurred in part of an adhesive layer when disposed onto a graphite sheet was evaluated as “C.” A case where wrinkling did not easily occur in an adhesive layer when disposed onto a graphite sheet was evaluated as “B.” A case where no wrinkling occurred in an adhesive layer when disposed onto a graphite sheet was evaluated as “A.”

(Bubble Entrapment in Graphite Laminate)

Bubble entrapment in a graphite laminate was evaluated visually.

A case where a bubble(s) caused a graphite laminate to become deformed was evaluated as “D.” A case where bubbles were present in a graphite laminate throughout the entirety thereof was evaluated as “C.” A case where a bubble(s) was present in part of a graphite laminate was evaluated as “B.” A case where no bubbles were present in a graphite laminate was evaluated as “A.”

(Cuttability of Graphite Laminate)

Cuttability of a graphite laminate was evaluated visually.

A case where a graphite sheet layer became detached upon cutting a graphite laminate to a thickness of 2 mm was evaluated as “F.” A case where a graphite sheet layer became partially detached upon cutting in the same manner was evaluated as “E.” A case where, upon cutting in the same manner, no graphite sheet became detached but a graphite laminate became deformed was evaluated as “D.” A case where, upon cutting in the same manner, no graphite sheet became detached but a graphite laminate became slightly deformed was evaluated as “C.” A case where, upon cutting in the same manner, no graphite sheet became detached and no deformation occurred in a graphite sheet layer was evaluated as “B.” A case where, upon cutting a graphite laminate to a thickness of 1.5 mm, no graphite sheet became detached and no deformation occurred in the graphite laminate was evaluated as “A.”

(Hardness of Graphite Laminate)

One end of a graphite laminate was fixed in such a manner that the graphite laminate was horizontal with respect to the ground, and a surface of the graphite laminate was marked at a position 4 cm away from the end fixed thusly. A load was then imposed at the position thus marked, the load being 0.7 g per 1 mm² of a cross section of the graphite laminate at the position thus marked. A distance (displacement) between (i) the position of marking before imposing the load and (ii) the position of marking after imposing the load was measured.

More specifically, used was a sample having a quadrangular shape such that a surface thereof measured 16 mm (widthwise direction)×65 mm (lengthwise direction). Tape was used to fix 10 mm of a lengthwise end of the sample. Thereafter, a circular weight having a diameter of 20 mm was placed onto a surface of the sample at a position 4 cm away from the end thus fixed. The weight and the sample were fixed to each other via tape so that the weight would not slip and fall from the sample. The weight and the sample were arranged such that the respective centers of the weight the sample were aligned with each other.

In a case where the weight of the weight is expressed as W (g), the thickness of the sample is expressed as T (mm), and the width of the sample is expressed as L (mm), the width L (mm), which is a dimension of the sample in the widthwise direction, is 16 (mm), and the thickness T (mm) is the “Thickness (mm)” indicated in Table 3. The weight of the weight can be calculated by using the following formula:

W (g)=[Width of sample (mm)]×[Thickness of sample (mm)]×0.7 (g)=16×L×0.7

In the above formula, “L” can be substituted with the “Thickness (mm)” indicated in Table 3.
A displacement of 12 mm was observed in the case of Examples 1B through 4B and 9B through 19B. A displacement of 14 mm was observed in the case of Examples 5B and 6B. A displacement of 10 mm was observed in the case of Examples 7B and 8B. In the case of Comparative Examples 1B through 6B, however, a displacement of 22 mm was observed. In the case of Comparative Example 7B, a displacement of 18 mm was observed. In this manner, the Examples each exhibited a displacement whose value was less than that of each of the Comparative Examples. This indicates that the respective graphite laminates of the Examples are harder than those of the Comparative Examples. Greater hardness of a graphite laminate results in better handleability thereof and can therefore said to be preferable.

TABLE 1

| | GS | | | | | |
|---|---|---|---|---|---|---|
| | | | | Electrical | Thermal | |
| | Kind | Thickness | Density | conductivity | conductivity | Surface |
| | of GS | [μm] | [g/cm³] | [S/cm] | [W/mk] | roughness |
| Example 1B | GS1 | 40 | 2.0 | 12000 | 1300 | B |
| Example 2B | GS1 | 40 | 2.0 | 12000 | 1300 | B |
| Example 3B | GS1 | 40 | 2.0 | 12000 | 1300 | B |
| Example 4B | GS1 | 40 | 2.0 | 12000 | 1300 | B |
| Example 5B | GS1 | 40 | 2.0 | 12000 | 1300 | B |
| Example 6B | GS1 | 40 | 2.0 | 12000 | 1300 | B |
| Example 7B | GS1 | 40 | 2.0 | 12000 | 1300 | B |
| Example 8B | GS1 | 40 | 2.0 | 12000 | 1300 | B |
| Example 9B | GS1 | 40 | 2.0 | 12000 | 1300 | B |
| Example 10B | GS1 | 40 | 2.0 | 12000 | 1300 | B |
| Example 11B | GS2 | 40 | 2.1 | 14000 | 1450 | B |
| Example 12B | GS2 | 40 | 2.1 | 14000 | 1450 | B |
| Example 13B | GS3 | 40 | 2.0 | 12000 | 1300 | A |
| Example 14B | GS3 | 40 | 2.0 | 12000 | 1300 | A |
| Example 15B | GS1 | 25 | 2.0 | 12000 | 1300 | B |
| Example 16B | GS1 | 80 | 2.0 | 12000 | 1300 | B |
| Example 17B | GS1 | 150 | 2.0 | 12000 | 1300 | B |
| Example 18B | GS1 | 40 | 2.0 | 12000 | 1300 | B |
| Example 19B | GS1 | 40 | 2.0 | 12000 | 1300 | B |
| Comparative | GS1 | 40 | 2.0 | 12000 | 1300 | B |
| Example 1B | | | | | | |
| Comparative | GS1 | 40 | 2.0 | 12000 | 1300 | B |
| Example 2B | | | | | | |
| Comparative | GS1 | 40 | 2.0 | 12000 | 1300 | B |
| Example 3B | | | | | | |
| Comparative | GS1 | 40 | 2.0 | 12000 | 1300 | B |
| Example 4B | | | | | | |
| Comparative | GS6 | 240 | 1.0 | 1500 | 200 | B |
| Example 5B | | | | | | |
| Comparative | GS6 | 240 | 1.0 | 1500 | 200 | B |
| Example 6B | | | | | | |
| Comparative | GS1 | 40 | 2.0 | 12000 | 1300 | B |
| Example 7B | | | | | | |
| Reference | GS1 | 40 | 2.0 | 12000 | 1300 | B |
| Example 1B | | | | | | |
| Reference | GS1 | 40 | 2.0 | 12000 | 1300 | B |
| Example 2B | | | | | | |
| Reference | GS1 | 40 | 2.0 | 12000 | 1300 | B |
| Example 3B | | | | | | |
| Reference | GS4 | 40 | 1.25 | 7500 | 800 | B |
| Example 4B | | | | | | |
| Reference | GS5 | 100 | 1.0 | 5000 | 600 | B |
| Example 5B | | | | | | |

TABLE 2

| | Adhesive layer | | | | | | | |
|---|---|---|---|---|---|---|---|---|
| | | Glass | | | Water | | Breaking | Adhesive |
| | Adhesive | transition | Thickness | Dielectric | absorption | Out- | strength | force |
| | layer | point [° C.] | [μm] | constant | rate [%] | gas | [GPa] | [N/25 mm] |
| Ex 1B | PA | 90 | 5 | 3.6 | 0.4 | No | 1.0 | 0 |
| Ex 2B | PET | 80 | 5 | 3.2 | 0.1 | No | 4.7 | 0 |
| Ex 3B | PET | 80 | 5 | 3.2 | 0.1 | No | 4.7 | 0 |
| Ex 4B | PE | <0 | 5 | 2.3 | <0.1 | No | 0.2 | 1 |
| Ex 5B | PA | 90 | 1 | 3.6 | 0.4 | No | 1.0 | 0 |
| Ex 6B | PET | 80 | 1 | 3.2 | 0.1 | No | 4.7 | 0 |
| Ex 7B | PA | 90 | 9 | 3.6 | 0.4 | No | 1.0 | 0 |
| Ex 8B | PET | 80 | 9 | 3.2 | 0.1 | No | 4.7 | 0 |
| Ex 9B | PA | 90 | 5 | 3.6 | 0.4 | No | 1.0 | 0 |
| Ex 10B | PET | 80 | 5 | 3.2 | 0.1 | No | 4.7 | 0 |
| Ex 11B | PA | 90 | 5 | 3.6 | 0.4 | No | 1.0 | 0 |
| Ex 12B | PET | 80 | 5 | 3.2 | 0.1 | No | 4.7 | 0 |
| Ex 13B | PA | 90 | 5 | 3.6 | 0.4 | No | 1.0 | 0 |
| Ex 14B | PET | 80 | 5 | 3.2 | 0.1 | No | 4.7 | 0 |
| Ex 15B | PET | 80 | 5 | 3.2 | 0.1 | No | 4.7 | 0 |
| Ex 16B | PET | 80 | 5 | 3.2 | 0.1 | No | 4.7 | 0 |
| Ex 17B | PET | 80 | 5 | 3.2 | 0.1 | No | 4.7 | 0 |
| Ex 18B | PET | 80 | 5 | 3.2 | 0.1 | No | 4.7 | 0 |
| Ex 19B | PET | 80 | 5 | 3.2 | 0.1 | No | 4.7 | 0 |
| CE 1B | ADT | <0 | 30 | 3.6 | 1.0 | Yes | 1.0 | >10 |
| CE 2B | PE | <0 | 30 | 2.3 | <0.1 | No | 0.2 | 1 |
| CE 3B | ADT | <0 | 30 | 3.6 | 1.0 | Yes | 1.0 | >10 |
| CE 4B | PE | <0 | 30 | 2.3 | <0.1 | No | 0.2 | 1 |
| CE 5B | ADT | <0 | 30 | 2.3 | 1.0 | Yes | 0.2 | >10 |
| CE 6B | PE | <0 | 30 | 2.3 | <0.1 | No | 0.2 | 1 |
| CE 7B | ADT | <0 | 5 | 3.6 | 2.5 | Yes | 0.2 | >10 |
| RE 1B | ADT | <0 | 30 | 3.5 | 1.0 | Yes | 1.0 | >10 |
| RE 2B | ADT | <0 | 30 | 3.5 | 1.0 | Yes | 1.0 | >10 |
| RE 3B | PE | <0 | 30 | 2.3 | <0.1 | No | 0.2 | 1 |
| RE 4B | Polyimide | <0 | 10 | 3.4 | >5.0 | Yes | 3.0 | 5 |
| | precursor | | | | | | | |
| RE 5B | Silicone | <0 | 400 | 3.5 | 3.0 | No | 1.0 | 2 |
| | rubber sheet | | | | | | | |

Ex stands for Example
CE stands for Comparative Example
RE stands for Reference Example
PA stands for Polyester-based adhesive
ADT stands for Acrylic double-sided tape

TABLE 3

| | Physical properties of graphite laminate | | | | | | | | | | |
|---|---|---|---|---|---|---|---|---|---|---|---|
| | | | Number of | | | Thermal | Thermal | Thermal | | | |
| | | Number of | disposed | | | conductivity | conductivity | conductivity | Layer | | |
| | | disposed | adhesive | | | (measured | (theoretical | (Closeness to | disposal | Bubble | |
| | Thickness | GS | layers | | Compres- | value) | value) | theoretical | work- | entrap- | Cutt- |
| | [mm] | [layers] | [layers] | Tg/Ta | sion rate | [W/mk] | [W/mk] | value) | ability | ment | ability |
| Ex 1B | 0.8 | 20 | 19 | 8.42 | 0.90 | 1060 | 1155.6 | 0.92 | B | A | C |
| Ex 2B | 0.8 | 20 | 19 | 8.42 | 0.90 | 1060 | 1155.6 | 1.00 | B | A | B |
| Ex 3B | 0.8 | 20 | 19 | 8.42 | 0.95 | 1000 | 1155.6 | 0.87 | B | B | D |
| Ex 4B | 0.8 | 20 | 19 | 8.42 | 0.97 | 900 | 1155.6 | 0.78 | B | B | E |
| Ex 5B | 0.8 | 22 | 21 | 41.9 | 0.90 | 1120 | 1268.3 | 0.88 | B | A | C |
| Ex 6B | 0.8 | 22 | 21 | 41.9 | 0.90 | 1220 | 1268.3 | 0.96 | B | A | B |
| Ex 7B | 0.8 | 22 | 21 | 4.66 | 0.90 | 920 | 1061.2 | 0.87 | B | A | C |
| Ex 8B | 0.8 | 22 | 21 | 4.66 | 0.90 | 1010 | 1061.2 | 0.95 | B | A | B |
| Ex 9B | 2.7 | 68 | 67 | 8.12 | 0.88 | 1060 | 1155.6 | 0.92 | B | A | C |
| Ex 10B | 2.7 | 68 | 67 | 8.12 | 0.88 | 1160 | 1155.6 | 1.00 | B | A | B |
| Ex 11B | 0.8 | 20 | 19 | 8.42 | 0.89 | 1200 | 1288.9 | 0.93 | B | A | C |
| Ex 12B | 0.8 | 20 | 19 | 8.42 | 0.89 | 1300 | 1288.9 | 1.01 | A | A | C |
| Ex 13B | 2.7 | 68 | 67 | 8.12 | 0.89 | 1060 | 1155.6 | 0.92 | B | A | B |
| Ex 14B | 2.7 | 68 | 67 | 8.12 | 0.89 | 1160 | 1155.6 | 1.00 | A | A | A |
| Ex 15B | 2.7 | 101 | 100 | 5.05 | 0.89 | 1160 | 1083.3 | 1.07 | A | A | A |
| Ex 16B | 2.7 | 47 | 46 | 16.3 | 0.89 | 1160 | 1223.5 | 0.95 | A | A | A |
| Ex 17B | 2.7 | 29 | 28 | 31.1 | 0.89 | 1160 | 1258.1 | 0.92 | A | A | B |
| Ex 18B | 0.8 | 20 | 19 | 8.42 | 0.90 | 1060 | 1155.6 | 1.00 | B | A | B |
| Ex 19B | 0.8 | 20 | 19 | 8.42 | 0.90 | 1060 | 1155.6 | 1.00 | B | A | B |
| CE 1B | 0.8 | 12 | 11 | 1.45 | 1.00 | 405 | 742.9 | 0.55 | D | C | F |
| CE 2B | 0.8 | 12 | 11 | 1.45 | 1.00 | 470 | 742.9 | 0.63 | C | C | F |
| CE 3B | 2.7 | 38 | 37 | 1.37 | 1.00 | 405 | 742.9 | 0.55 | D | C | F |
| CE 4B | 2.7 | 39 | 38 | 1.37 | 1.00 | 470 | 742.9 | 0.63 | C | C | F |
| CE 5B | 2.7 | 10 | 9 | 8.89 | 1.00 | 90 | 177.8 | 0.51 | C | C | F |
| CE 6B | 2.7 | 10 | 9 | 8.89 | 1.00 | 95 | 177.8 | 0.53 | C | C | F |
| CE 7B | 0.5 | 12 | 11 | 8.73 | 1.00 | 640 | 1155.6 | 0.55 | D | C | F |
| RE 1B | 210 | 3000 | 2999 | 1.33 | 1.00 | 400 | 742.9 | 0.54 | D | C | F |
| RE 2B | 1 | 14 | 13 | 1.44 | 1.02 | 400 | 742.9 | 0.54 | D | D | F |
| RE 3B | 210 | 3000 | 2999 | 1.33 | 1.00 | 470 | 742.9 | 0.63 | C | C | F |
| RE 4B | 1 | 20 | 19 | 4.21 | 1.00 | 400 | 640.0 | 0.63 | D | D | F |
| RE 5B | 1 | 18 | 17 | 0.265 | 1.11 | 95 | 120.0 | 0.79 | D | C | F |

Ex stands for Example
CE stands for Comparative Example
RE stands for Reference Example

(Test Results)

Through testing, it was made clear that each of the Examples were excelled with regard to thermal conductivity (closeness to theoretical value), layer disposal workability, bubble entrapment, and cuttability.

The fact that the Examples each exhibited a thermal conductivity (closeness to theoretical value) that was close to 1.00 indicates that the respective graphite laminates of the Examples have high thermal conductivities.

The fact that the Examples each excelled with regard to layer disposal workability, bubble entrapment, and cuttability indicates that each of the Examples enables favorable disposal and cutting of each layer during production of the respective graphite laminates. Such favorable properties make it possible to produce a graphite laminate in which a void does not easily occur.

Furthermore, in comparison to Comparative Examples 1B through 7B, Examples 1B through 19B each had adhesive layers having lower water absorption rates and higher glass transition points, which led to less bubble entrapment.

### Example Set C

<C-1. Graphite Sheet>

(Basic Configuration of Graphite Sheet)

Utilized in the Examples of Example Set C was a graphite sheet which is obtained by heat treating a polymeric film (polyimide film) and has a thickness of 40 μm, a width of 210 mm, a length of 260 mm, and a surface direction thermal conductivity of 1,300 W/mK.

(Thickness of Graphite Sheet)

The thickness of a graphite sheet was measured using a thickness gauge (“Heidenhain-CERTO,” manufactured by Heidenhain Corporation). A 50 mm×50 mm sample was cut from the graphite sheet, and the sample was measured at 10 given points in a temperature controlled room at 25° C. The thickness of the graphite sheet was then calculated as the average value of these measurements.

<C-2. Adhesive Layer>

(Basic Configuration of Adhesive Layer)

The adhesive layer material used in Example Set C was polyethylene terephthalate (PET, melting point: 260° C.). The following description discusses methods by which the various physical properties were measured.

(Melting Point of Adhesive Layer Material)

The melting point of an adhesive layer was measured in conformance with JIS K 7121, and by using a differential scanning calorimeter (DSC-50, manufactured by Shimadzu Corporation).

<C-3. Graphite Laminate>

(Method for Producing Graphite Laminates of Examples 1C to 11C and Reference Examples 1C to 11C)

A stack was prepared by disposing graphite sheets and an adhesive layer material alternately on top of each other in the number of layers indicated in Table 4. Thereafter, a predetermined pressure was applied to the stack while the stack had a predetermined temperature as indicated in Table 4. This produced a graphite laminate having biaxially oriented graphite crystals. In case where a second pressurizing was performed, the second pressurizing was performed after the first pressurizing.

(Method for Producing Graphite Laminates of Examples 12C to 23C and Reference Examples 12C to 22C)

Stacks were prepared by disposing graphite sheets and an adhesive layer material alternately on top of each other in the number of layers indicated in Table 5. These stacks were then disposed on top of each other in the number indicated in Table 5. Thereafter, a predetermined pressure was applied to the stacks while the stacks had a predetermined temperature as indicated in Table 5. This produced a graphite laminate having biaxially oriented graphite crystals. In case where a second pressurizing was performed, the second pressurizing was performed after the first pressurizing.

As indicated in Tables 4 and 5, in the Examples of Example Set C, the first pressurizing was continuously performed on a stack while the stack was in a temperature range of 20° C. to less than 250° C., and the second pressurizing was continuously performed on the stack while the stack was in a temperature range of 250° C. to 260° C. When polyethylene terephthalate (PET, melting point: 260° C.) is used as the adhesive layer material, [(melting point of adhesive layer material)−20° C.] equals 240° C. In such a case, pressurizing performed in a temperature range of 240° C. to less than 250° C., which temperature range is included in “First pressurizing (° C.)” as indicated Tables 4 and 5, can be thought of as being a pressurizing other than the first and second pressurizings (for example, as being a third pressurizing).

(Peel Strength of Graphite Laminate)

In order to evaluate peel strength of a graphite laminate, a Thomson blade (which is a center blade having a 30 degree bezel) and a 50-ton pressing machine were used to punch out portions from five in-plane points (upper left, lower left, center, upper right, lower right) of a graphite laminate measuring 210 mm wide and 260 mm long, so as to produce five graphite laminates each measuring 210 mm wide and 64 mm long. Each graphite laminate produced thusly was then visually checked to determine whether or not peeling occurred between a graphite sheet and an adhesive layer. A case where peeling was absent in all five graphite laminates produced thusly was evaluated as “3.” A case where peeling occurred in one or two of the graphite laminates produced thusly was evaluated as “2.” A case where peeling occurred in three or more of the graphite laminates produced thusly was evaluated as “1.”

(Adhesion Ratio of Graphite Laminate)

SEM imaging of a graphite laminate was used to inspect a cross section of an interface between an adhesive layer and a graphite sheet. An adhesion ratio of the graphite laminate was then calculated by dividing (i) a length of a portion of the interface in which portion the adhesive layer and graphite sheet were adhered to each other by (ii) the entire length of the interface. SEM imaging was performed via field emission scanning electron microscopy (FE-SEM). The apparatus used was the ULTRAplus (manufactured by Carl Zeiss), and observations were performed on specimens using a secondary electron detector SE2, with acceleration voltage being 5.0 kV. Each sample, having a cross section to be observed, was prepared by embedding a graphite laminate in resin and then using a cross section polisher (CP) to process the graphite laminate embedded in resin.

In Examples 12C to 23C and Reference Examples 12C to 22C, each of which included a plurality of stacks disposed on each other, graphite laminates corresponding to respective stacks disposed in an upper, middle, and lower portion of each respective batch were extracted and observed via SEM imaging in order to evaluate the adhesiveness in each graphite laminate. Here, “upper portion” refers to a stack positioned first from the top, “middle portion” refers to a stack positioned in the vicinity of the middle of the batch, and “lower portion” refers to a stack positioned first from the bottom.

(Thermal Conductivity of Graphite Laminate)

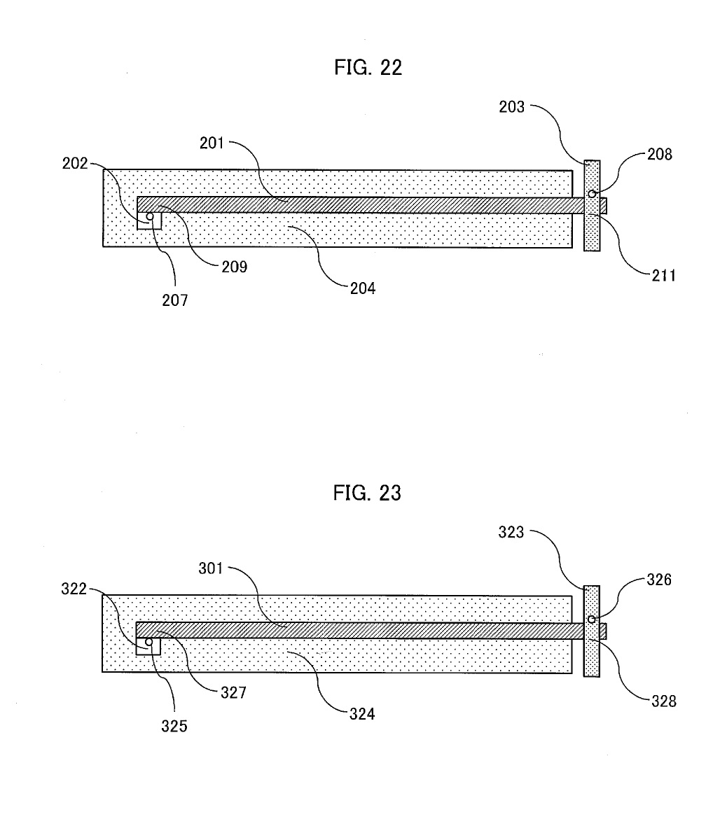

A measurement device as illustrated in FIG. 22 was used to make measurements as described below, and then thermal conductivity (temperature difference between a heater portion and cooling portion) was calculated. An end 211 of a graphite laminate 201 was brought into contact with running water 203 (low-temperature site) to keep the end 211 at 18° C. A heater 202 (high-temperature site) was attached to an end 209 of the graphite laminate 201. A thermocouple 207 was attached to a portion of the graphite laminate 201 at which portion the end 209 is in contact with the graphite laminate 201. The graphite laminate 201 was covered with a heat insulating material 204 except for the low-temperature site. The output of the heater 202 was adjusted to 2 W. The thermal conductivity was then calculated by confirming the difference between the measured temperature of the heater portion and the temperature of the cooling portion. It was determined that a lower value of the thermal conductivity corresponded to a greater thermal conductivity.

(Thickness and Deviation in Thickness of Graphite Laminate)

The thickness and deviation in thickness of a graphite laminate was measured using a thickness gauge (“Heidenhain-CERTO,” manufactured by Heidenhain Corporation). A 50 mm×50 mm sample was cut from the graphite laminate, and the sample was measured at 9 given points in a temperature controlled room at 25° C. The thickness and deviation in thickness of the graphite laminate were then calculated by using the average value of these measurements.

(Smoothness of Graphite Laminate)

From the thicknesses measured at the 9 given points, a maximum value and minimum value were averaged, and the resulting average value was used as a center value. The ratio by which thickness varied from this center value was then calculated. A deviation in thickness of less than ±5% was evaluated as “5.” A deviation in thickness of not less than 5% and not more than 10% was evaluated as “4.” A deviation in thickness of not less than 10% and not more than 15% was evaluated as “3.” A deviation in thickness of not less than 15% and not more than 20% was evaluated as “2.” A deviation in thickness of not less than 20% and not more than 30% was evaluated as “1.”

(External Appearance of Graphite Laminate)

The external appearance of a graphite laminate was evaluated in accordance with the results of a visual inspection for bubble entrapment therein. A case where a bubble(s) caused a graphite laminate to become deformed was evaluated as “1.” A case where bubbles were present in a graphite laminate throughout the entirety thereof was evaluated as “2.” A case where a bubble(s) was present in part of a graphite laminate was evaluated as “3.” A case where no bubbles were present in a graphite laminate was evaluated as “4.”

TABLE 4

| Graphite sheet | Adhering step | | |
|---|---|---|---|
| Number of | Temperature | Pressure | Pressurizing time length |

| | disposed | First | Second | First | Second | First | Second |
|---|---|---|---|---|---|---|---|
| | layers | pressurizing | pressurizing | pressurizing | pressurizing | pressurizing | pressurizing |
| | (layers) | (° C.) | (° C.) | (Mpa) | (Mpa) | (min) | (min) |
| Ex 1C | 3 | 25-<250 | 250-260 | 1 | 5 | 35 | 5 |
| Ex 2C | 5 | 25-<250 | 250-260 | 1 | 5 | 35 | 5 |
| Ex 3C | 10 | 25-<250 | 250-260 | 1 | 5 | 35 | 5 |
| Ex 4C | 50 | 25-<250 | 250-260 | 1 | 5 | 35 | 5 |
| Ex 5C | 5 | 25-<250 | 250-260 | 3 | 5 | 35 | 5 |
| Ex 6C | 5 | 25-<250 | 250-260 | 3 | 7 | 35 | 5 |
| Ex 7C | 3 | 25-<250 | 250-260 | 3 | 10 | 35 | 5 |
| Ex 8C | 5 | 25-<250 | 250-260 | 3 | 10 | 35 | 5 |
| Ex 9C | 10 | 25-<250 | 250-260 | 3 | 10 | 35 | 5 |
| Ex 10C | 50 | 25-<250 | 250-260 | 3 | 10 | 35 | 5 |
| Ex 11C | 5 | 25-<250 | 250-260 | 3 | 15 | 35 | 5 |
| RE 1C | 5 | 25-<250 | — | 1 | — | 40 | 0 |
| RE 2C | 5 | 25-<250 | — | 3 | — | 40 | 0 |
| RE 3C | 5 | 25-<250 | — | 1 | — | 40 | 0 |
| RE 4C | 5 | 25-<250 | — | 3 | — | 40 | 0 |
| RE 5C | 5 | 25-<250 | — | 5 | — | 40 | 0 |
| RE 6C | 5 | 25-<250 | — | 7 | — | 40 | 0 |
| RE 7C | 5 | 25-<250 | — | 10 | — | 40 | 0 |
| RE 8C | 5 | 25-<250 | — | 15 | — | 40 | 0 |
| RE 9C | 3 | 25-<250 | — | 1 | — | 40 | 0 |
| RE 10C | 10 | 25-<250 | — | 1 | — | 40 | 0 |
| RE 11C | 50 | 25-<250 | — | 1 | — | 40 | 0 |

| | Evaluation | | | | | | |
|---|---|---|---|---|---|---|---|
| | | | Peel strength | | Thermal conductivity | | |
| | Graphite laminate | | Punch-out | | Temperature difference | | |
| | | Thickness | workability | | (° C.) between | Smoothness | Appearance |
| | Thickness | deviation | (scored | Adhesion | heater portion and | (scored | (scored |
| | (μm) | (%) | out of 3) | ratio (%) | cooling portion | out of 5) | out of 5) |
| Ex 1C | 120 | ±15 | 2 | 60 | 58 | 3 | 3 |
| Ex 2C | 200 | ±15 | 2 | 60 | 37 | 3 | 3 |
| Ex 3C | 400 | ±15 | 2 | 50 | 20 | 3 | 3 |
| Ex 4C | 2100 | ±15 | 2 | 50 | 7 | 3 | 3 |
| Ex 5C | 200 | ±15 | 2 | 65 | 35 | 3 | 4 |
| Ex 6C | 195 | ±10 | 3 | 70 | 33 | 4 | 4 |
| Ex 7C | 110 | ±5 | 3 | ≧95 | 55 | 5 | 4 |
| Ex 8C | 190 | ±5 | 3 | ≧95 | 30 | 5 | 4 |
| Ex 9C | 390 | ±5 | 3 | ≧95 | 16 | 5 | 4 |
| Ex 10C | 2000 | ±5 | 3 | ≧95 | 5 | 5 | 4 |
| Ex 11C | 185 | ±5 | 3 | 95 | 35 | 5 | 3 |
| RE 1C | 210 | ±30 | 1 | 50 | 40 | 1 | 1 |
| RE 2C | 205 | ±20 | 1 | 55 | 38 | 1 | 1 |
| RE 3C | 210 | ±30 | 1 | 50 | 40 | 1 | 2 |
| RE 4C | 200 | ±20 | 1 | 60 | 38 | 2 | 3 |
| RE 5C | 200 | ±15 | 1 | 65 | 37 | 2 | 2 |
| RE 6C | 195 | ±15 | 1 | 70 | 35 | 2 | 2 |
| RE 7C | 190 | ±15 | 1 | 80 | 35 | 2 | 1 |
| RE 8C | 185 | ±15 | 1 | 80 | 37 | 2 | 1 |
| RE 9C | 130 | ±30 | 1 | 50 | 65 | 1 | 1 |
| RE 10C | 410 | ±30 | 1 | 50 | 25 | 1 | 1 |
| RE 11C | 2200 | ±30 | 1 | 50 | 10 | 1 | 1 |

Ex stands for Example
RE stands for Reference Example
25-<250 stands for 25 to less than 250

TABLE 5

| | Graphite sheet | | Adhering step | | | | | |
|---|---|---|---|---|---|---|---|---|
| | Number of | Number of | Temperature | | Pressure | | Pressurizing time period | |
| | disposed | stacks | First | Second | First | Second | First | Second |
| | layers | disposed | pressurizing | pressurizing | pressurizing | pressurizing | pressurizing | pressurizing |
| | (layers) | (stacks) | (° C.) | (° C.) | (Mpa) | (Mpa) | (min) | (min) |
| Ex 12C | 3 | 270 | 25-<250 | 250-260 | 1 | 5 | 35 | 5 |
| Ex 13C | 5 | 160 | 25-<250 | 250-260 | 1 | 5 | 35 | 5 |
| Ex 14C | 10 | 80 | 25-<250 | 250-260 | 1 | 5 | 35 | 5 |
| Ex 15C | 50 | 16 | 25-<250 | 250-260 | 1 | 5 | 35 | 5 |
| Ex 16C | 5 | 160 | 25-<250 | 250-260 | 3 | 5 | 35 | 5 |
| Ex 17C | 5 | 160 | 25-<250 | 250-260 | 3 | 7 | 35 | 5 |
| Ex 18C | 3 | 270 | 25-<250 | 250-260 | 3 | 10 | 35 | 5 |
| Ex 19C | 5 | 160 | 25-<250 | 250-260 | 3 | 10 | 35 | 5 |
| Ex 20C | 10 | 80 | 25-<250 | 250-260 | 3 | 10 | 35 | 5 |
| Ex 21C | 50 | 16 | 25-<250 | 250-260 | 3 | 10 | 35 | 5 |
| Ex 22C | 5 | 160 | 25-<250 | 250-260 | 3 | 15 | 35 | 5 |
| RE 12C | 5 | 5 | 25-<250 | — | 1 | — | 40 | 0 |
| RE 13C | 5 | 5 | 25-<250 | — | 3 | — | 40 | 0 |
| RE 14C | 5 | 5 | 25-<250 | — | 1 | — | 40 | 0 |
| RE 15C | 5 | 5 | 25-<250 | — | 3 | — | 40 | 0 |
| RE 16C | 5 | 5 | 25-<250 | — | 5 | — | 40 | 0 |
| RE 17C | 5 | 5 | 25-<250 | — | 7 | — | 40 | 0 |
| RE 18C | 5 | 5 | 25-<250 | — | 10 | — | 40 | 0 |
| RE 19C | 5 | 5 | 25-<250 | — | 15 | — | 40 | 0 |
| RE 20C | 3 | 270 | 25-<250 | — | 1 | — | 40 | 0 |
| RE 21C | 10 | 80 | 25-<250 | — | 1 | — | 40 | 0 |
| RE 22C | 50 | 16 | 25-<250 | — | 1 | — | 40 | 0 |

| | Evaluation | | | | | | | | |
|---|---|---|---|---|---|---|---|---|---|
| | | | Peel strength | | | | Thermal conductivity | | |
| | Graphite laminate | | Punch-out | Adhesion | Adhesion | Adhesion | Temperature difference | | |
| | | Thickness | workability | ratio (%) | ratio (%) | ratio (%) | (° C.) between | Smoothness | Appearance |
| | Thickness | deviation | (scored | of upper | of middle | of lower | heater portion and | (scored | (scored |
| | (μm) | (%) | out of 5) | portion | portion | portion | cooling portion | out of 5) | out of 5) |
| Ex 12C | 120 | ±20 | 2 | 70 | 60 | 70 | 58 | 3 | 3 |
| Ex 13C | 200 | ±20 | 2 | 70 | 60 | 70 | 37 | 3 | 3 |
| Ex 14C | 400 | ±20 | 2 | 60 | 50 | 60 | 20 | 3 | 3 |
| Ex 15C | 2100 | ±20 | 2 | 60 | 50 | 60 | 7 | 3 | 3 |
| Ex 16C | 200 | ±15 | 2 | 70 | 65 | 70 | 35 | 3 | 4 |
| Ex 17C | 195 | ±10 | 3 | 80 | 70 | 80 | 33 | 4 | 4 |
| Ex 18C | 110 | ±5 | 3 | 95 | 95 | 95 | 55 | 5 | 4 |
| Ex 19C | 190 | ±5 | 3 | 95 | 95 | 95 | 30 | 5 | 4 |
| Ex 20C | 390 | ±5 | 3 | 95 | 95 | 95 | 16 | 5 | 4 |
| Ex 21C | 2000 | ±5 | 3 | 95 | 95 | 95 | 5 | 5 | 4 |
| Ex 22C | 185 | ±5 | 3 | 80 | 95 | 80 | 35 | 5 | 3 |
| RE 12C | 210 | ±30 | 1 | 50 | 50 | 50 | 40 | 1 | 1 |
| RE 13C | 205 | ±20 | 1 | 55 | 55 | 55 | 38 | 1 | 1 |
| RE 14C | 210 | ±30 | 1 | 50 | 50 | 50 | 40 | 1 | 2 |
| RE 15C | 200 | ±20 | 1 | 60 | 60 | 60 | 38 | 2 | 3 |
| RE 16C | 200 | ±15 | 1 | 65 | 65 | 65 | 37 | 2 | 2 |
| RE 17C | 195 | ±15 | 1 | 70 | 70 | 70 | 35 | 2 | 2 |
| RE 18C | 190 | ±15 | 1 | 70 | 80 | 70 | 35 | 2 | 1 |
| RE 19C | 185 | ±15 | 1 | 70 | 80 | 70 | 37 | 2 | 1 |
| RE 20C | 130 | ±30 | 1 | 50 | 50 | 50 | 65 | 1 | 1 |
| RE 21C | 410 | ±30 | 1 | 50 | 50 | 50 | 25 | 1 | 1 |
| RE 22C | 2200 | ±30 | 1 | 50 | 50 | 50 | 10 | 1 | 1 |

Ex stands for Example
RE stands for Reference Example
25-<250 stands for 25 to less than 250

(Test Results)

In a comparison between graphite laminates having the same number of graphite sheets, each of the Examples was superior to the Reference Examples with regard to peel strength, thermal conductivity, smoothness, and external appearance.

In Example 1C, the first pressurizing removes air in the laminate thereof, and then the second pressurizing is performed at a pressure higher than the first pressurizing so as to improve adhesiveness between the graphite sheets and the adhesive layers. For this reason, in comparison to Reference Example 1C, Example 1C has better a thermal conduction property along the thickness direction in the graphite laminate, and is superior in terms of thermal conductivity of the graphite laminate.

For the same reasons, and in the same manner with regards to a thermal conduction property along the thickness direction in the graphite laminate and thermal conductivity of the graphite laminate, Examples 2C, 3C, 4C, 5C, 6C, 7C, 8C, 9C, 10C, and 11C are each superior to Reference Example 1C, and Example 12C is superior to Reference Example 12C.

### INDUSTRIAL APPLICABILITY

The present invention is usable as a material for heat transport in an electronic device or the like. The present invention is thus suitably usable as a thermal highway for use in, for example, a smart phone, a tablet computer, and a fanless laptop personal computer, in each of which CPUs generate large amounts of heat.

### REFERENCE SIGNS LIST

1 Graphite laminate
5 Graphite sheet
6 Adhesive layer
7 Layered surface
10 Bent portion (first bent portion)
11 Bent portion (second bent portion)
12 Bent portion (third bent portion)
15 Region
16 Region
17 Region
30 Pressurizing jig
50 Adhering portion
51 Non-adhering portion
100 Heat-generating element
101 Metal plate
102 Heat-transferring material
110 Side view
120 Top view
201 Graphite laminate
202 Heater
203 Running water
204 Heat insulating material
205 Graphite sheet
206 Adhesive layer
207 Thermocouple (measurement of temperature of high-temperature site)
208 Thermocouple (measurement of temperature of low-temperature site)
209 End (in contact with high-temperature site)
210 Bent portion
211 End (in contact with low-temperature site)
235 Cutting position
301 Rod-shaped heat transporter
302 First CPU
303 Plate
304 Casing
305 Second CPU
312 First clamp
313 Second clamp
322 Heater
323 Running water
324 Heat insulating material
325 Thermocouple
326 Thermocouple
327 End
328 End
401 Graphite laminate
402 Adhesion layer
403 Protective layer
501 Graphite laminate
540 High-temperature site
541 Low-temperature site
550 Electronic component
601 Rod-shaped heat transporter

1.-10. (canceled)

11. A graphite laminate, comprising:
graphite sheets; and
adhesive layers,
the graphite sheets and the adhesive layers being disposed alternately on top of each other,
the adhesive layers each containing at least one of a thermoplastic resin and a thermosetting resin,
the adhesive layers each having a water absorption rate of not more than 2% and a thickness of less than 15 μm,
the graphite sheets being included in the graphite laminate in a number of not less than 3.

12. A graphite laminate, comprising:
graphite sheets; and
adhesive layers,
the graphite sheets and the adhesive layers being disposed alternately on top of each other,
the adhesive layers each containing at least one of a thermoplastic resin and a thermosetting resin,
the adhesive layers each having a thickness of less than 15 μm,
the graphite sheets being included in the graphite laminate in a number of not less than 3,
the graphite laminate having a water absorption rate of not more than 0.25%.

13. The graphite laminate according to claim 11, wherein the thermoplastic resin and the thermosetting resin each have a glass transition point of not lower than 50° C.

14. The graphite laminate according to claim 11, wherein the graphite sheets each have a thermal conductivity of not less than 1000 W/(m·K) in a surface direction.

15. The graphite laminate according to claim 11, wherein the graphite laminate is bent so as to have at least one bent portion.

16. A graphite laminate, comprising:
graphite sheets; and
adhesive layers,
the graphite sheets and the adhesive layers each having a surface defined by an X axis and a Y axis, which is orthogonal to the X axis, the graphite sheets and the adhesive layers being disposed alternately on top of each other in a direction of a Z axis, which is perpendicular to the surface, in such a manner that the respective surfaces of the graphite sheets and the adhesive layers overlap with each other, the graphite laminate being bent so as to have at least two bent portions,
each of the at least two bent portions being one of (a) to (c) below,
(a) a first bent portion, which is formed by bending the graphite laminate in a direction of the X axis or the Y axis,
(b) a second bent portion, which is formed by bending the graphite laminate in the direction of the Z axis, and
(c) a third bent portion, which is formed by bending the graphite laminate in the direction of the X axis or the Y axis and also in the direction of the Z axis.

17. A graphite laminate, comprising:
graphite sheets; and
adhesive layers,
the graphite sheets and the adhesive layers each having a surface defined by an X axis and a Y axis, which is orthogonal to the X axis, the graphite sheets and the adhesive layers being disposed alternately on top of each other in a direction of a Z axis, which is perpendicular to the surface, in such a manner that the respective surfaces of the graphite sheets and the adhesive layers overlap with each other,
the graphite laminate being bent so as to have at least one bent portion,
each of the at least one bent portion being (c) below,
(c) a third bent portion, which is formed by bending the graphite laminate in a direction of the X axis or the Y axis and also in the direction of the Z axis.

18. The graphite laminate according to claim 11, wherein in a case where (i) one end of the graphite laminate is fixed so that the graphite laminate is horizontal with respect to ground and then (ii) a load is imposed on a cross section of the graphite laminate which cross section is located 4 cm away from the fixed end, the load being 0.7 g per 1 mm² of the cross section, the cross section has a displacement of not more than 15 mm.

19. A heat transport structure, comprising:
a graphite laminate according to claim 11; and
a heat-generating element,
the graphite laminate being connected with a high-temperature site, whose temperature is raised by heat generated by the heat-generating element, and with a low-temperature site, whose temperature is lower than the temperature of the high-temperature site.

20.-25. (canceled)

26. A graphite laminate, comprising:
graphite sheets; and
adhesive layers,
the graphite sheets and the adhesive layers being disposed alternately on top of each other,
the adhesive layers each containing at least one of a thermoplastic resin and a thermosetting resin,
the graphite sheets being included in the graphite laminate in a number of not less than 3,
the graphite sheets and the adhesive layers being in close contact with each other at not less than 50% of an interface therebetween.

27.-31. (canceled)

32. The graphite laminate according to claim 12, wherein the thermoplastic resin and the thermosetting resin each have a glass transition point of not lower than 50° C.

33. The graphite laminate according to claim 12, wherein the graphite sheets each have a thermal conductivity of not less than 1000 W/(m·K) in a surface direction.

34. The graphite laminate according to claim 12, wherein the graphite laminate is bent so as to have at least one bent portion.

35. The graphite laminate according to claim 12, wherein in a case where (i) one end of the graphite laminate is fixed so that the graphite laminate is horizontal with respect to ground and then (ii) a load is imposed on a cross section of the graphite laminate which cross section is located 4 cm away from the fixed end, the load being 0.7 g per 1 mm² of the cross section, the cross section has a displacement of not more than 15 mm.

36. A heat transport structure, comprising:
a graphite laminate according to claim 12; and
a heat-generating element,
the graphite laminate being connected with a high-temperature site, whose temperature is raised by heat generated by the heat-generating element, and with a low-temperature site, whose temperature is lower than the temperature of the high-temperature site.

37. The graphite laminate according to claim 16, wherein in a case where (i) one end of the graphite laminate is fixed so that the graphite laminate is horizontal with respect to ground and then (ii) a load is imposed on a cross section of the graphite laminate which cross section is located 4 cm away from the fixed end, the load being 0.7 g per 1 mm² of the cross section, the cross section has a displacement of not more than 15 mm.

38. A heat transport structure, comprising:
a graphite laminate according to claim 16; and
a heat-generating element,
the graphite laminate being connected with a high-temperature site, whose temperature is raised by heat generated by the heat-generating element, and with a low-temperature site, whose temperature is lower than the temperature of the high-temperature site.

39. The graphite laminate according to claim 17, wherein in a case where (i) one end of the graphite laminate is fixed so that the graphite laminate is horizontal with respect to ground and then (ii) a load is imposed on a cross section of the graphite laminate which cross section is located 4 cm away from the fixed end, the load being 0.7 g per 1 mm² of the cross section, the cross section has a displacement of not more than 15 mm.

40. A heat transport structure, comprising:
a graphite laminate according to claim 17; and
a heat-generating element,
the graphite laminate being connected with a high-temperature site, whose temperature is raised by heat generated by the heat-generating element, and with a low-temperature site, whose temperature is lower than the temperature of the high-temperature site.
